(19) United States
(12) Patent Application Publication
(10) Pub. No.: US 2017/0322358 A1
(43) Pub. Date: Nov. 9, 2017

(54) POLARIZING PLATE, FRONT PANEL OF DISPLAY DEVICE, DISPLAY APPARATUS, SUBSTRATE OF TOUCH PANEL, RESISTIVE FILM-TYPE TOUCH PANEL, AND CAPACITANCE-TYPE TOUCH PANEL

(71) Applicant: FUJIFILM Corporation, Tokyo (JP)

(72) Inventors: Keigo UEKI, Kanagawa (JP); Katsuyuki TAKADA, Kanagawa (JP)

(73) Assignee: FUJIFILM Corporation, Tokyo (JP)

(21) Appl. No.: 15/657,687

(22) Filed: Jul. 24, 2017

Related U.S. Application Data
(63) Continuation of application No. PCT/JP2016/051488, filed on Jan. 20, 2016.

(30) Foreign Application Priority Data
Jan. 27, 2015 (JP) 2015-013768

(51) Int. Cl. G02B 5/30; B32B 27/06; B32B 7/02; G02F 1/1335; B32B 7/12; H01L 51/52; G06F 3/044; G06F 3/045

(52) U.S. Cl. CPC G02B 5/3025; B32B 7/12; B32B 27/06; B32B 7/02; G02B 5/3016; G02F 1/133528; B32B 2307/42; B32B 2307/51; B32B 2309/105; G06F 3/044; G06F 3/045; H01L 51/5281; B32B 2457/20

(57) ABSTRACT

Provided is a polarizing plate including a base material, an interlayer, an adhesive layer, and a polarizer layer in this order, in which the base material contains at least a resin film and has a thickness of equal to or greater than 120 μm, the interlayer is a cured layer obtained by curing a thermosetting composition containing a thermally cross-linkable compound in a proportion of equal to or higher than 0.10% by mass with respect to a total amount of solid content of the composition, and a modulus of elasticity Ea of the base material, a modulus of elasticity Eb of the interlayer, and a modulus of elasticity Ec of the adhesive layer satisfy Expression 1: Ea>Eb>Ec. Also provided are a front panel of a display device, a display apparatus, a substrate of a touch panel, a resistive film-type touch panel, and a capacitance-type touch panel.

### CROSS-REFERENCE TO RELATED APPLICATIONS

This application is a Continuation of PCT International Application No. PCT/JP2016/051488 filed on Jan. 20, 2016, which was published under PCT Article 21(2) in Japanese and claims priority under 35 U.S.C. §119(a) to Japanese Patent Application No. 2015-013768 filed on Jan. 27, 2015. The above applications are hereby expressly incorporated by reference, in their entirety, into the present application.

### BACKGROUND OF THE INVENTION

### 1. Field of the Invention

The present invention relates to a polarizing plate, a front panel of a display device, a display apparatus, a substrate of a touch panel, a resistive film-type touch panel, and a capacitance-type touch panel.

### 2. Description of the Related Art

A polarizing plate is a constituent member of a display apparatus such as a liquid crystal display apparatus and includes at least a polarizer layer (referred to as a polarizing film or polarizer as well). Generally, the polarizing plate is constituted with a polarizer layer and a protective film bonded to each other through an adhesive layer (for example, see JP2014-133408A).

In the related art, for use in such as a front panel of a display apparatus or a substrate of a touch panel for which high durability is required, glass such as a chemically strengthened glass is mainly used. Compared to such glass, plastics have advantages such as lightweightness, excellent workability, inexpensiveness, and excellent transparency. Therefore, in recent years, for the use for which glass was mainly utilized, the usefulness of plastics as a substitute for glass has drawn attention. Under this circumstance, for example, JP2014-89270A suggests that, as a front panel of a display apparatus or a substrate of a touch panel, an optical laminate including a resin film (described as a plastic film in JP2014-89270A) is used. JP2014-89270A suggests that, in the optical laminate, the resin film is laminated on a polarizer layer (described as a polarizing film in JP2014-89270A).

### SUMMARY OF THE INVENTION

As suggested in JP2014-89270A, in the optical laminate used as a front panel of a display apparatus or as a substrate of a touch panel, by laminating a base material including at least a resin film and a polarizer layer, the base material can function as a polarizing plate protective film. From the viewpoint of making a thin laminate by combining the members, it is desirable to make the base material contained in the front panel or the substrate function as a polarizing plate protective film as described above.

Meanwhile, JP2014-89270A discloses that the polarizer layer is bonded by exploiting the water adhesion action of a polyvinyl alcohol (PVA)-based polarizing film without using an adhesive layer (see paragraphs “0037” and “0051” in JP2014-89270A). However, from the viewpoint of improving the adhesiveness of the polarizer layer, it is desirable to bond the polarizer layer through an adhesive layer as described in JP2014-133408A, for example. In a case where a polarizer layer is formed of a material other than PVA, as a case where it is difficult to bond the polarizer layer by exploiting the water adhesion action described in JP2014-89270A, the polarizer layer is generally bonded through an adhesive layer.

However, as a result of conducting an examination, the inventors of the present invention revealed that, in a case where a base material including at least a resin film used in a front panel of a display apparatus or in a substrate of a touch panel is bonded to a polarizer layer through an adhesive layer, when the laminate obtained by bonding is subjected to a process of being cut into a product size, cracking occurs on the edge of the cut product, and hence the process suitability becomes poor. Because the occurrence of cracking on the edge reduces the product yield, the cracking needs to be suppressed.

Accordingly, an object of the present invention is to provide a polarizing plate which is obtained by bonding a base material including at least a resin film to a polarizer layer through an adhesive layer, suitable for a front panel of a display apparatus or for a substrate of a touch panel, and is excellent in process suitability (in which cracking that occurs on the edge at the time of cutting process is inhibited).

An aspect of the present invention relates to a polarizing plate comprising a base material, an interlayer, an adhesive layer, and a polarizer layer in this order, in which the base material includes at least a resin film and has a thickness equal to or greater than 120 m, the interlayer is a cured layer obtained by curing a thermosetting composition which contains a thermally cross-linkable compound in an amount equal to or greater than 0.10% by mass with respect to a total amount of solid content of the composition, and a modulus of elasticity Ea of the base material, a modulus of elasticity Eb of the interlayer, and a modulus of elasticity Ec of the adhesive layer satisfy the following Expression 1:

Ea>Eb>Ec Expression 1.

In the present invention and the present specification, the “modulus of elasticity” is a value measured according to JIS Z 2251 in a portion positioned in the middle of the thickness direction (that is, in a case where the thickness is denoted by “A”, the portion that is beneath any one of the surfaces by a depth that equals “thickness A/2”) of a film or a layer to be measured. Furthermore, a modulus of elasticity of a surface layer portion of an interlayer, which will be described later, is a value measured in a portion that is below the surface of the interlayer by a depth that accounts for 20% of the total thickness of the interlayer. The modulus of elasticity is measured in an environment with a temperature of 25° C. and a relative humidity of 50% under the conditions of a maximum indentation load of 20 mN, an indentation time of 10 seconds, and a creep of 5 seconds. Indentation is performed using an indenter made of diamond, and from the obtained relationship between the maximum indentation depth and the load, the modulus of elasticity is determined. As a device for measuring the modulus of elasticity, known devices can be used. In the examples which will be described later, a HM2000-type hardness meter manufactured by Fischer Instrument K.K. was used.

In the present invention and the present specification, the thickness of a film or layer is a value determined by observing a cross-section using a microscope such as an optical electroscope or a scanning electron microscope (SEM). The thickness is measured in at least one site, and in a case where the thickness is measured in at least two or more sites, the arithmetic mean of the measured thicknesses is taken as the thickness.

In an aspect, the aforementioned polarizing plate further has a resin film on a side of the polarizer layer that is opposite to the base material.

In an aspect, a thickness of the base material is equal to or greater than 200 μm and equal to or less than 700 μm.

In an aspect, the modulus of elasticity Ea of the base material, the modulus of elasticity Eb of the interlayer, and the modulus of elasticity Ec of the adhesive layer satisfy the following Expression 2:

(Ea+Ec)×3/5>Eb>(Ea+Ec)×2/5 Expression 2.

In an aspect, the modulus of elasticity Eb of the interlayer is equal to or higher than 1.5 GPa and equal to or lower than 5.0 GPa.

In an aspect, the modulus of elasticity Eb of the interlayer, a modulus of elasticity E1 of a surface layer portion of the interlayer on the base material side, and a modulus of elasticity E2 of a surface layer portion of the interlayer on the adhesive layer side satisfy the following Expression 3:

E1>Eb>E2 Expression 3.

In an aspect, a thickness of the interlayer is equal to or greater than 0.01 μm and equal to or less than 5.00 μm.

In an aspect, the interlayer contains a compound having a barbituric acid structure.

In an aspect, the polarizing plate further has a cured layer, which is obtained by curing an active energy ray-curable composition, on a side of the base material that is opposite to the interlayer side.

In an aspect, the polarizing plate has a decorative layer in a portion on one surface of the base material.

In an aspect, the base material includes a quarter wavelength retardation plate.

In an aspect, the resin film included in the base material is a laminated film having an acryl-based resin film, a polycarbonate-based resin film, and an acryl-based resin film in this order.

Another aspect of the present invention relates to a front panel of a display device that is the aforementioned polarizing plate.

Another aspect of the present invention relates to a display apparatus comprising the front panel and a display device.

In an aspect, the display device is a liquid crystal display device.

In an aspect, the display device is an organic electroluminescence (hereinafter, described as “EL” as well) display device.

In an aspect, the display device is an in-cell touch panel display device.

In an aspect, the display device is an on-cell touch panel display device.

Another aspect of the present invention relates to a substrate of a touch panel that is the aforementioned polarizing plate.

Another aspect of the present invention relates to a resistive film-type touch panel comprising the substrate.

Another aspect of the present invention relates to a capacitance-type touch panel comprising the substrate.

According to the present invention, it is possible to provide a polarizing plate which can be used as a front panel of a display apparatus or as a substrate of a touch panel and in which the edge of the polarizing plate is inhibited from cracking at the time of a cutting process.

### DESCRIPTION OF THE PREFERRED EMBODIMENTS

Hereinafter, the present invention will be described based on typical embodiments, but the present invention is not limited to the embodiments. In the present invention and the present specification, a range of numerical values described using “to” means a range which includes the numerical values listed before and after “to” as a lower limit and an upper limit. In the present invention and the present specification, the description relating to an angle such as “orthogonal” means that the angle includes a margin of error accepted in the technical field to which the present invention belongs. For example, the description means that the angle is within a range less than a precise angle ±10°, and a difference between the angle and the precise angle is preferably equal to or less than 50 and more preferably equal to or less than 3°.

[Polarizing Plate]

An aspect of the present invention relates to a polarizing plate which has a base material, an interlayer, an adhesive layer, and a polarizer layer in this order, in which the base material includes at least a resin film and has a thickness equal to or greater than 120 μm, the interlayer is a cured layer obtained by curing a thermosetting composition which contains a thermally cross-linkable compound in an amount equal to or greater than 0.10% by mass with respect to the total amount of solid content of the composition, and a modulus of elasticity Ea of the base material, a modulus of elasticity Eb of the interlayer, and a modulus of elasticity Ec of the adhesive layer satisfy Expression 1: Ea>Eb>Ec.

Hereinafter, the assumption that the inventors of the present invention made regarding the aforementioned polarizing plate will be described. The following description is merely a an assumption, and the present invention is not limited thereto.

It is desirable for a base material formed of a resin film or a base material including a resin film, which is used as a substitute for glass in a front panel of a display apparatus or a substrate of a touch panel, to be thicker than a film generally used as a polarizing plate protective film, such that the hardness is improved to enable the base material to substitute glass. However, in the process of repeating the examination for achieving the aforementioned object, the inventors of the present invention made an assumption that the lamination of a thick base material including at least a resin film, specifically, the lamination of a base material, which includes at least a resin film and has a thickness equal to or greater than 120 μm, and a polarizer layer through an adhesive layer may result in the occurrence of cracking on the edge at the time of cutting process described above. Specifically, the mechanism is as below. It is considered that, generally, the base material is harder than the adhesive layer (the adhesive layer is softer than the base material), and accordingly, at the time of cutting process, stress is applied to the vicinity of the interface between the base material and the adhesive layer. It is considered that the base material being thicker than a polarizing plate protective film of the related art has a large contact area contacting cutting means such as a punching blade or a punching die at the time of cutting process, friction increases, and as a result, the applied stress becomes stronger. Presumably, for this reason, if the base material which includes at least a resin film and has a thickness equal to or greater than 120 μm and the polarizer layer are laminated through an adhesive layer, strong stress is applied to the vicinity of the interface between the base material and the adhesive layer. The inventors of the present invention assume that, as a result, interfacial peeling or cohesive failure occurs between the base material and the adhesive layer on the edge at the time of cutting process and results in the aforementioned cracking.

Furthermore, the inventors of the present invention further continued thorough examination based on the aforementioned assumption. As a result, they newly found out that, by providing an interlayer having a modulus of elasticity satisfying Expression 1 described above between the base material, which includes at least a resin film and a thickness equal to or greater than 120 μm, and the adhesive layer, the occurrence of cracking can be inhibited. Based on what they have found, the inventors completed the polarizing plate of the present invention. The inventors of the present invention assume that the interlayer may make a contribution to the inhibition of the occurrence of the cracking by playing a role in dispersing the stress. However, as described above, the present invention is not limited to the assumption.

Hereinafter, the polarizing plate of the present invention will be more specifically described.

<Base Material>

(Specific Aspect of Base Material)

The base material contained in the polarizing plate is a base material which includes at least a resin film and has a thickness equal to or greater than 120 μm. In the present invention and the present specification, a resin film refers to a film containing a resin as a constituent component. Furthermore, a resin layer refers to a layer containing a resin as a constituent component. It is preferable that the resin film and the resin layer contain a resin as a component which makes up the greatest portion in the film or the layer among the components constituting the film or the layer. In the resin film or the resin layer, the proportion of a resin can be equal to or higher than 50% by mass for example, preferably can be equal to or higher than 60% by mass, and more preferably can be equal to or higher than 70% by mass.

In the polarizing plate of the present invention, the base material can include one or more cured layers obtained by curing an active energy ray-curable composition on the interlayer side of the resin film. The cured layer is also a portion of the base material. In contrast, as will be described later, on a side of the resin film opposite to the interlayer side, a cured layer obtained by curing an active energy ray-curable composition can be provided, but this cured layer is not regarded as a portion of the base material. That is, in the polarizing plate of the present invention, the resin film forms the uppermost surface of the base material that is on the side opposite to the interlayer side. In the present invention and the present specification, active energy rays refer to ionizing radiation and includes X-rays, ultraviolet rays, visible light, infrared rays, electron beams, α-rays, β-rays, γ-rays, and the like. Furthermore, “active energy ray-curable” means a property of being cured by being irradiated with the active energy rays.

—Resin Film—

The resin film included in the base material may be a single layer film consisting of a single resin layer or a laminated film consisting of two or more resin layers. The resin film is available as commercial products, or can be manufactured by a known film forming method. Examples of resin films which can be used as the resin film included in the base material include an acryl-based resin film, a polycarbonate-based resin film, a polyolefin-based resin film, a polyester-based resin film, an acrylonitrile-butadiene-styrene copolymer (ABS) film, and the like. In a preferred aspect, the resin film included in the base material includes at least one kind of film selected from the group consisting of an acryl-based resin film and a polycarbonate-based resin film. In a more preferred aspect, the resin film included in the base material is a laminated film consisting of two or more layers of resin films. Herein, the number of layers laminated is 2 or 3 for example, but is not particularly limited. As an example of a preferred resin film (laminated film), a laminated film can be exemplified which has an acryl-based resin film, a polycarbonate-based resin film, and an acryl-based resin film in this order. The acryl-based resin film is a resin film of a polymer or a copolymer containing one or more kinds of monomers selected from the group consisting of an acrylic acid ester and a methacrylic acid ester, and examples thereof include a polymethyl methacrylate resin (PMMA) film.

—Optional Component of Resin Film—

The resin film can optionally contain one or more kinds of other components such as known additives in addition to the resin. As an example of the components which can be optionally contained, an ultraviolet absorber can be exemplified. Examples of the ultraviolet absorber include a benzotriazole compound and a triazine compound. The benzotriazole compound mentioned herein is a compound having a benzotriazole ring, and specific examples thereof include various benzotriazole-based ultraviolet absorbers described in paragraph “0033” of JP2013-111835A. The triazine compound is a compound having a triazine ring, and specific examples thereof include various triazine-based ultraviolet absorbers described in paragraph “0033” of JP2013-111835A. The content of the ultraviolet absorber in the resin film is, for example, about 0.1 to 10 parts by mass with respect to 100 parts by mass of the resin contained in the film, but is not particularly limited. Regarding the ultraviolet absorber, paragraph “0032” of JP2013-111835A can also be referred to. In the present invention and the present specification, the ultraviolet rays refer to the light having a central emission wavelength in a wavelength range of 200 to 380 nm.

(Thickness of Base Material)

In the polarizing plate of the present invention, the thickness of the base material is equal to or greater than 120 μm, because the resin film containing a resin and having a thickness equal to or greater than 120 μm can exhibit high hardness and is preferred as a base material substituting glass. Here, if such a base material is laminated on a polarizer layer through an adhesive layer without providing an interlayer which will be specifically described later, cracking occurs on the edge at the time of cutting process as described above. With the polarizing plate of the present invention, such a problem can be solved by providing the interlayer. The thickness of the base material is equal to or greater than 120 μm, and preferably equal to or greater than 200 μm. From the viewpoint of ease of handling (for example, flexibility), the thickness of the base material is preferably equal to or less than 1,000 μm, and more preferably equal to or less than 700 μm. For the base material formed of a laminated film (resin film), the thickness of the base material refers to the total thickness of the laminated film, and the same shall be applied to other films. In a case where the polarizing plate includes one or more cured layers on the interlayer side of the resin film as described above, the thickness of the base material refers to the total thickness of the cured layers and the resin film.

The modulus of elasticity, which will be described later, of the base material can be controlled by the type of resin constituting the resin film. In a case where the aforementioned cured layers are included in the base material, the modulus of elasticity can be controlled by the formulation of the active energy ray-curable composition for forming the cured layers.

(Quarter Wavelength Retardation Plate)

The base material can also include a quarter wavelength retardation plate as the single layer film consisting of a single resin layer, as the resin layer included in the resin film which is a laminated film, or as the cured layer which is provided on the interlayer side of the resin film and obtained by curing the active energy ray-curable composition. The quarter wavelength retardation plate can convert linearly polarization emitted from the polarizer layer into circular polarization. Accordingly, for example, in a case where a viewer wears polarized sunglasses, the quarter wavelength retardation plate can provide excellent visibility. In the present invention and the present specification, the quarter wavelength retardation plate refers to a plate causing in-plane retardation of 100 to 175 nm at a wavelength of 550 nm.

In the present invention and the present specification, the in-plane retardation at a wavelength of 550 nm is measured by causing light having a wavelength of 550 nm to enter a film or layer to be measured along a normal direction in KOBRA 21ADH (manufactured by Oji Scientific Instruments). At the time of selecting a measurement wavelength, by manually replacing the wavelength-selective filter or by converting the measured value by using a program or the like, the in-plane retardation can be measured. The in-plane retardation can also be measured using AxoScan (manufactured by Axometrics, Inc).

The quarter wavelength retardation plate may be formed by a known method. Alternatively, as the quarter wavelength retardation plate, a commercially available resin film may be used as it is or used after being subjected to a stretching treatment or the like.

Furthermore, as described in JP2001-4837A for example, the quarter wavelength retardation plate can be an optically-anisotropic layer (cured layer) formed by coating an arbitrary support with a curable composition containing a liquid crystal compound. For example, as described in JP2001-4837A, by using a vertical alignment film, it is possible to prepare a cured layer which can function as a quarter wavelength retardation plate.

The thickness of the quarter wavelength retardation plate is generally about 0.1 to 80 μm for example, but is not particularly limited. The quarter wavelength retardation plate can also be laminated on the uppermost surface of the base material (that is, the resin film as the uppermost surface). In this case, the quarter wavelength retardation plate is not included in the base material as described above. In view of the surface hardness of the polarizing plate, it is preferable to provide the quarter wavelength retardation plate between the resin film of the base material and the interlayer.

(Layer which can be Optionally Included in Base Material)

As described above, the base material can have the cured layer, which is obtained by curing an active energy ray-curable composition, on the interlayer side of the resin film. In an aspect, the cured layer is the aforementioned quarter wavelength retardation plate. The cured layer may also be a cured layer other than the quarter wavelength retardation plate that is obtained by curing a known active energy ray-curable composition.

<Modulus of Elasticity>

(Expression 1)

The interlayer positioned between the base material described so far and an adhesive layer which will be described later is a layer having a modulus of elasticity that is smaller than a modulus of elasticity of the base material and a modulus of elasticity of the adhesive layer. That is, provided that a modulus of elasticity of the base material is Ea, a modulus of elasticity of the interlayer is Eb, and a modulus of elasticity of the adhesive layer is Ec, the polarizing plate of the present invention satisfies the following Expression 1.

Ea>Eb>Ec Expression 1

When Ea, Eb, and Ec satisfy Expression 1, the occurrence of cracking at the time of cutting process can be inhibited due to the mechanism described above that was assumed by the inventors of the present invention.

(Expression 2)

Furthermore, it is more preferable that Ea, Eb, and Ec satisfy the following Expression 2.

(Ea+Ec)×3/5>Eb>(Ea+Ec)×2/5 Expression 2

Expression 2 is a relational expression which shows that the modulus of elasticity Eb of the interlayer is a median modulus of elasticity of the modulus of elasticity Ea of the base material and the modulus of elasticity Ec of the adhesive layer ((Ea+Ec)/2) or is close to the median modulus of elasticity. It is preferable that Ea, Eb, and Ec satisfy Expression 2 because then the occurrence of cracking at the time of cutting process may further be inhibited.

(Modulus of Elasticity of Each Layer and Base Material)

The modulus of elasticity Eb of the interlayer can be, for example, equal to or higher than 1.5 GPa and equal to or lower than 5.0 GPa. The modulus of elasticity of the resin film can be, for example, equal to or higher than 3.0 GPa and equal to or lower than 15.0 GPa. The modulus of elasticity of the adhesive layer can be, for example, equal to or higher than 0.1 GPa and equal to or lower than 2.5 GPa. Here, in the polarizing plate of the present invention, Ea, Eb, and Ec are not particularly limited as long as they satisfy Expression 1.

<Interlayer>

Next, specific aspects of the interlayer will be described.

(Thermally Cross-Linkable Compound)

The interlayer is a cured layer obtained by curing a thermosetting composition (composition for forming an interlayer) which contains a thermally cross-linkable compound in an amount equal to or greater than 0.1% by mass with respect to the total amount of solid content of the composition. The cured layer (interlayer) formed of the thermosetting composition shrinks less during curing compared to the cured layer obtained by curing the active energy curable composition, and thus can inhibit the occurrence of curling in the polarizing plate. Herein, the thermally cross-linkable compound refers to a compound having one or more functional groups (thermally cross-linkable groups), which can cause a crosslinking reaction by heating, in one molecule, and is preferably a polyfunctional compound having two or more thermally cross-linkable groups in one molecule. Hereinafter, the thermally cross-linkable compound will be described as a cross-linking agent as well. By forming a cross-linked structure by the cross-linking agent, and preferably by forming a cross-linked structure between resins which will be described later, the cured layer can be formed.

As the cross-linking agent, it is preferable to use an isocyanate-based compound (hereinafter, referred to as an isocyanate-based cross-linking agent as well). From the viewpoint of improving the adhesiveness with respect to the base material, it is preferable to use the isocyanate-based cross-linking agent. Considering the application of the isocyanate-based cross-linking agent to in-line coating or the like, it is preferable that the cross-linking agent is soluble or dispersible in water.

The isocyanate-based compound is a compound derived from an isocyanate derivative represented by an isocyanate or a blocked isocyanate. Examples of the isocyanate include an aromatic isocyanate such as tolylene diisocyanate, xylylene diisocyanate, methylene biphenyl diisocyanate, phenylene diisocyanate, or naphthalene diisocyanate, an aromatic ring-containing aliphatic isocyanate such as α,α,α′,α′-tetramethylxylylene diisocyanate, an aliphatic isocyanate such as methylene diisocyanate, propylene diisocyanate, lysine diisocyanate, trimethyl hexamethylene diisocyanate, or hexamethylene diisocyanate, and an alicyclic isocyanate such as cyclohexane diisocyanate, methyl cyclohexane diisocyanate, isophorone diisocyanate, methylene bis(4-cyclohexylisocyanate), or isopropylidene dicyclohexyl diisocyanate. Examples of the isocyanate also include a biuretized isocyanate, an isocyanurated isocyanate, a uretdionized isocyanate, and polymers or derivatives of an isocyanate modified with carbodiimide. One kind of these isocyanates may be used singly, or plural kinds thereof may be used in combination. Among the above isocyanate-based compounds, from the viewpoint of avoiding yellowing caused by ultraviolet rays, an aliphatic isocyanate or an alicyclic isocyanate is more preferred than an aromatic isocyanate.

From the viewpoint of the pot life of the composition for forming an interlayer, it is preferable that the isocyanate-based compound is used in the state of a blocked isocyanate. Examples of blocking agents for making the blocked isocyanate include bisulfites, a phenol-based compound such as phenol, cresol, or ethyl phenol, an alcohol-based compound such as propylene glycol monomethyl ether, ethylene glycol, benzyl alcohol, methanol, or ethanol, an active methylene-based compound such as dimethyl malonate, diethyl malonate, methyl acetoacetate, ethyl acetoacetate, or acetyl acetone, a mercaptan-based compound such as butyl mercaptan or dodecyl mercaptan, a lactam-based compound such as ε-caprolactam or 8-valerolactam, an amine-based compound such as diisopropylamine, diphenylaniline, aniline, or ethylenimine, acetanilide, an acid amide compound of amide acetate, or formaldehyde, an oxime-based compound such as acetaldoxime, acetone oxime, methyl ethyl ketone oxime, or cyclohexanone oxime, a pyrazole-based compound such as dimethyl pyrazol or 1,2,4-triazole, and the like. One kind of these may be used singly, or two or more kinds thereof may be used in combination.

As the blocking agent, it is preferable to use a malonic acid diester derivative of an active methylene-based compound. As the amine-based compound, linear secondary amines are preferable, and among these, diisopropylamine, diisobutylamine, di(2-butylamine), and di(t-butyl)amine are more preferable. It is more preferable to use the active methylene-based compound and the amine-based compound in combination. Particularly, it is preferable to use a blocking agent formed of diethyl malonate and diisopropylamine.

Only one kind of isocyanate-based compound may be used, or plural kinds thereof may be used. Furthermore, a material obtained by mixing or bonding the isocyanate-based compound with or to the various resins may be used. In order to improve the dispersibility or cross-linking properties of the isocyanate-based compound, it is preferable to use a material obtained by mixing or bonding the isocyanate-based compound with or to a polyester-based resin or a polyurethane-based resin.

In addition to the isocyanate-based cross-linking agent, for example, a cross-linking agent formed of a melamine-based compound, an epoxy-based compound, an oxazoline-based compound, a carbodiimide-based compound, or the like may be mixed in and used. Generally, in the interlayer, the cross-linking agent is contained in the cross-linking agent in the form of a compound that has partially or totally undergone a crosslinking reaction. Furthermore, in some cases, a resin is also contained in the cross-linking agent, in a state where at least a portion thereof is cross-linked with the cross-linking agent.

From the viewpoint of controlling the modulus of elasticity, the proportion of the cross-linking agent in the composition for forming an interlayer, with respect to the total amount of solid content of the composition for forming an interlayer, is preferably 0.10% to 30.00% by mass, more preferably 0.50% to 25.00% by mass, and even more preferably 2.00% to 20.00% by mass.

(Components which can Constitute Interlayer)

—Resin—

The interlayer preferably contains a resin. From the viewpoint of the adhesiveness with respect to the base material, the proportion of the resin in the interlayer, with respect to the total mass of the interlayer, is preferably 30% to 90% by mass, more preferably 40% to 85% by mass, and even more preferably 50% to 80% by mass. The resin can function as a binder, and the type of the resin is not particularly limited. It is preferable that the resin is at least one of the acryl-based resin, polyester-based resin, polyurethane-based resin, polystyrene-based resin, and styrene-butadiene copolymer. Considering the environment, the resin is preferably soluble or dispersible in water.

As an example of the resin preferred as a binder, a polyvinyl alcohol-based resin can be exemplified. The polyvinyl alcohol-based resin refers to a resin having a polyvinyl alcohol moiety. For other resins or compounds, “-based” means that the resins or compounds have a moiety listed before the term (“-based”).

Generally, the polyvinyl alcohol-based resin is synthesized using an acid component as a raw material. The acid component includes a dicarboxylic acid such as maleic acid, fumaric acid, or itaconic acid or a monoester thereof, a monocarboxylic acid such as acrylic acid, methacrylic acid, or crotonic acid, and the like. The acid component may contain a carboxyl group on a side chain. As the acid component, a dicarboxylic acid, maleic acid, and itaconic acid which easily form a cross-link by an acid are preferable, and maleic acid and itaconic acid are more preferable.

The degree of saponification of the polyvinyl alcohol-based resin is not particularly limited, but is preferably 50 to 95 mol %, more preferably 60 to 90 mol %, and even more preferably 70 to 90 mol %.

The degree of carboxylic acid modification is not particularly limited, but is preferably 0.5 to 10 mol % and more preferably 2 to 5 mol %.

The degree of polymerization is not particularly limited, but is preferably equal to or higher than 300 and equal to or lower than 3,000, more preferably equal to or higher than 400 and equal to or lower than 2,000, and even more preferably equal to or higher than 500 and equal to or lower than 2,000. The higher the degree of polymerization is, the further the cohesive force of the interlayer can be improved, and the further the modulus of elasticity can be increased. From the viewpoint of the viscosity of the composition for forming an interlayer, the degree of polymerization is preferably equal to or lower than 2,000. Furthermore, by mixing resins with different degrees of polymerization together, it is possible to adjust the viscosity of the composition for forming an interlayer while improving the cohesive force of the interlayer.

In the present invention, the degree of saponification and the degree of polymerization are values measured according to JIS K 6726 1994.

—Other Components—

If necessary, within a scope in which the interlayer having the modulus of elasticity Eb satisfying Expression 1 can be formed, the composition for forming an interlayer can contain one or more kinds of known additives. Examples of the additives include an antifoaming agent, a coating property-improving agent, a thickener, an organic lubricant, an antistatic agent, an ultraviolet absorber, an antioxidant, a foaming agent, a dye, a pigment, and the like. Furthermore, if necessary, the composition for forming an interlayer may contain a catalyst, a surfactant, a dispersant, a thickener, a film-forming aid, an anti-blocking agent, and the like. Examples of the catalyst include an organic tin-based compound (such as ERASTRON Cat*21 manufactured by DKS Co., Ltd). Examples of the surfactant include an anionic surfactant, a sulfosuccinic acid-based surfactant, a polyethylene oxide-based surfactant (such as NAROACTY CL-95 manufactured by Sanyo Chemical Industries, Ltd.), and the like. The compositional analysis for the interlayer can be performed by, for example, obliquely cutting the interlayer by using a Surface And Interfacial Cutting Analysis System (SAICAS) (registered trademark, manufactured by DAYPLA WINTES CO., LTD.) and performing surface analysis such as Time-of-Flight Secondary Ion Mass Spectrometry (TOF-SIMS) on the cutting surface.

For the purpose of improving blocking properties and lubricating properties of the interlayer, the interlayer may contain particles. Examples of the particles include inorganic particles such as silica, alumina, and other metal oxides, organic particles such as cross-linked polymer particles of a polymethyl methacrylate resin (PMMA) or styrene, and the like. Specifically, examples of the particles include silica sol containing colloidal silica particles having an average particle size of 30 nm to 300 nm. The average particle size refers to a volume-average particle size and is a value measured by laser analysis/scattering-type particle size distribution analysis. As a device for measuring the average particle size, it is possible to use a laser analysis/scattering-type particle size distribution analyzer LA950 [manufactured by HORIBA, Ltd.]. The average particle size shown in the examples which will be described later is a value measured by this device.

The modulus of elasticity of the interlayer tends to be increased by using, for example, a resin having a great molecular weight and decreased by using a resin having a small molecular weight. Furthermore, the modulus of elasticity of the interlayer tends to be increased by increasing the amount of the cross-linking agent and decreased by reducing the amount of the cross-linking agent. Regarding the particles, the modulus of elasticity of the interlayer tends to be increased by increasing the amount of the particles and decreased by reducing the amount of the particles. By appropriately setting the constituent components of the interlayer or the mixing ratio in consideration of the aforementioned points, the modulus of elasticity of the interlayer can be adjusted.

In addition, a compound having a barbituric acid structure can be optionally added to the interlayer. The barbituric acid structure has the following structure.

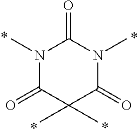

(In the Above Structure, the Position Indicated by * is a Binding Position in which the Structure Binds to Other Atoms or Structures.)

Hereinafter, the compound having a barbituric acid structure will be described as a barbituric acid-based compound as well. By providing the interlayer containing the barbituric acid-based compound between the base material and the adhesive layer, the occurrence of cracking at the time of cutting process can be further inhibited, and this is a novel knowledge acquired by the inventors of the present invention.

As a specific aspect of the barbituric acid-based compound, a compound represented by the following Formula (1) can be exemplified.

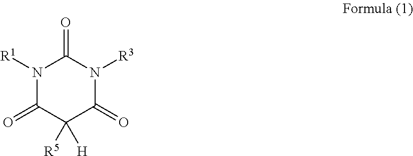

(In Formula (1), R¹ and R³ each independently represent a hydrogen atom, a linear alkyl group having 1 to 20 carbon atoms, a branched alkyl group having 3 to 20 carbon atoms, a cycloalkyl group having 3 to 20 carbon atoms, an alkenyl group having 2 to 20 carbon atoms, or an aromatic group having 6 to 20 carbon atoms, and R⁵ represents a substituent.)

Hereinafter, the compound represented by Formula (1) will be more specifically described. In the present invention and the present specification, in a case where there is no description regarding whether a group (atomic group) is substituted or unsubstituted, the group includes both of a group which does not have a substituent and a group which has a substituent. For example, an “alkyl group” includes not only an alkyl group which does not have a substituent (unsubstituted alkyl group) but also an alkyl group which has a substituent (substituted alkyl group).

The preferred range of R¹ and R³ in Formula (1) will be described.

The linear alkyl group having 1 to 20 carbon atoms or the branched alkyl group having 3 to 20 carbon atoms is preferably a linear alkyl group having 1 to 10 carbon atoms or a branched alkyl group having 3 to 20 carbon atoms, more preferably a linear alkyl group having 1 to 5 carbon atoms or a branched alkyl group having 3 to 5 carbon atoms, even more preferably a linear alkyl group having 1 to 3 carbon atoms, and particularly preferably a methyl group or an ethyl group.

The aforementioned cyclolakyl group having 3 to 20 carbon atoms is preferably a cycloalkyl group having 3 to 10 carbon atoms, and more preferably a cycloalkyl group having 4 to 8 carbon atoms. Specific examples of the cycloalkyl group include a cyclopropyl group, a cyclopentyl group, and a cyclohexyl group. Among these, a cyclohexyl group is particularly preferable. The cycloalkyl group refers to a cyclic alkyl group.

The aforementioned alkenyl group having 2 to 20 carbon atoms is preferably an alkenyl group having 2 to 10 carbon atoms, and more preferably an alkenyl group having 2 to 5 carbon atoms.

The aforementioned aromatic group having 6 to 20 carbon atoms may be an aromatic hydrocarbon group or an aromatic heterocyclic ring group, but is preferably an aromatic hydrocarbon group. As the aromatic hydrocarbon group, a phenyl group or a naphthyl group is preferable, and a phenyl group is more preferable.

R¹ and R³ may have a substituent. The substituent is not particularly limited. Examples of the substituent include an alkyl group (preferably an alkyl group having 1 to 10 carbon atoms, such as a methyl group, an ethyl group, an isopropyl group, a t-butyl group, a pentyl group, a heptyl group, a 1-ethylpentyl group, a benzyl group, a 2-ethoxyethyl group, or a 1-carboxymethyl group), an alkenyl group (preferably an alkenyl group having 2 to 20 carbon atoms, such as a vinyl group, an allyl group, or an oleyl group), an alkynyl group (preferably an alkynyl group having 2 to 20 carbon atoms, such as an ethynyl group, a butadinyl group, or a phenylethynyl group), a cycloalkyl group (preferably a cycloalkyl group having 3 to 20 carbon atoms, such as a cyclopropyl group, a cyclopentyl group, a cyclohexyl group, or a 4-methylcyclohexyl group), an aryl group (preferably an aryl group having 6 to 26 carbon atoms, such as a phenyl group, a 1-naphthyl group, a 4-methoxyphenyl group, a 2-chlorophenyl group, or a 3-methylphenyl group), a heterocyclic group (preferably a heterocyclic group having 0 to 20 carbon atoms, in which the heteroatom constituting the ring is preferably an oxygen atom, a nitrogen atom, or a sulfur atom; the heterocyclic group may be a 5- or 6-membered ring and condensed with a benzene ring or a hetero ring, and the ring may be a saturated ring, an unsaturated ring, or an aromatic ring; examples of the heterocyclic group include a 2-pyridyl group, a 4-pyridyl group, a 2-imidazolyl group, a 2-benzimidazolyl group, a 2-thiazolyl group, and a 2-oxazolyl group), an alkoxy group (preferably an alkoxy group having 1 to 20 carbon atoms, such as a methoxy group, an ethoxy group, an isopropyloxy group, or a benzyloxy group), an aryloxy group (preferably an aryloxy group having 6 to 26 carbon atoms, such as a phenoxy group, a 1-naphthyloxy group, a 3-methylphenoxy group, or a 4-methoxyphenoxy group),

an alkylthio group (preferably an alkylthio group having 1 to 20 carbon atoms, such as a methylthio group, an ethylthio group, an isopropylthio group, or a benzylthio group), an arylthio group (preferably an arylthio group having 6 to 26 carbon atoms, such as a phenylthio group, a 1-naphthylthio group, a 3-methylphenylthio group, or a 4-methoxyphenylthio group), an acyl group (including an alkyl carbonyl group, an alkenyl carbonyl group, an aryl carbonyl group, and a heterocyclic carbonyl group and preferably having 20 or less carbon atoms; examples of the acyl group include an acetyl group, a pivalolyl group, an acryloyl group, a methacryloyl group, a benzoyl group, and a nicotinoyl group), an aryloylalkyl group, an alkoxycarbonyl group (preferably an alkoxycarbonyl group having 2 to 20 carbon atoms, such as an ethoxycarbonyl group or a 2-ethoxyhexyloxycarbonyl group), an aryloxycarbonyl group (preferably an aryloxycarbonyl group having 7 to 20 carbon atoms, such as a phenyloxycarbonyl group or a naphthyloxycarbonyl group), an amino group (including an amino group, an alkylamino group, an arylamino group, and a heterocyclic amino group and preferably having 0 to 20 carbon atoms; examples of the amino group include an amino group, a N,N-dimethylamino group, a N,N-diethylamino group, a N-ethylamino group, an anilino group, a 1-pyrrolidinyl group, a piperidino group, and a morphonyl group), a sulfonamide group (preferably a sulfonamide group having 0 to 20 carbon atoms, such as a N,N-dimethylsulfonamide group or a N-diphenylsulfonamide group), a sulfamoyl group (preferably a sulfamoyl group having 0 to 20 carbon atoms, such as a N,N-diemethylsulfamoyl group or a N-phenylsulfamoyl group), an acyloxy group (preferably an acyloxy group having 1 to 20 carbon atoms, such as an acetyloxy group or a benzoyloxy group), a carbamoyl group (preferably a carbamoyl group having 1 to 20 carbon atoms, such as a N,N-dimethylcarbamoyl group or a N-phenylcarbamoyl group), an acylamino group (preferably an acylamino group having 1 to 20 carbon atoms, such as an acetylamino group, an acryloylamino group, a benzoylamino group, or a nicotinamide group), a cyano group, a hydroxyl group, a mercapto group, and a halogen atom (such as a fluorine atom, a chlorine atom, a bromine atom, or an iodine atom). The above substituents that R¹ and R³ can have may further have the above substituents.

Among the substituents that each of the groups represented by R¹ and R³ may have, an alkyl group, an aryl group, an alkoxy group, and an acyl group are preferable.

R⁵ represents a substituent. The substituent is not particularly limited, and examples thereof include those exemplified above as the substituents that R¹ and R³ have. R⁵ is preferably an alkyl group (preferably an alkyl group having 1 to 5 carbon atoms), an aryl group, or an aralkyl group, more preferably an aryl group or an aralkyl group, and even more preferably a phenyl group or a benzyl group.

In the present invention, it is particularly preferable that R⁵ is a substituent which has an aromatic ring and demonstrates a polar effect. Such a substituent may be further substituted with a substituent. The substituent represented by R⁵ that has an aromatic ring and demonstrates a polar effect is preferably a structure which demonstrates a polar effect so as to contribute to the stabilization by trapping radicals. Although a substituent demonstrating an effect of causing polarization can be used as the structure demonstrating a polar effect, R⁵ is preferably a substituent which has an aromatic ring and demonstrates a polar effect.

As the substituent which has an aromatic ring and demonstrates a polar effect, an aromatic group having 6 to 20 carbon atoms or an aralkyl group having 7 to 20 carbon atoms is preferable, an aromatic group having 6 to 14 carbon atoms or an aralkyl group having 7 to 15 carbon atoms is more preferable, and an aromatic group having 6 to 10 carbon atoms or an aralkyl group having 7 to 11 carbon atoms is even more preferable. Herein, the number of carbon atoms is the total number of carbon atoms. The aralkyl group is a compound in which an aryl group is substituted with an alkyl group. Among the aralkyl groups, the compounds in which one or two aryl groups are substituted with an alkyl group are preferable (in a case where two aryl groups are substituted, they are preferably substituted with the same carbon atom). Examples of the substituent which has an aromatic ring and demonstrates a polar effect include a phenyl group, a naphthyl group, an anthracenyl group, a benzyl group, a diphenylmethyl group, and the like.

Examples of R⁵ include a phenyl group, a p-chlorophenyl group, a p-toluyl group, a benzyl group, an ethylphenyl group, an m-toluyl group, a p-methoxyphenyl group, a p-trifluoromethylphenyl group, a p-methylbenzyl group, a diphenylmethyl group, a methylbenzoyl phenylmethyl group, and the like.

Among the compounds represented by Formula (1), the following can be exemplified as preferred compounds.
A compound in which at least one of R¹, R³, and R⁵ has a substituent demonstrating a polar effect
A compound in which one of R¹ and R³ is an aralkyl group

The aralkyl group is a compound in which an aryl group is substituted with an alkyl group. Among the aralkyl groups, the compounds in which one or two aryl groups are substituted with an alkyl group are preferable (in a case where two aryl groups are substituted, they are preferably substituted with the same carbon atom). Furthermore, the compounds in which an aryl group and an acyl group (preferably an aryloyl group) are substituted with an alkyl group are also preferable.
A compound in which one of R¹ and R³ is a group containing a cycloalkyl group, and preferably a compound in which a group containing a cycloalkyl group is a cycloalkyl group
A compound in which R¹ and R³ are a hydrogen atom, and particularly, a compound in which R¹ and R³ are hydrogen atoms and R⁵ is an alkyl group having 1 to 3 carbon atoms

In a preferred aspect of the compound represented by Formula (1), at least one of R¹, R³, and R⁵ is a water-soluble group or contains a water-soluble functional group, and both R¹ and R are a hydrogen atom. The compound represented by Formula (1) according to the above aspect is excellently compatible with polyvinyl alcohol. Therefore, this compound is particularly preferable in an aspect in which the resin contained in the interlayer is polyvinyl alcohol.

The water-soluble functional group is a group which contributes to the water solubility of the compound represented by Formula (1). Specific examples of the water-soluble functional group that the compound represented by Formula (1) can have include a sulfo group (or a salt thereof), a carboxy group (or a salt thereof), a hydroxyl group, a mercapto group, an amino group, an amnonio group, a sulfonamide group, an acylsulfamoyl group, a sulfonyl sulfamoyl group, an active methine group, and substituents containing these groups. Among these, the groups such as a sulfo group (or a salt thereof), a carboxy group (or a salt thereof), a hydroxyl group, and an amino group are preferable.

The carboxyl group, the sulfonamide group, and the sulfo group may be in a salt state. Examples of the counterion forming the salt include an ammonium ion, an alkali metal ion (such as a lithium ion, a sodium ion, or a potassium ion), and an organic cation (such as a tetramethylammonium ion, a tetramethylguanidium ion, or a tetramethylsulfonium ion). Among the counterions, an alkali metal salt is preferable.

As the group which imparts water solubility to the compound represented by Formula (1), an aspect in which both of R¹ and R³ are a hydrogen atom can be exemplified, because when this constitution is adopted, the water solubility of the compound represented by Formula (1) is improved.

The compound represented by Formula (1) may be used in the form of a hydrate, a solvate, or a salt. In the present invention and the present specification, a hydrate may contain an organic solvate, and a solvate may contain water. That is, the “hydrate” and “solvate” include a mixed solvate containing both water and an organic solvate.

Examples of the solvent that the solvate contains include all of the general organic solvents. Specifically, examples of the solvent include an alcohol (such as methanol, ethanol, 2-propanol, 1-butanol, 1-methoxy-2-propanol, or t-butanol), an ester (such as ethyl acetate), a hydrocarbon (the hydrocarbon may be an aliphatic hydrocarbon or an aromatic hydrocarbon, such as toluene, hexane, or heptane), an ether (such as diethyl ether or tetrahydrofuran), a nitrile (such as acetonitrile), a ketone (such as acetone or 2-butanone), and the like. The solvent is preferably a solvate of an alcohol, and more preferably methanol, ethanol, 2-propanol, or 1-butanol. These solvents may be a reaction solvent which is used at the time of synthesis of the compound represented by Formula (1) according to the present invention, a solvent which is used at the time of crystallization and purification following the synthesis, or a mixture of these.

Two or more kinds of solvents may be used simultaneously. Furthermore, the solvent may contain water and a solvent (for example, water and alcohol (such as methanol, ethanol, or t-butanol), or the like).

As a salt, an acid addition salt formed using an inorganic or organic acid is contained in the compound. Examples of the inorganic acid include a hydrohalic acid (hydrochloric acid or hydrobromic acid), sulfuric acid, phosphoric acid, and the like. Examples of the organic acid include acetic acid, trifluoroacetic acid, oxalic acid, citric acid, alkane sulfonic acid (methane sulfonic acid), and aryl sulfonic acid (benzene sulfonic acid, 4-toluene sulfonic acid, or 1,5-naphthalene sulfonic acid).

Examples of the salt include salts formed when an acidic portion present in the parent compound is substituted with a metal ion (such as an alkali metal salt including a sodium or potassium salt, an alkaline earth metal salt including a calcium or magnesium salt, an ammonium salt alkali metal ion, an alkaline earth metal ion, or an aluminum ion) or adjusted using an organic base (ethanolamine, diethanolamine, triethanolamine, morpholine, or piperidine). However, the salt is not limited to these. Among these, a sodium salt and a potassium salt are preferable.

Regarding the form of a salt of the compound represented by Formula (1), for example, in a case where the salt is a sodium salt, it includes a tautomer as illustrated below. However, in the present invention and the present specification, the salt and the tautomer are not differentiated and regarded as the same compound. In specific examples, the compound is described as the structure of either of them.

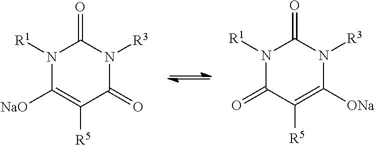

The degree of hydrophilicity of the compound represented by Formula (1) can be represented by a CLogP value. P in the CLogP value represents a partition coefficient in an n-octanol/water system, and can be measured using n-octanol and water. The partition coefficient can be determined as an estimated CLogP value by using a CLogP value estimation program (CLOGP program incorporated into PC Models of Daylight Chemical Information Systems). The CLogP value is preferably within a range of −8.0 to 12.0, more preferably within a range of −5.0 to 10.0, and even more preferably within a range of −5.0 to 8.0.

Specific examples of the compound represented by Formula (1) or the like will be shown below, but the present invention is not limited thereto. In the following example compounds, Me represents a methyl group.

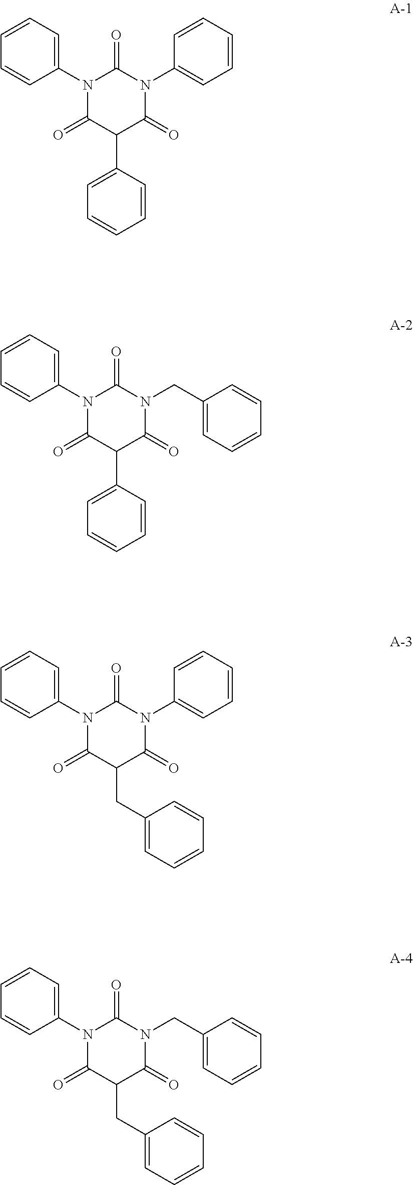 [SMILES: O=C1C(c2ccccc2)C(=O)N(c2ccccc2)C(=O)N1c1ccccc1 ; O=C1C(c2ccccc2)C(=O)N(c2ccccc2)C(=O)N1Cc1ccccc1 ; O=C1C(Cc2ccccc2)C(=O)N(c2ccccc2)C(=O)N1c1ccccc1 ; O=C1C(Cc2ccccc2)C(=O)N(c2ccccc2)C(=O)N1Cc1ccccc1]

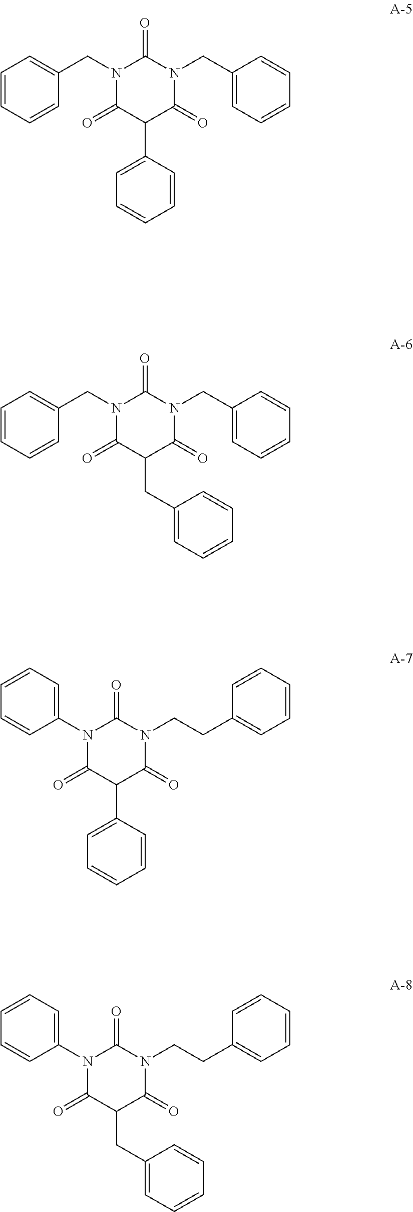 [SMILES: O=C1C(c2ccccc2)C(=O)N(Cc2ccccc2)C(=O)N1Cc1ccccc1 ; O=C1C(Cc2ccccc2)C(=O)N(Cc2ccccc2)C(=O)N1Cc1ccccc1 ; O=C1C(c2ccccc2)C(=O)N(c2ccccc2)C(=O)N1CCc1ccccc1 ; O=C1C(Cc2ccccc2)C(=O)N(c2ccccc2)C(=O)N1CCc1ccccc1]

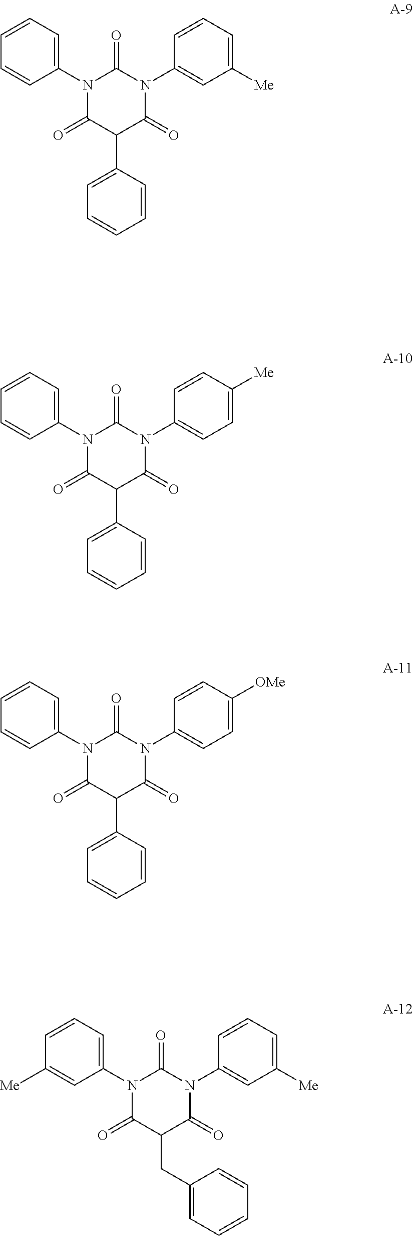 [SMILES: Cc1cccc(N2C(=O)C(c3ccccc3)C(=O)N(c3ccccc3)C2=O)c1 ; Cc1ccc(N2C(=O)C(c3ccccc3)C(=O)N(c3ccccc3)C2=O)cc1 ; COc1ccc(N2C(=O)C(c3ccccc3)C(=O)N(c3ccccc3)C2=O)cc1 ; Cc1cccc(N2C(=O)C(Cc3ccccc3)C(=O)N(c3cccc(C)c3)C2=O)c1]

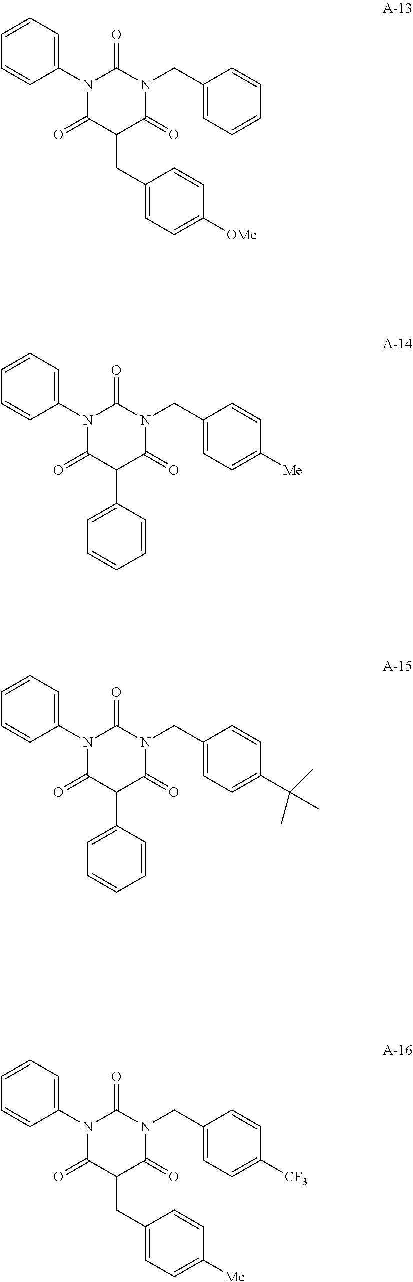 [SMILES: COc1ccc(CC2C(=O)N(Cc3ccccc3)C(=O)N(c3ccccc3)C2=O)cc1 ; Cc1ccc(CN2C(=O)C(c3ccccc3)C(=O)N(c3ccccc3)C2=O)cc1 ; CC(C)(C)c1ccc(CN2C(=O)C(c3ccccc3)C(=O)N(c3ccccc3)C2=O)cc1 ; Cc1ccc(CC2C(=O)N(Cc3ccc(C(F)(F)F)cc3)C(=O)N(c3ccccc3)C2=O)cc1]

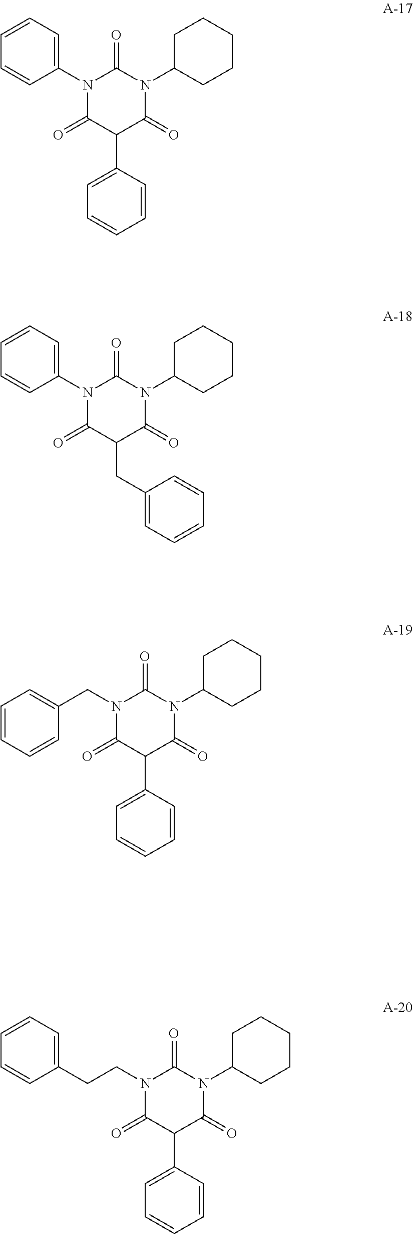 [SMILES: O=C1C(c2ccccc2)C(=O)N(C2CCCCC2)C(=O)N1c1ccccc1 ; O=C1C(Cc2ccccc2)C(=O)N(C2CCCCC2)C(=O)N1c1ccccc1 ; O=C1C(c2ccccc2)C(=O)N(C2CCCCC2)C(=O)N1Cc1ccccc1 ; O=C1C(c2ccccc2)C(=O)N(C2CCCCC2)C(=O)N1CCc1ccccc1]

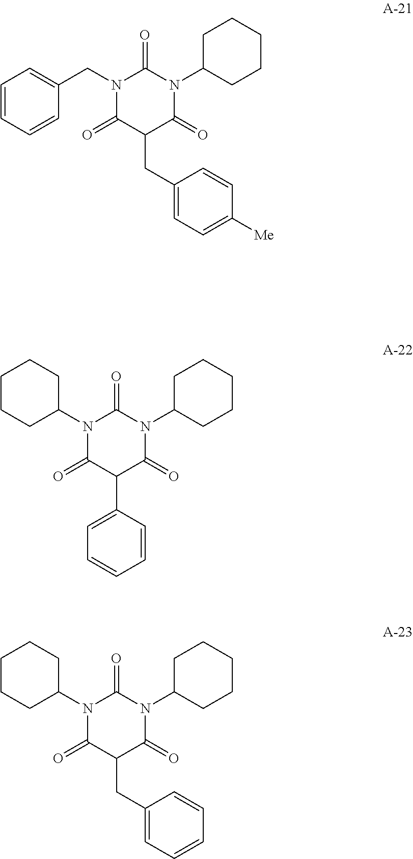 [SMILES: Cc1ccc(CC2C(=O)N(Cc3ccccc3)C(=O)N(C3CCCCC3)C2=O)cc1 ; O=C1C(c2ccccc2)C(=O)N(C2CCCCC2)C(=O)N1C1CCCCC1 ; O=C1C(Cc2ccccc2)C(=O)N(C2CCCCC2)C(=O)N1C1CCCCC1]

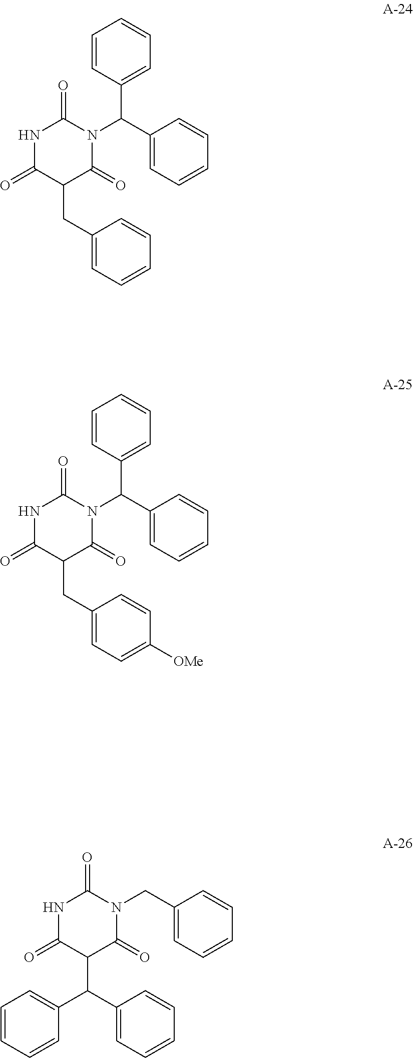 [SMILES: O=C1NC(=O)N(C(c2ccccc2)c2ccccc2)C(=O)C1Cc1ccccc1 ; COc1ccc(CC2C(=O)NC(=O)N(C(c3ccccc3)c3ccccc3)C2=O)cc1 ; O=C1NC(=O)N(Cc2ccccc2)C(=O)C1C(c1ccccc1)c1ccccc1]

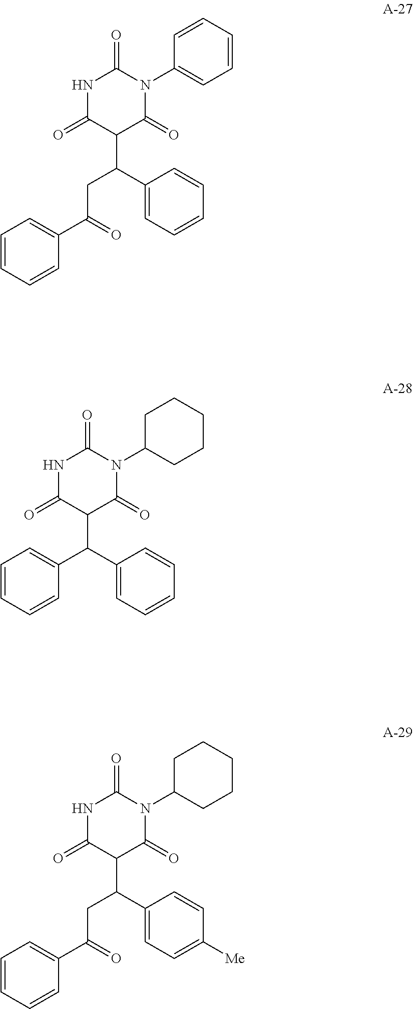 [SMILES: O=C(CC(c1ccccc1)C1C(=O)NC(=O)N(c2ccccc2)C1=O)c1ccccc1 ; O=C1NC(=O)N(C2CCCCC2)C(=O)C1C(c1ccccc1)c1ccccc1 ; Cc1ccc(C(CC(=O)c2ccccc2)C2C(=O)NC(=O)N(C3CCCCC3)C2=O)cc1]

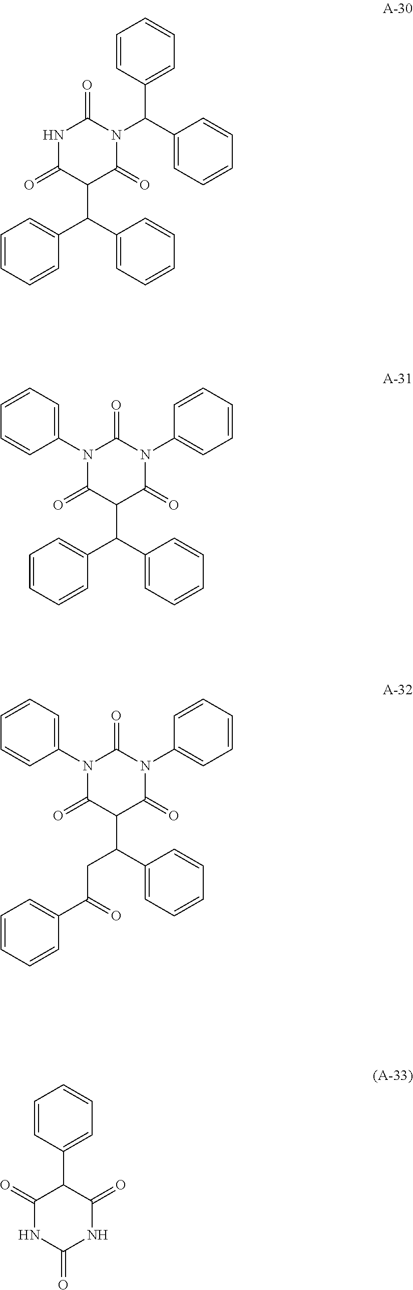 [SMILES: O=C1NC(=O)N(C(c2ccccc2)c2ccccc2)C(=O)C1C(c1ccccc1)c1ccccc1 ; O=C1C(C(c2ccccc2)c2ccccc2)C(=O)N(c2ccccc2)C(=O)N1c1ccccc1 ; O=C(CC(c1ccccc1)C1C(=O)N(c2ccccc2)C(=O)N(c2ccccc2)C1=O)c1ccccc1 ; O=C1NC(=O)C(c2ccccc2)C(=O)N1]

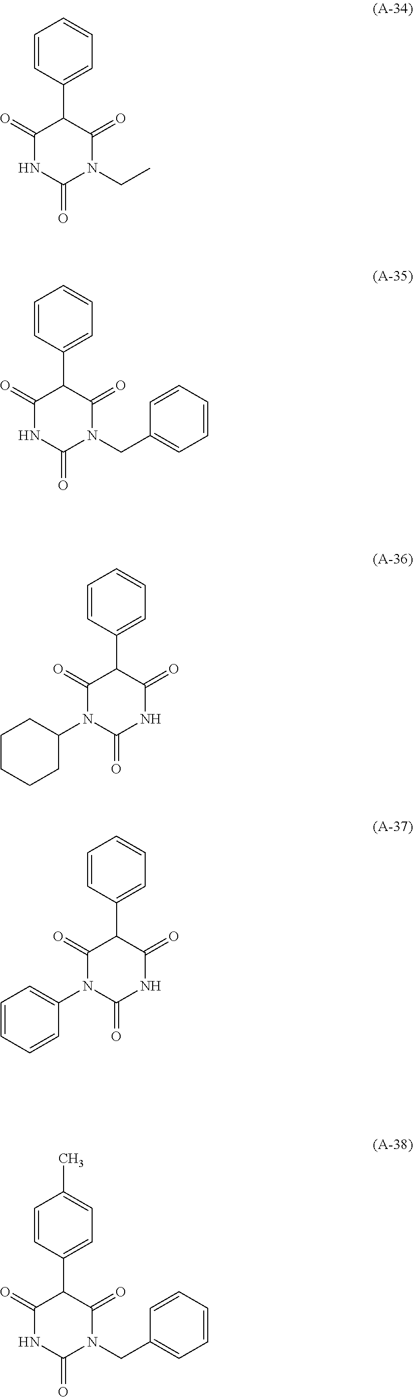 [SMILES: CCN1C(=O)NC(=O)C(c2ccccc2)C1=O ; O=C1NC(=O)N(Cc2ccccc2)C(=O)C1c1ccccc1 ; O=C1NC(=O)N(C2CCCCC2)C(=O)C1c1ccccc1 ; O=C1NC(=O)N(c2ccccc2)C(=O)C1c1ccccc1 ; Cc1ccc(C2C(=O)NC(=O)N(Cc3ccccc3)C2=O)cc1]

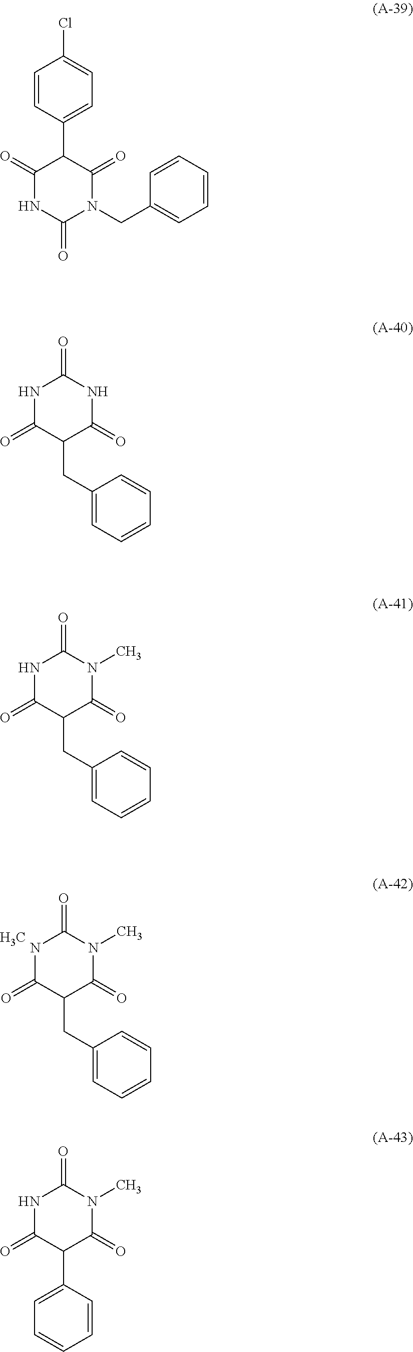

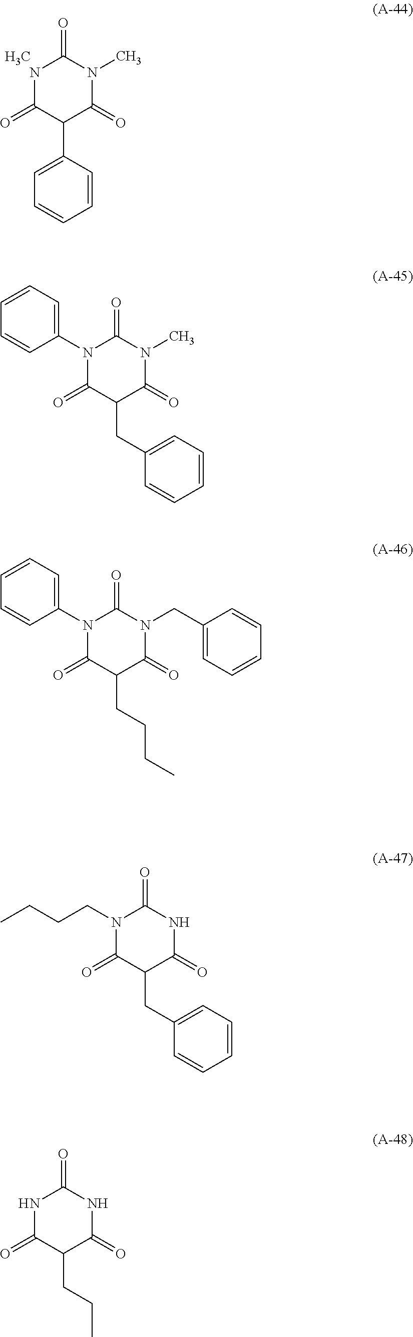

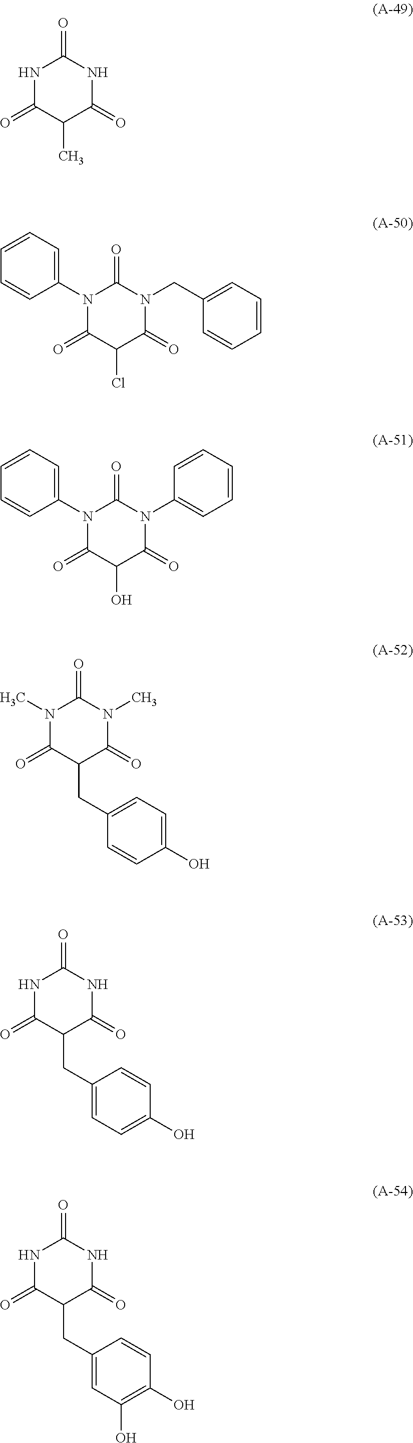

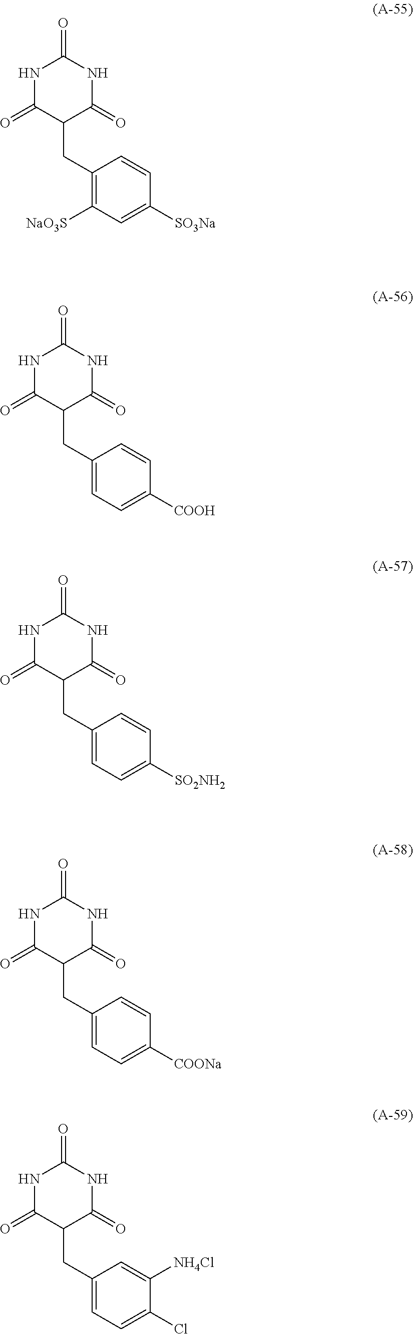

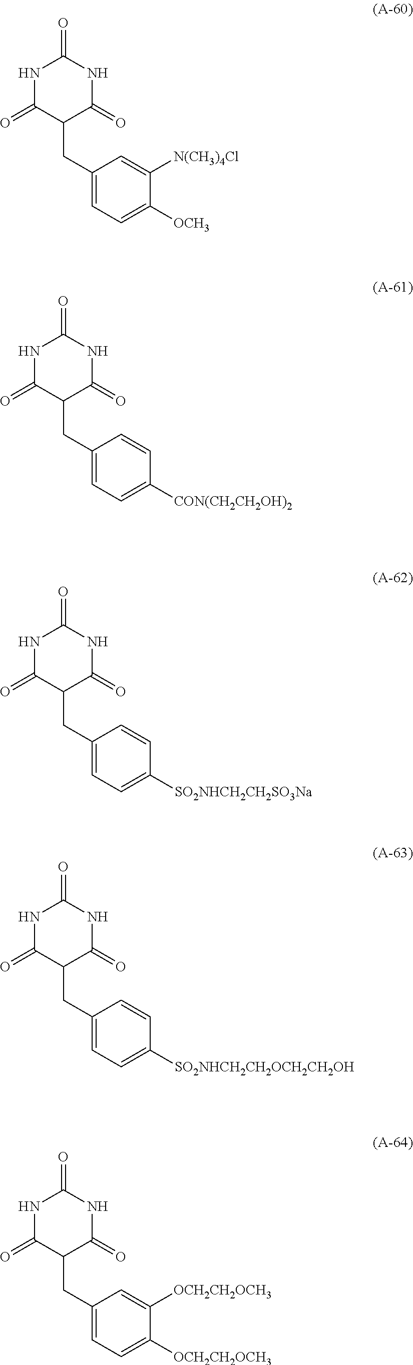

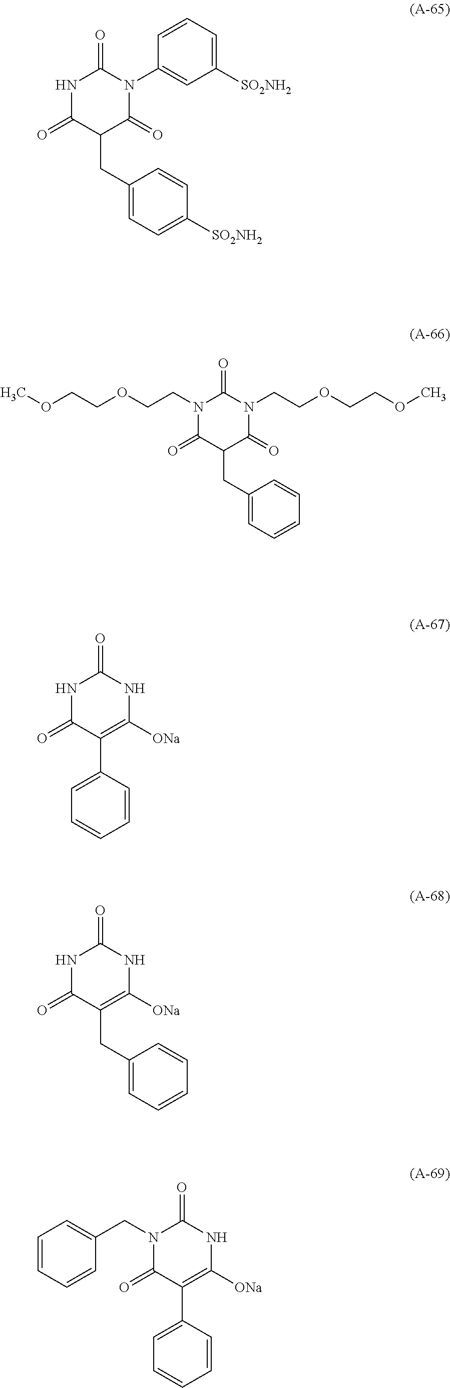

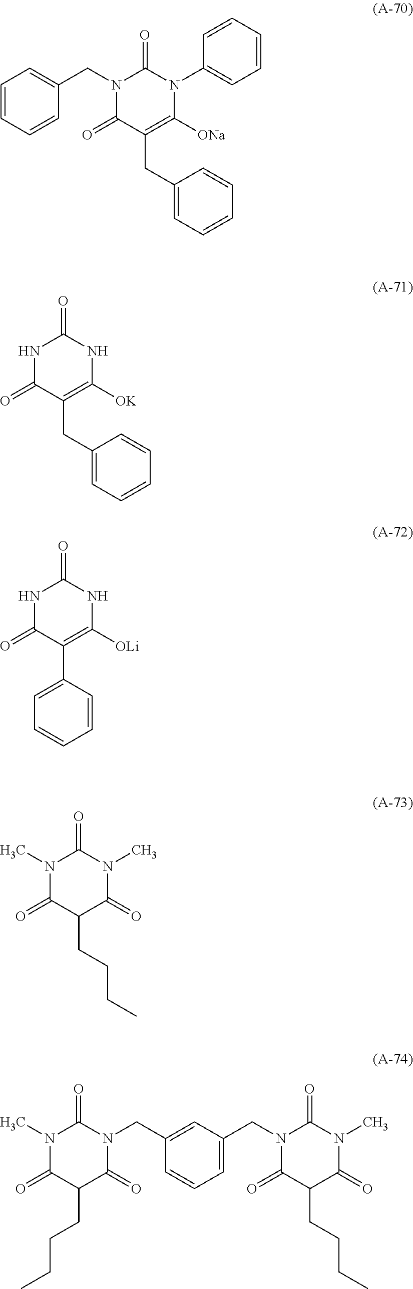

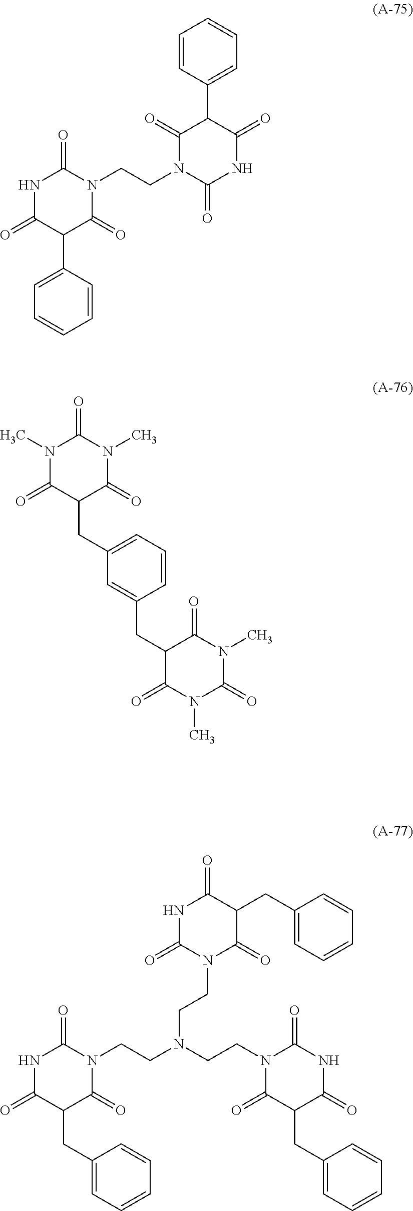 [SMILES: O=C1NC(=O)N(CCN2C(=O)NC(=O)C(c3ccccc3)C2=O)C(=O)C1c1ccccc1 ; CN1C(=O)C(Cc2cccc(CC3C(=O)N(C)C(=O)N(C)C3=O)c2)C(=O)N(C)C1=O ; O=C1NC(=O)N(CCN(CCN2C(=O)NC(=O)C(Cc3ccccc3)C2=O)CCN2C(=O)NC(=O)C(Cc3ccccc3)C2=O)C(=O)C1Cc1ccccc1]

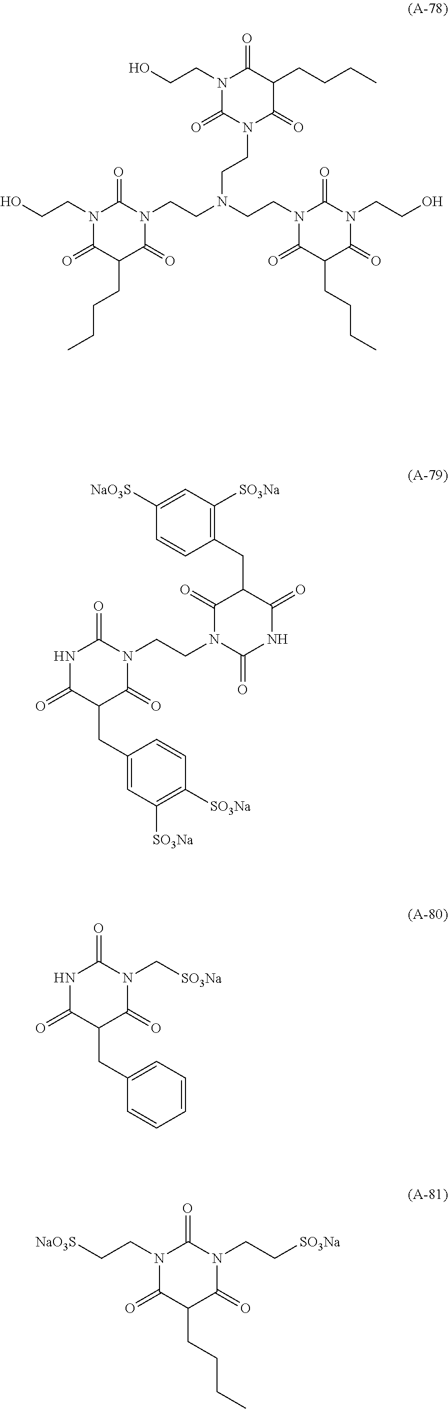

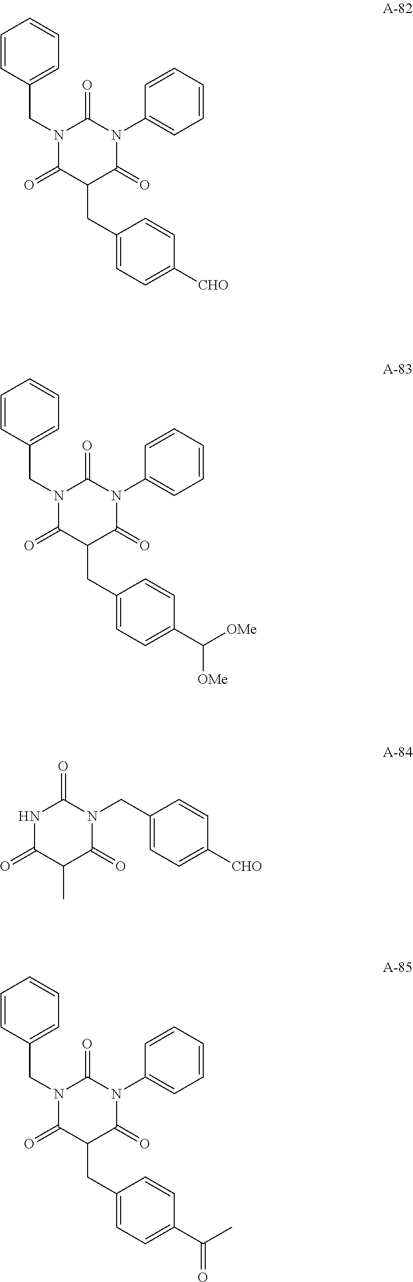 [SMILES: O=Cc1ccc(CC2C(=O)N(Cc3ccccc3)C(=O)N(c3ccccc3)C2=O)cc1 ; COC(OC)c1ccc(CC2C(=O)N(Cc3ccccc3)C(=O)N(c3ccccc3)C2=O)cc1 ; CC1C(=O)NC(=O)N(Cc2ccc(C=O)cc2)C1=O ; CC(=O)c1ccc(CC2C(=O)N(Cc3ccccc3)C(=O)N(c3ccccc3)C2=O)cc1]

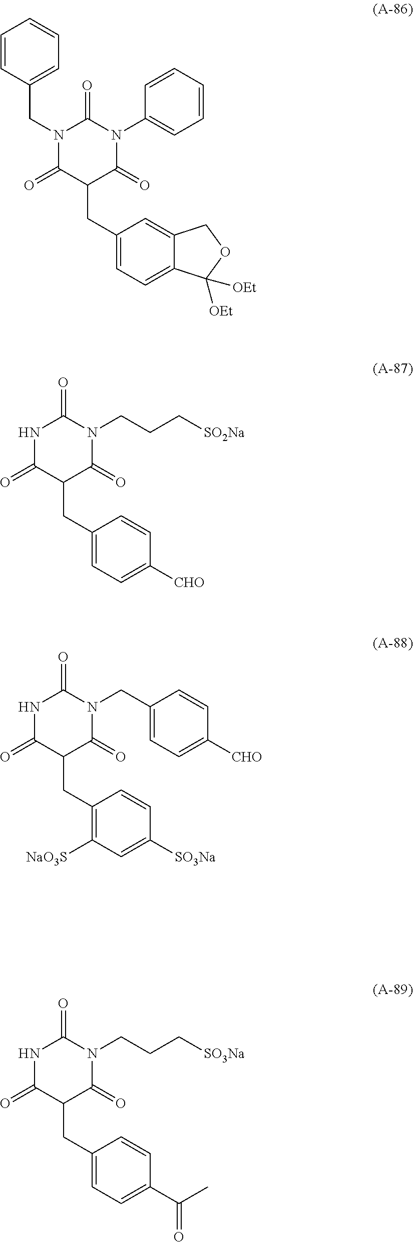

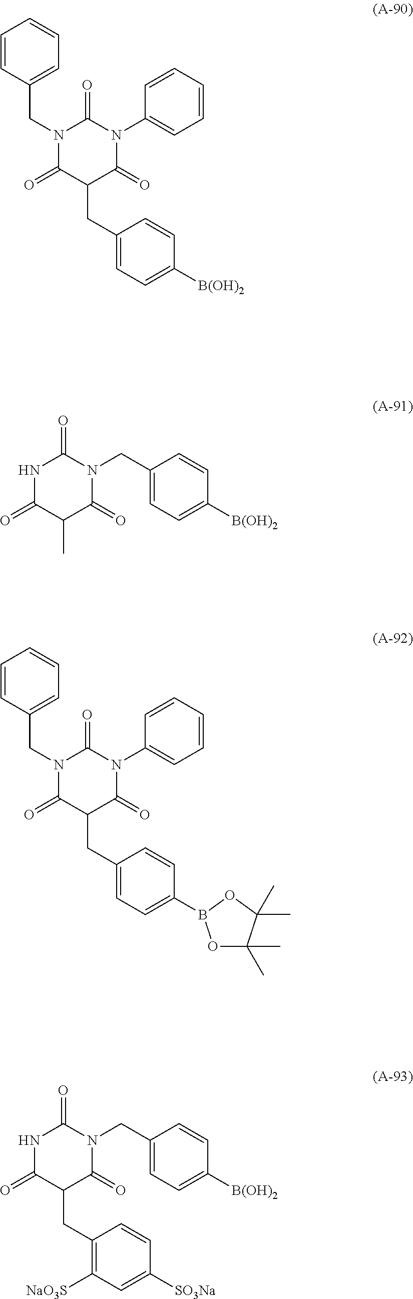

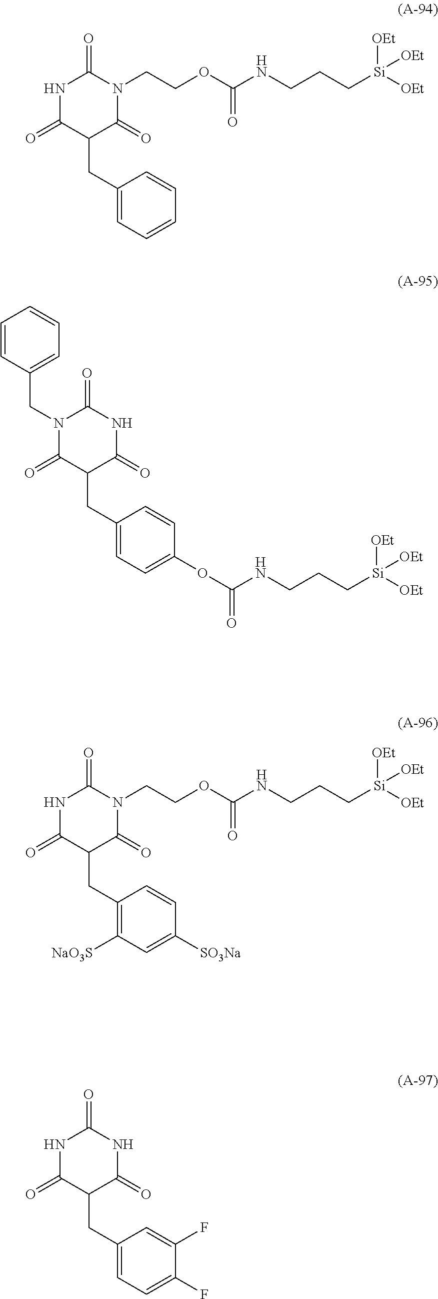

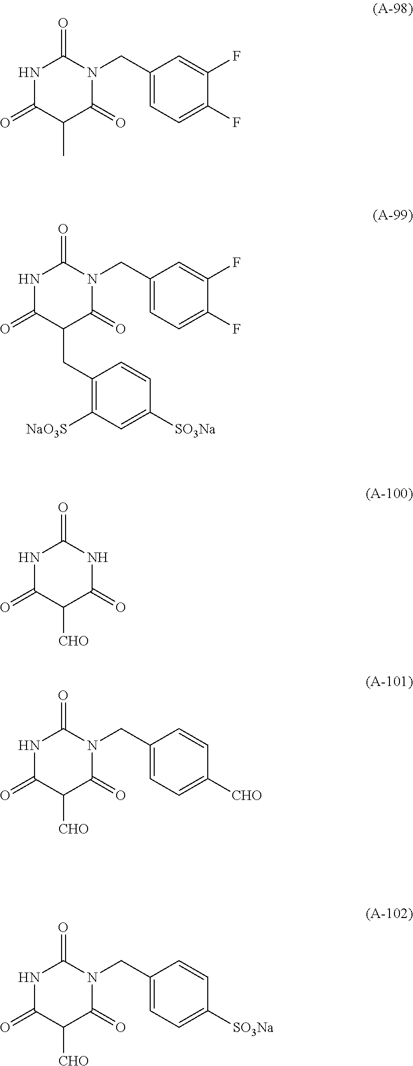

The compound represented by Formula (1) has a barbituric acid structure. Therefore, the compound can be synthesized using a barbituric acid synthesis method of condensing a urea derivative with a malonic acid derivative. A compound having two substituents on a nitrogen atom can be obtained by heating N,N-disubstituted urea and malonic acid chloride or by heating malonic acid and an activator such as acetic anhydride in combination. As the synthesis method, it is possible to preferably use the methods described in Journal of the American Chemical Society, Vol. 61, page 1015 (1939), Journal of Medicinal Chemistry, Vol. 54, page 2409 (2011), Tetrahedron Letters, Vol. 40, page 8029 (1999), WO2007/150011A, and the like.

The maloinc acid used for condensation may be unsubstituted or have a substituent. If the malonic acid having a substituent corresponding to R⁵ is used, the compound represented by Formula (1) can be synthesized by constructing a barbituric acid. When the unsubstituted malonic acid is condensed with a urea derivative, a barbituric acid in which the 5-position is unsubstituted is obtained. Accordingly, by modifying the 5-position, the compound represented by Formula (1) may be synthesized.

As the method for modifying the 5-position, it is possible to use a nucleophilic substitution reaction with halogenated alkyl or an addition reaction such as a Michael addition reaction. Furthermore, it is also possible to preferably use a method of generating an alkylidene or arylidene compound through dehydrocondensation with an aldehyde or ketone and then reducing a double bond. As this method, for example, it is possible to preferably use the methods described in Organic Letters, Vol. 5, page 2887 (2003), Journal of Medicinal Chemistry, Vol. 17, page 1194 (1974), Journal of Organic Chemistry, Vol. 68, page 4684 (2003), Tetrahedron Letters, Vol. 42, page 4103 (2001), Journal of the American Chemical Society, Vol. 119, page 12849 (1997), Tetrahedron Letters, Vol. 28, page 4173 (1987), and the like.

The synthesis method of the compound represented by Formula (1) is not limited to the above.

As the barbituric acid-based compound, the following compounds can be exemplified.

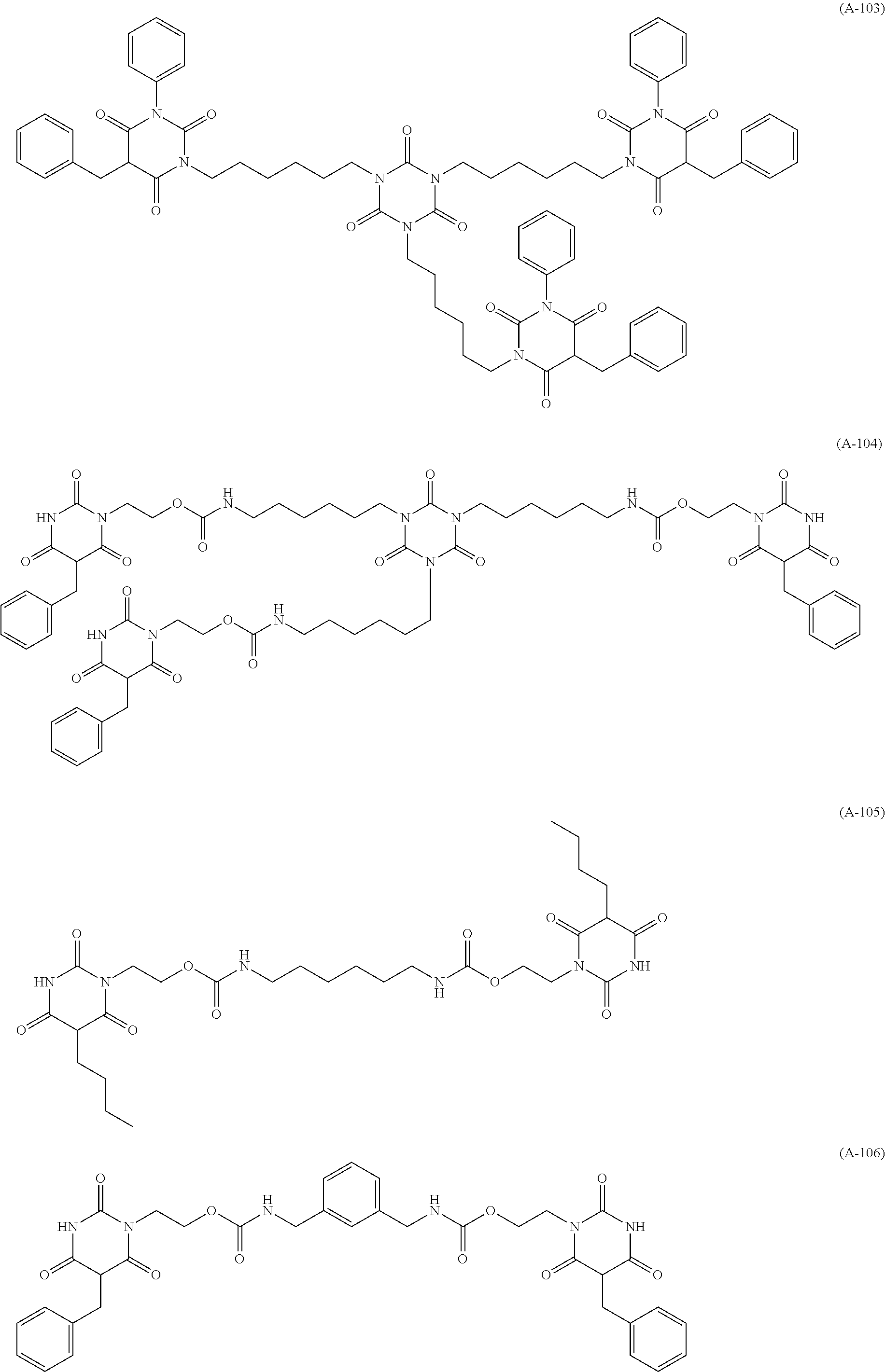

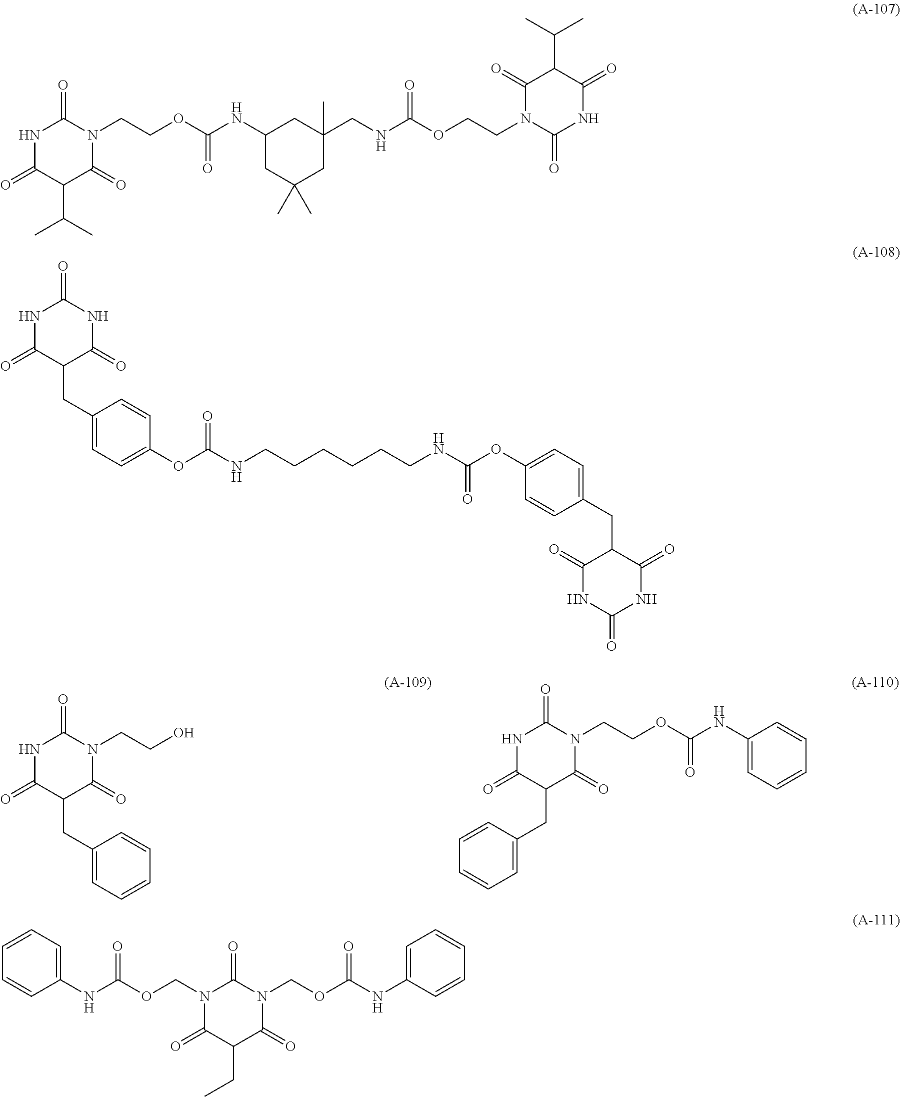

TABLE 1

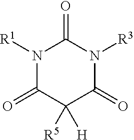

| Compound No. | R¹ | R³ | R⁵ |
|---|---|---|---|
| BA-101 | H | H | C₂H₅ |
| BA-102 | H | H | C₃H₇ |
| BA-103 | H | H | CHPh₂ |
| BA-104 | H | H | CH₂C₆H₄(p-CH₃) |
| BA-105 | H | H | CH₂C₆H₄(p-OCH₃) |
| BA-106 | H | H | CH₂C₆H₄(p-Cl) |
| BA-107 | H | CH₂Ph | NHCOCH₃ |
| BA-108 | H | CH₂Ph | NHCHO |
| BA-109 | H | CH₂Ph | iC₃H₇ |
| BA-110 | H | CH₂Ph | sec-C₄H₉ |
| BA-111 | H | CH₂Ph | tert-C₄H₉ |
| BA-112 | H | CH₂Ph | CH₂Ph |
| BA-113 | H | CHPh₂ | Ph |
| BA-114 | H | cHex | cHex |
| BA-115 | Ph | Ph | cPentyl |
| BA-116 | Ph | Ph | CH₂-cPentyl |
| BA-117 | Ph | Ph | n-C₄H₉ |
| BA-118 | Ph | Ph | CH(CH₃)Ph |
| BA-119 | Ph | Ph | CH₂CH═CH₂ |
| BA-120 | Ph | C₆H₄(p-OCH₃) | CH₂Ph |
| BA-121 | Ph | CH₂ph | CH₂CH₂Ph |
| BA-122 | Ph | Ph | CH₂CH₂CN |
| BA-123 | Ph | Ph | CH₂CH₂COOC₂H₅ |
| BA-124 | Ph | Ph | OCH₃ |

In Table 1, Ph represents a phenyl group, cHex represents a cyclohexyl group, cPentyl represents a cyclopentyl group, C₆H₄ represents a phenylene group, the group in the parenthesis as C₆H₄(p-CH₃) represents a substituent for a phenyl group, and “p-” shows that the substituent is in the p-position.

The interlayer can contain one kind or two or more kinds of the barbituric acid-based compound described above. Provided that the total solid content in the interlayer is 100 parts by mass, the content of the barbituric acid-based compound in the interlayer is preferably equal to or greater than 0.01 parts by mass and equal to or less than 30 parts by mass, more preferably equal to or greater than 0.01 parts by mass and equal to or less than 10 parts by mass, and even more preferably equal to or greater than 1 part by mass and equal to or less than 10 parts by mass. In the present invention and the present specification, in a case where two or more kinds of a certain component are used, the content of the certain component refers to the total content of two or more kinds of the certain component.

The interlayer can be formed by coating a coating surface such as a surface of a base material with a composition for forming the interlayer, by a known coating method such as a reverse gravure coating method, a direct gravure coating method, a roll coating method, a reverse roll method, a die coating method, a bar coating method, or a curtain coating method. Regarding the coating method, for example, “Coating Method” (Maki Shoten, Yuji Harazaki, 1979) can be referred to. The coating surface may be subjected to a surface treatment such as a saponification treatment, a corona discharge treatment, or a plasma treatment before coating.

(Thickness of Interlayer)

The thickness of the interlayer described so far is equal to or greater than 0.01 μm, for example. However, the interlayer just needs to have a modulus of elasticity satisfying Expression 1 described above, and the thickness thereof is not particularly limited. From the viewpoint of thinning the polarizing plate, the thickness of the interlayer is preferably equal to or less than 5.00 μm.

(Distribution of Modulus of Elasticity in Interlayer)

As described above, the modulus of elasticity Eb is measured in the middle portion in the thickness direction of the interlayer. The interlayer may have the same modulus of elasticity in each portion within the layer or may have a distribution of modulus of elasticity in which the modulus of elasticity varies within the layer. Regarding the distribution of modulus of elasticity, it is preferable that the modulus of elasticity Eb of the interlayer, a modulus of elasticity E1 of a surface layer portion of the interlayer on the base material side, and a modulus of elasticity E2 of a surface layer portion of the interlayer on the adhesive layer side satisfy the following Expression 3.

E1>Eb>E2 Expression 3

That is, it is preferable that the interlayer have a distribution of modulus of elasticity in which the modulus of elasticity decreases toward the surface layer portion on the adhesive layer side from the surface layer portion on the base material side. The inventors of the present invention assume that the interlayer having such a distribution of modulus of elasticity may enable the stress described above to be more effectively dispersed. For example, if one kind of resin is used as the resin for forming the interlayer, the modulus of elasticity tends to become uniform within the interlayer, and if two or more kinds of different resins are used as the resin, the modulus of elasticity tends to vary within the layer. Accordingly, in order to form an interlayer satisfying Expression 3, it is preferable to use two or more kinds of different resins as the resin.

<Adhesive Layer>

(Component which can Constitute Adhesive Layer)

The adhesive layer is a layer which plays a role in bonding the polarizer layer and the base material to each other through the interlayer. The adhesive layer may be formed using a composition containing a component (pressure sensitive adhesive) that expresses adhesiveness by showing viscosity or formed using a composition containing a component (adhesive) that expresses adhesiveness through drying or a reaction. The adhesive layer formed using a composition (curable composition) containing a component that expresses adhesiveness through a curing reaction is a cured layer obtained by curing the curable composition.

As the pressure sensitive adhesive and the adhesive, a resin can be used. In an aspect, the adhesive layer is preferably a layer in which the resin takes up the layer in a proportion equal to or higher than 50% by mass and preferably in a proportion equal to or higher than 70% by mass. As the resin, a mixture of a plurality of resins may be used. In a case where the resin mixture is used, the aforementioned proportion of the resin refers to the proportion of the resin mixture. Examples of the resin mixture include a mixture of a certain resin and a resin having a structure established by partially modifying the certain resin, a resin mixture obtained by reacting different polymerizable compounds, and the like.

As the pressure sensitive adhesive, for example, it is possible to use various pressure sensitive adhesives such as a solvent-type pressure sensitive adhesive, a non-aqueous emulsion-type pressure sensitive adhesive, an aqueous pressure sensitive adhesive, and a hot-melt pressure sensitive adhesive. Among these, a solvent-type pressure sensitive adhesive containing an acryl-based resin is preferably used, because such a pressure sensitive adhesive exhibits appropriate pressure sensitive adhesiveness at the time of bonding the polarizer layer to the interlayer and has excellent transparency, weather fastness, and heat resistance.

As the adhesive, it is possible to use any adhesive having appropriate properties, form, and adhesion mechanism. Specifically, examples of the adhesive include a water-soluble adhesive, an ultraviolet curable type adhesive, an emulsion-type adhesive, a latex-type adhesive, a mastic adhesive, a multi-layered adhesive, a paste-like adhesive, a foaming adhesive, a supported film adhesive, a thermoplastic adhesive, a hot-melt adhesive, a thermally solidified adhesive, a thermally activated adhesive, a heat-seal adhesive, a thermosetting adhesive, a contact-type adhesive, a pressure-sensitive adhesive, a polymerizable adhesive, a solvent-type adhesive, a solvent-activated adhesive, and the like. As the adhesive, a water-soluble adhesive and an ultraviolet curable type adhesive are preferable. Among these, a water-soluble adhesive is preferably used, because it has excellent transparency, adhesiveness, workability, product quality, and economic feasibility.

The water-soluble adhesive can contain a natural or synthesized water-soluble component such as a protein, starch, or a synthetic resin. Examples of the synthetic resin include a resol resin, a urea resin, a melamine resin, polyethylene oxide, a polyacrylamide, a polyvinyl pyrrolidone, an acrylic acid ester, a methacrylic acid ester, a polyvinyl alcohol resin, and the like. Among these, a water-soluble adhesive containing a polyvinyl alcohol resin is preferably used, because the adhesive exhibits excellent adhesiveness at the time of bonding the polarizer layer to the interlayer.

The adhesive layer can be formed by, for example, coating the surface of at least one of the polarizing layer and the interlayer with a coating solution containing a pressure sensitive adhesive or an adhesive and then drying the coating solution. As the method for preparing the coating solution, any appropriate methods can be adopted. As the coating solution, for example, a commercial solution or dispersion, a coating solution obtained by adding a solvent to a commercial solution or dispersion, or a coating solution obtained by dissolving or dispersing solid content in various solvents may be used.

In an aspect, the adhesive layer can be a cured layer obtained by curing an active energy ray-curable composition. It is preferable that the active energy ray-curable composition for forming an adhesive layer contains, as an active energy ray-curable component, a cationically polymerizable compound such as an epoxy-based compound, more specifically, an epoxy-based compound which does not have an aromatic ring within a molecule as described in JP2004-245925A. Examples of such an epoxy-based compound include a hydrogenated epoxy-based compound, which is obtained by performing nuclear hydrogenation of an aromatic polyhydroxy compound as a raw material of an aromatic epoxy-based compound that is represented by diglycidyl ether of bisphenol A for example and then performing glycidyl etherification of the nuclear-hydrogenated resultant, an alicyclic epoxy-based compound having at least one epoxy group bonded to an alicyclic ring in a molecule, an aliphatic epoxy-based compound represented by glycidyl ether of an aliphatic polyhydroxy compound for example, and the like. The active energy ray-curable composition for forming an adhesive layer can contain a cationically polymerizable compound represented by an epoxy-based compound for example, a polymerization initiator such as a photo-cationic polymerization initiator which generates a cation species or a Lewis acid by being irradiated with active energy rays so as to initiate the polymerization of a cationically polymerizable compound, and a photobase generator which generates a base through light irradiation. The active energy ray-curable composition may further contain a thermal cationic polymerization initiator which initiates polymerization by heating and various additives such as a photosensitizer.

The polarizing plate of the present invention has the adhesive layer for bonding the polarizer layer to the interlayer on at least one surface of the polarizer layer, but the adhesive layer may be provided on the other surface thereof as well. For example, on the other surface, a known polarizing plate protective film may be provided through the adhesive layer. In a case where both surfaces of the polarizer layer are provided with the adhesive layer, the composition for forming the adhesive layers may be the same as or different from each other. From the viewpoint of productivity, it is preferable that both surfaces are provided with the adhesive layers formed of the same composition. The coating surface such as the surface of the polarizer layer can be coated with the composition for forming an interlayer by a known coating method. The coating surface may be subjected to a surface treatment such as a saponification treatment, a corona discharge treatment, or a plasma treatment before coating.

(Thickness of Adhesive Layer)

The thickness of the adhesive layer described so far is equal to or greater than 10 nm for example. However, the adhesive layer just needs to have a modulus of elasticity satisfying Expression 1 described above, and the thickness thereof is not particularly limited. From the viewpoint of thinning the polarizing plate, the thickness of the adhesive layer is preferably equal to or less than 30 μm.

<Polarizer Layer>

The polarizer layer may be a so-called linear polarizer having a function of converting natural light into a specific linearly polarized light. The polarizer layer is not particularly limited, and an absorptive polarizer can be used as the polarizer layer. As the absorptive polarizer, generally used polarizers can be used. For example, it is possible to use any of an iodine-based polarizer, a dye-based polarizer using a dichroic dye, a polyene-based polarizer, and a polarizer using a wire grid. Generally, the iodine-based polarizer and the dye-based polarizer can be prepared by causing iodine or a dichroic dye to be adsorbed onto polyvinyl alcohol and then stretching the polyvinyl alcohol. The thickness of the polarizer layer is not particularly limited, and is equal to or greater than 0.1 μm and equal to or less than 50.0 μm, for example. From the viewpoint of thinning the polarizing plate, the thickness of the polarizer layer is preferably equal to or less than 30 μm and more preferably equal to or less than 20 μm.

The polarizer layer may be a so-called coating-type polarizing film. The coating-type polarizing film can be prepared by a known method. For example, the coating-type polarizing film can be prepared by coating a coating surface with a dye-containing composition containing one kind or two or more kinds of plate-like dyes, thermotropic liquid crystal dichroic dyes, and the like based on anthraquinone, phthalocyanine, porphyrin, naphthalocyanine, quinacridone, dioxazine, indanthrene, acridine, perylene, pyrazolone, acridone, pyranthrone, and isobioranthrone. The content of the dye in the dye-containing composition is not particularly limited. Furthermore, the dye-containing composition may contain a known additive, solvent, or the like in any amount. The coating surface mentioned herein can be, for example, the surface of the adhesive layer of the laminate including the base material, the interlayer, and the adhesive layer. The coating surface may be subjected to a rubbing treatment or a photo-alignment treatment before coating. In addition, it is suitable to make the adhesive layer function as an alignment film. The coating-type polarizing film can be further thinned compared to the polarizer obtained by stretching polyvinyl alcohol. Moreover, the coating-type polarizing film is preferable because the optical properties thereof change little even in a case where external force such as bending force is applied thereto. The thickness of the coating-type polarizing film is preferably equal to or less than 3 μm.

It is preferable that the aforementioned coating-type polarizing film is formed of a dichroic dye-containing composition containing at least one kind of thermotropic liquid crystal dichroic dye. The proportion of a non-colorable liquid crystal compound in the dichroic dye composition is preferably equal to or lower than 30% by mass. Examples of the thermotropic liquid crystal dichroic dye include the thermotropic liquid crystal dichroic dye used in a light absorbing anisotropic film described in JP2011-237513A.

<Resin Film>

The polarizing plate of the present invention can also have a resin film on a side of the polarizer layer that is opposite to the base material side. As such a resin film, various resin films generally used as a polarizing plate protective film can be used without limitation. Furthermore, the resin film may function as a retardation film. The thickness of the resin film is generally about 15 to 100 μm. As the resin film, a commercial product or a resin film manufactured by a known film forming method can be used. The resin film can be bonded to the polarizer layer, for example, by exploiting the water adhesion action as described in JP2014-89270A or through an adhesive layer.

<Layer which can be Optionally Provided>

The polarizing plate of the present invention has a constitution in which the films and layers described so far are laminated. However, the polarizing plate can additionally have one or more other layers. Hereinafter, some specific examples of the layer which can be optionally provided will be described. Herein, polarizing plates having one or more layers other than the layers described below in any position are also included in the polarizing plate of the present invention.

(Cured Layer Obtained by Curing Active Energy Ray-Curable Composition)

In an aspect, the polarizing plate of the present invention can have a cured layer, which is obtained by curing an active energy ray-curable composition, on a side of the base material that is opposite to the interlayer side. The cured layer is a layer which can function as a hardcoat layer. From the viewpoint of improving the durability of the polarizing plate of the present invention, it is preferable to laminate the hardcoat layer on the base material. Furthermore, in an aspect in which the polarizing plate of the present invention is used as a front panel of a display apparatus, from the viewpoint of improving scratch resistance, it is preferable for the hardcoat layer to exist on the surface of the front panel. In the present invention and the present specification, the polarizing plate provided with the hardcoat layer is humidified for 2 hours under the conditions of a temperature of 25° C. and a relative humidity of 60%, and then 5 different sites on the surface of the hardcoat layer are scratched under a load of 4.9 N according to JIS K 5400 by using a testing pencil with 2H hardness specified in JIS-S6006. At this time, the layer in which scratch is visually recognized at 0 to 2 sites is the hardcoat layer. Furthermore, in a case where the same evaluation as descried above is performed using a testing pencil with 3H hardness specified in JIS-S6006, and as a result scratch is visually recognized at 0 to 2 sites, the cured layer is regarded as having a pencil hardness equal to or higher than 3H. The same shall be applied to the cured layer having a pencil hardness equal to or higher than 4H, 5H, 6H, 7H, or the like. The pencil hardness of the cured layer is preferably equal to or higher than 2H, more preferably equal to or higher than 3H, even more preferably equal to or higher than 4H, still more preferably equal to or higher than 5H, yet more preferably equal to or higher than 6H, and further preferably equal to or higher than 7H. That is, the higher the pencil hardness, the better. For the polarizing plate which does not include the aforementioned cured layer and adopts the surface of the base material as the uppermost surface, the pencil hardness measured on the surface of the base material by the same method as described above is preferably equal to or higher than 2H, and more preferably equal to or higher than 3H. That is, the higher the pencil hardness, the better.

As a preferred aspect of the active energy ray-curable composition for forming the aforementioned cured layer, an active energy ray-curable composition (hereinafter, simply described as a “composition” as well) can be exemplified which contains a radically polymerizable compound containing two or more radically polymerizable groups selected from the group consisting of an acryloyloxy group, an acryloyl group, a methacryloyloxy group, and a methacryloyl group in one molecule and containing one or more urethane bonds in one molecule, a cationically polymerizable compound, a radical photopolymerization initiator, and a cation photopolymerization initiator. Hereinafter, the active energy ray-curable composition will be specifically described, but the present invention is not limited to the following aspect. The aforementioned cured layer can also be formed using various active energy ray-curable compositions generally used in forming a hardcoat layer.

—Polymerizable Compound—

The composition contains, as polymerizable compounds, a radically polymerizable compound and a cationically polymerizable compound that are polymerized in different ways.

Hereinafter, each of the polymerizable compounds will be sequentially described.

Radically Polymerizable Compound

The composition preferably contains urethane (meth)acrylate as the radically polymerizable compound. By definition, the urethane (meth)acrylate includes both acrylate and methacrylate having one or more urethane bonds in one molecule. Acrylate refers to a compound containing one or more acryl-based functional groups selected from the group consisting of an acryloyloxy group (H₂C═CH—C(═O)—O—) and an acryloyl group (H₂C═CH—C(═O)—) in one molecule. Methacrylate refers to a compound containing one or more methacryl-based functional groups selected from the group consisting of a methacryloyloxy group (H₂C═C(CH₃)—C(═O)—O—) and a methacryloyl group (H₂C═C(CH₃)—C(═O)—) in one molecule. Furthermore, urethane (meth)acrylate also includes a compound which has one or more urethane bonds in one molecule and one acryl-based functional group and one methacryl-based functional group described above. Urethane (meth)acrylate is a polymerizable compound that can contribute to the improvement of the hardness of the cured layer. In contrast, the cationically polymerizable compound contained in the composition together with the urethane (meth)acrylate is a polymerizable compound that can contribute to the inhibition of curling (warping) of the cured layer or to the amelioration of brittleness of the cured layer. The composition containing these components is preferable because it forms a cured layer which has high hardness, is improved in terms of brittleness, and is inhibited from experiencing the occurrence of curling.

As the urethane (meth)acrylate, only one kind of urethane (meth)acrylate may be used, or two or more kinds of urethane (meth)acrylate having different structures may be used in combination. As the radically polymerizable compound, one or more kinds of urethane (meth)acrylate and one or more kinds of radically polymerizable compounds other than urethane (meth)acrylate may be used in combination. Other radically polymerizable compounds that can be used in combination will be described later. For various components such as the cationically polymerizable compound, the radical photopolymerization initiator, and the cation photopolymerization initiator which will be described later, only one kind of a certain component may be used, or two or more kinds thereof having different structures may be used in combination in the same manner as described above.

Hereinafter, a radically polymerizable compound (urethane (meth)acrylate) containing two or more radically polymerizable groups selected from the aforementioned group in one molecule and containing one or more urethane bonds in one molecule will be described as a “first radically polymerizable compound”, and a radically polymerizable compound other than urethane (meth)acrylate will be described as a “second radically polymerizable compound”. As described above, the aforementioned composition may contain two or more kinds of radically polymerizable compounds having different structures as the first radically polymerizable compound, or may contain two or more kinds of radically polymerizable compounds having different structures as the second radically polymerizable compound.

(i) First Radically Polymerizable Compound

The first radically polymerizable compound (urethane (meth)acrylate) contained in the aforementioned composition is specifically a compound which contains two or more radically polymerizable groups selected from the group consisting of an acryloyloxy group, an acryloyl group, a methacryloyloxy group, and a methacryloyl group in one molecule and contains one or more urethane bonds in one molecule. The radically polymerizable group (polymerizable group which can be radically polymerized) selected from the aforementioned group is a polymerizable group which can be photopolymerized (photopolymerizable group). For forming a hardcoat layer having high hardness, it is useful to use a polyfunctional compound, which contains two or more radically polymerizable groups described above in one molecule, as the radically polymerizable compound. Two or more of the radically polymerizable groups contained in the first radically polymerizable compound may be the same as each other. Alternatively, two or more kinds of different radically polymerizable groups may be contained in the first radically polymerizable compound. The number of radically polymerizable groups contained in one molecule of the first radically polymerizable compound is at least 2. The number of radically polymerizable groups is for example 2 to 10 and preferably 2 to 6. Among the radically polymerizable groups selected from the aforementioned group, an acryloyloxy group and a methacryloyloxy group are preferable.

It is preferable that the first radically polymerizable compound contains one or more urethane bonds in one molecule together with two or more radically polymerizable groups selected from the aforementioned group. The number of urethane bonds contained in one molecule of the first radically polymerizable compound may be equal to or greater than 1. From the viewpoint of further improving the hardness of the hardcoat layer to be formed, the number of urethane bonds is preferably equal to or greater than 2, for example, 2 to 5. In the first radically polymerizable compound containing two urethane bonds in one molecule, the radically polymerizable groups selected from the aforementioned group may be bonded to only one of the urethane bonds directly or through a linking group. Alternatively, each of the radically polymerizable groups may be bonded to the two urethane bonds directly or through a linking group. In an aspect, it is preferable that one or more radically polymerizable groups selected from the aforementioned group are bonded to each of the two urethane bonds bonded to each other through a linking group.

In the first radically polymerizable compound, the urethane bonds and the radically polymerizable groups may be directly bonded to each other, or a linking group may exist between the urethane bonds and the radically polymerizable groups. The linking group is not particularly limited, and examples thereof include a linear or branched saturated or unsaturated hydrocarbon group, a cyclic group, a group obtained by combining two or more of these groups, and the like. The number of carbon atoms on the hydrocarbon group is about 2 to 20 for example but is not particularly limited. As an example of a cyclic structure contained in the cyclic group, an aliphatic ring (such as a cyclohexane ring), an aromatic ring (such as a benzene ring or a naphthalene ring), or the like can be exemplified. These groups may be unsubstituted or may have a substituent. Unless otherwise specified, a group described in the present invention and the present specification may have a substituent or may be unsubstituted. In a case where a certain group has a substituent, examples of the substituent include an alkyl group (such as an alkyl group having 1 to 6 carbon atoms), a hydroxyl group, an alkoxy group (such as an alkoxy group having 1 to 6 carbon atoms), a halogen atom (such as a fluorine atom, a chlorine atom, or a bromine atom), a cyano group, an amino group, a nitro group, an acyl group, a carboxyl group, and the like.

The first radically polymerizable compound described so far can be synthesized by a known method, or may be obtained as a commercial product.

As an example of the synthesis method, a method can be exemplified in which an alcohol, a polyol, and/or a hydroxyl group-containing compound such as hydroxyl group-containing (meth)acrylate are reacted with an isocyanate, and then, if necessary, a urethane compound obtained by the reaction is esterified using (meth)acrylic acid. Herein, by definition, (meth)acrylic acid includes acrylic acid and methacrylic acid.

Examples of commercial products of urethane (meth)acrylate include, but are not limited to, UA-306H, UA-3061, UA-306T, UA-510H, UF-8001G, UA-101I, UA-101T, AT-600, AH-600, and Al-600 manufactured by KYOEISHA CHEMICAL Co., LTD., U-4HA, U-6HA, U-6LPA, UA-32P, U-15HA, and UA-1100H manufactured by SHIN-NAKAMURA CHEMICAL CO., LTD., SHIKOH UV-1400B, SHIKOH UV-1700B, SHIKOH UV-6300B, SHIKOH UV-7550B, SHIKOH UV-7600B, SHIKOH UV-7605B, SHIKOH UV-7610B, SHIKOH UV-7620EA, SHIKOH UV-7630B, SHIKOH UV-7640B, SHIKOH UV-6630B, SHIKOH UV-7000B, SHIKOH UV-7510B, SHIKOH UV-7461TE, SHIKOH UV-3000B, SHIKOH UV-3200B, SHIKOH UV-3210EA, SHIKOH UV-3310EA, SHIKOH UV-3310B, SHIKOH UV-3500BA, SHIKOH UV-3520TL, SHIKOH UV-3700B, SHIKOH UV-6100B, SHIKOH UV-6640B, SHIKOH UV-2000B, SHIKOH UV-2010B, SHIKOH UV-2250EA, and SHIKOH UV-2750B manufactured by NIPPON GOHSEI, UL-503LN manufactured by KYOEISHA CHEMICAL Co., LTD., UNIDIC 17-806, UNIDIC 17-813, UNIDIC V-4030, and UNIDIC V-4000BA manufactured by DIC Corporation, EB-1290K manufactured by Daicel-UCB Company, Ltd., HICORP AU-2010 and HICORP AU-2020 manufactured by TOKUSHIKI Co., Ltd., and the like.

As specific examples of the first radically polymerizable compound, example compounds A-1 to A-8 will be shown below, but the present invention is not limited to the following specific examples.

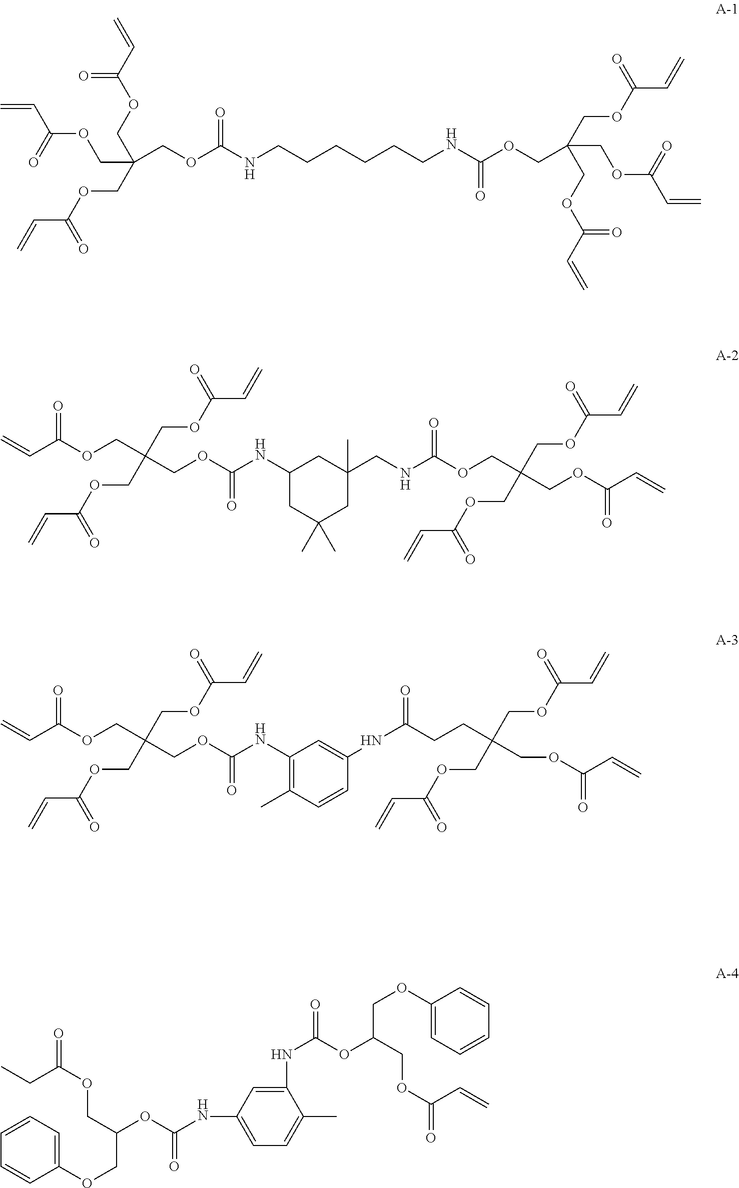

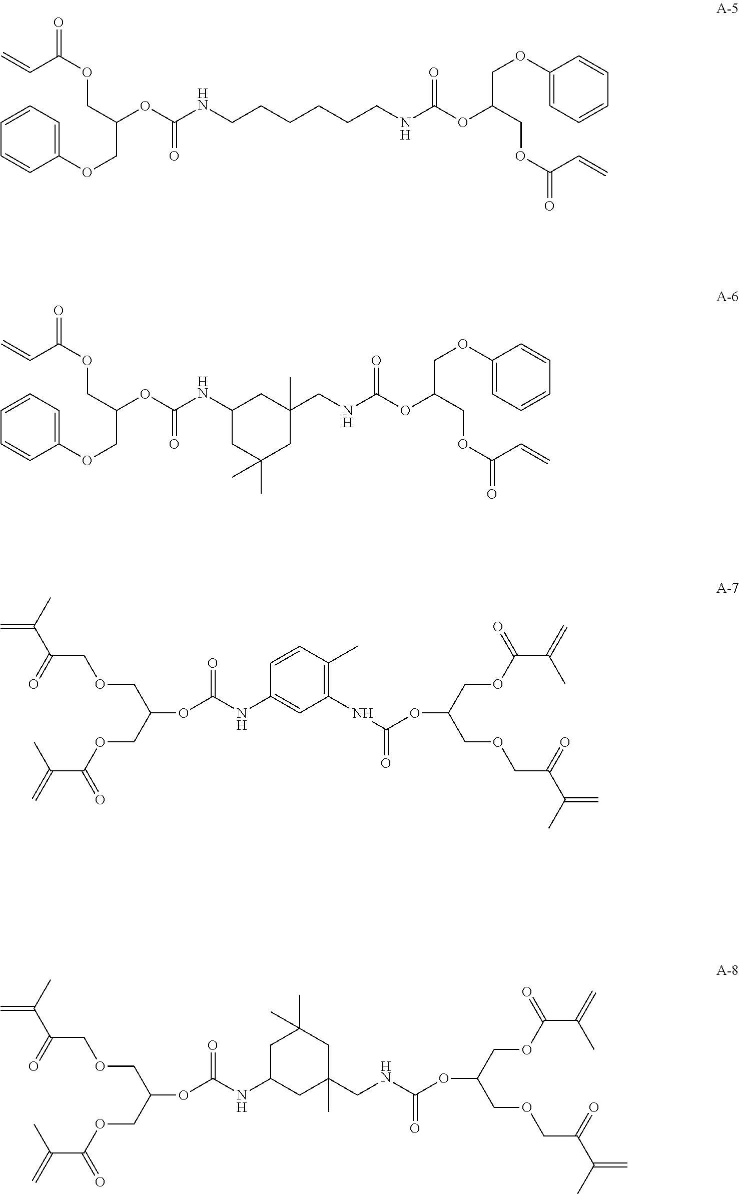

The content of the first radically polymerizable compound in the composition, with respect to a total amount of 100% by mass of the composition, is preferably equal to or greater than 30% by mass, more preferably equal to or greater than 50% by mass, and even more preferably equal to or greater than 70% by mass. From the viewpoint of improving the hardness of the cured layer obtained by curing the composition, it is preferable that the composition contains a large amount of the first radically polymerizable compound. From the viewpoint of further ameliorating brittleness, the content of the first radically polymerizable compound, with respect to a total amount of 100% by mass of the composition, is preferably equal to or less than 98% by mass, and more preferably equal to or less than 95% by mass.

(ii) Second Radically Polymerizable Compound

The composition may contain, as a radically polymerizable compound, one or more kinds of radically polymerizable compound (second radically polymerizable compound) other than urethane (meth)acrylate. The second radically polymerizable compound may be used in combination with one or more kinds of first radically polymerizable compound. From the viewpoint of achieving either or both further amelioration of brittleness and further inhibition of curling, it is preferable to use the first radically polymerizable compound and the second radically polymerizable compound in combination. From the viewpoint described above, in a case where the composition contains the first radically polymerizable compound and the second radically polymerizable compound, a mass ratio of first radically polymerizable compound/second radically polymerizable compound is preferably 3/1 to 1/30, more preferably 2/1 to 1/20, and even more preferably 1/1 to 1/10.

The second radically polymerizable compound is preferably a radically polymerizable compound which contains two or more radically polymerizable groups in one molecule and does not have a urethane bond. The radically polymerizable group contained in the second radically polymerizable compound is preferably a functional group having an ethylenically unsaturated double bond. In an aspect, the radically polymerizable group is preferably selected from the group consisting of an epoxy group, an oxetanyl group, and a vinyl ether group. In another aspect, the second radically polymerizable compound preferably has a radically polymerizable group selected from the group consisting of an acryloyloxy group, an acryloyl group, a methacryloyloxy group, and a methacryloyl group, exactly like the first radically polymerizable compound. The number of radically polymerizable groups contained in one molecule of the second radically polymerizable compound is preferably at least 2, more preferably equal to or greater than 3, and even more preferably equal to or greater than 4. In an aspect, the number of radically polymerizable groups contained in one molecule of the second radically polymerizable compound is equal to or less than 10 for example, but may be greater than 10.

As the second radically polymerizable compound, a radically polymerizable compound having a molecular weight equal to or greater than 200 and less than 1,000 is preferable. In the present invention and the present specification, unless otherwise specified, for a polymer, a molecular weight refers to a weight-average molecular weight measured by gel permeation chromatography (GPC) and expressed in terms of polystyrene. Specifically, the weight-average molecular weight can be measured under the following conditions, for example.

GPC device: HLC-8120 (manufactured by Tosoh Corporation):

Column: TSK gel Multipore HXL-M (manufactured by Tosoh Corporation, 7.8 mmID (inner diameter)×30.0 cm)

Eluent: tetrahydrofuran (THF)

The following compounds can be exemplified as the second radically polymerizable compound, but the present invention is not limited to the following example compounds.

Examples of the second radically polymerizable compound include bifunctional (meth)acrylate compounds such as polyethylene glycol 200 di(meth)acrylate, polyethylene glycol 300 di(meth)acrylatc, polyethylene glycol 400 di(meth)acrylate, polyethylene glycol 600 di(meth)acrylate, triethylene glycol di(meth)acrylate, epichlorohydrin-modified ethylene glycol di(meth)acrylate (as a commercial product, for example, DENACOL DA-811 manufactured by NAGASE & CO., LTD.), polypropylene glycol 200 di(meth)acrylate, polypropylene glycol 400 di(meth)acrylate, polypropylene glycol 700 di(meth)acrylate, Ethylene Oxide (EO)•Propylene Oxide (PO) block polyether di(meth)acrylate (as a commercial product, for example, a BLEMMER PET series manufactured by NOF CORPORATION), dipropylene glycol di(meth)acrylate, bisphenol A EO addition-type di(meth)acrylate (as a commercial product, for example, M-210 manufactured by TOAGOSEI CO., LTD. or NK ESTER A-BPE-20 manufactured by SHIN-NAKAMURA CHEMICAL CO., LTD.), hydrogenated bisphenol A EO addition-type di(meth)acrylate (such as NK ESTER A-HPE-4 manufactured by SHIN-NAKAMURA CHEMICAL CO., LTD.), bisphenol A PO-addition type di(meth)acrylate (as a commercial product, for example, LIGHT ACRYLATE BP-4PA manufactured by KYOEISIIA CHEMICAL Co., LTD.), bisphenol A epichlorohydrin addition-type di(meth)acrylate (as a commercial product, for example, EBECRYL 150 manufactured by Daicel-UCB Company, Ltd.), bisphenol A EO-PO addition-type di(meth)acrylate (as a commercial product, for example, BP-023-PE manufactured by TOHO Chemical Industry Co., Ltd.), bisphenol F EO addition-type di(meth)acrylate (as a commercial product, for example, ARONIX M-208 manufactured by TOAGOSEI CO., LTD.), 1,6-hexanediol di(meth)acrylate, 1,6-hexanediol di(meth)acrylate modified with epichlorohydrin, neopentyl glycol di(meth)acrylate, hydroxypivalic acid neopentyl glycol di(meth)acrylate, hydroxypivalic acid neopentyl glycol di(meth)acrylate modified with caprolactone, 1,4-butanediol di(meth)acrylate, 1,9-nonanediol di(meth)acrylate, trimethylolpropane di(meth)acrylate, tricyclodecane dimethanol di(meth)acrylate, pentaerythritol di(meth)acrylate monostearate, trimethylolpropane acrylic acid-benzoic acid ester, and isocyanuric acid EO-modified di(meth)acrylate (as a commercial product, for example, ARONIX M-215 manufactured by TOAGOSEI CO., LTD.).

Examples of the second radically polymerizable compound also include trifunctional (meth)acrylate compounds such as trimethylolpropane tri(meth)acrylate, trimethylolpropane tri(meth)acrylate modified with EO, PO, or epichlorohydrin, pentaerythritol tri(meth)acrylate, glycerol tri(meth)acrylate, glycerol tri(meth)acrylate modified with EO, PO, or epichlorohydrin, isocyanuric acid EO-modified tri(meth)acrylate (as a commercial product, for example, ARONIX M-315 manufactured by TOAGOSEI CO., LTD.), tris(meth)acryloyloxyethyl phosphate, (2,2,2-tri-(meth)acryloyloxymethyl)ethyl hydrogen phthalate, glycerol tri(meth)acrylate, and glycerol tri(meth)acrylate modified with EO, PO, or epichlorohydrin; tetrafunctional (meth)acrylate compounds such as pentaerythritol tetra(meth)acrylate, pentaerythritol tetra(meth)acrylate modified with EO, PO, or epichlorohydrin, and ditrimethylolpropane tetra(meth)acrylate; pentafunctional (meth)acrylate compounds such as dipentaerythritol penta(meth)acrylate and dipentaerythritol penta(meth)acrylate modified with EO, PO, epichlorohydrin, fatty acid, or alkyl; and hexafunctional (meth)acrylate compounds such as dipentaerythritol hexa(meth)acrylate, dipentaerythritol hexa(meth)acrylate modified with EO, PO, epichlorohydrin, fatty acid, or alkyl, sorbitol hexa(meth)acrylate, and sorbitol hexa(meth)acrylate modified with EO, PO, epichlorohydrin, fatty acid, or alkyl.

As the second radically polymerizable compound, polyester (meth)acrylate and epoxy (meth)acrylate having a weight-average molecular weight equal to or greater than 200 and less than 1,000 are also preferable. Examples thereof include commercial polyester (meth)acrylate products such as a BEAMSET (trade name) 700 series including BEAMSET 700 (hexafunctional), BEAMSET 710 (tetrafunctional), and BEAMSET 720 (trifunctional) manufactured by Arakawa Chemical Industries, Ltd. Examples of the epoxy (meth)acrylate include an SP series such as SP-1506, 500, SP-1507, and 480 (trade names) as well as a VR series such as VR-77 manufactured by Showa Highpolymer Co., Ltd., EA-1010/ECA, EA-11020, EA-1025, EA-6310/ECA (trade names) manufactured by SHIN-NAKAMURA CHEMICAL CO., LTD., and the like.

Specific examples of the second radically polymerizable compound also include the following example compounds A-9 to A-11.

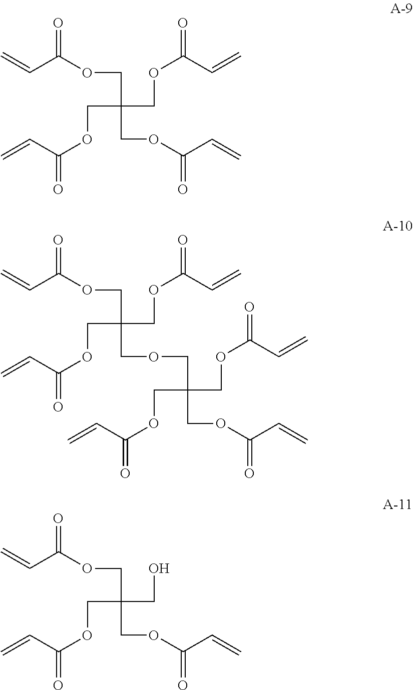

Cationically Polymerizable Compound

The aforementioned composition contains a cationically polymerizable compound together with the first radically polymerizable compound described above. Any of the cationically polymerizable compounds can be used without limitation as long as the compounds have a polymerizable group which can be cationically polymerized (cationically polymerizable group). The number of cationically polymerizable groups contained in one molecule is at least 1. The cationically polymerizable compound may be a monofunctional compound containing one cationically polymerizable group or a polyfunctional compound containing two or more cationically polymerizable groups. The number of cationically polymerizable groups contained in the polyfunctional compound is not particularly limited, but is 2 to 6, for example. Two or more cationically polymerizable groups contained in the polyfunctional compound may be the same as each other. Alternatively, two or more different kinds of cationically polymerizable groups may be contained in the polyfunctional compound.

As the cationically polymerizable group, an oxygen-containing heterocyclic group and a vinyl ether group can be preferably exemplified. The cationically polymerizable compound may contain one or more oxygen-containing heterocyclic groups and one or more vinyl ether groups in one molecule.

The oxygen-containing heterocyclic ring may be a monocyclic ring or a condensed ring. Furthermore, it is also preferable that the oxygen-containing heterocyclic ring has a bicyclo skeleton. The oxygen-containing heterocyclic ring may be a non-aromatic ring or an aromatic ring, and is preferably a non-aromatic ring. Specific examples of the monocyclic ring include an epoxy ring, a tetrahydrofuran ring, and an oxetane ring. Examples of the oxygen-containing heterocyclic ring having a bicyclo skeleton include an oxabicyclo ring. The cationically polymerizable group containing the oxygen-containing heterocyclic ring is contained in the cationically polymerizable compound as a monovalent substituent or a polyvalent substituent with a valency of 2 or higher. The aforementioned condensed ring may be a ring formed by the condensation of two or more oxygen-containing heterocyclic rings or a ring formed by the condensation of one or more oxygen-containing heterocyclic rings and one or more ring structures other than the oxygen-containing heterocyclic ring. The ring structure other than the oxygen-containing heterocyclic ring is not limited to the above, and examples thereof include a cycloalkane ring such as a cyclohexane ring.

Specific examples of the oxygen-containing heterocyclic ring will be shown below, but the present invention is not limited to the following specific examples.

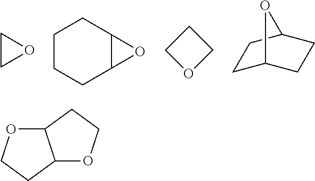

The cationically polymerizable compound may have a partial structure other than the cationically polymerizable group. The partial structure is not particularly limited, and may be a linear, branched, or cyclic structure. The partial structure may contain one or more heteroatoms such as oxygen atoms or nitrogen atoms.

As a preferred aspect of the cationically polymerizable compound, a compound (cyclic structure-containing compound) can be exemplified which has a cyclic structure as the cationically polymerizable group or as a partial structure other than the cationically polymerizable group. The cyclic structure-containing compound may have one cyclic structure, for example, and the cyclic structure-containing compound may have two or more cyclic structures. The number of cyclic structures contained in the cyclic structure-containing compound is 1 to 5 for example, but is not particularly limited. In a case where the compound contains two or more cyclic structures, the cyclic structures may be the same as each other. Alternatively, the compound may contain two or more kinds of cyclic structures having different structures.

As an example of the cyclic structure contained in the cyclic structure-containing compound, an oxygen-containing heterocyclic ring can be exemplified. The details of the oxygen-containing heterocyclic ring are as described above.

As another example of the cyclic structure contained in the cyclic structure-containing compound, a nitrogen-containing heterocyclic ring can be exemplified. Examples of the nitrogen-containing heterocyclic ring include an isocyanurate ring (nitrogen-containing heterocyclic ring contained in example compounds B-1 to B-3 which will be described later), a glycoluril ring (nitrogen-containing heterocyclic ring contained in an example compound B-10 which will be described later), and the like. Among these, from the viewpoint of forming a cured layer that exhibits excellent adhesiveness with respect to the base material, the compound containing an isocyanurate ring (isocyanurate ring-containing compound) is preferred as a cationically polymerizable compound, because the isocyanurate ring is considered to have excellent affinity to the resin constituting the base material. In this respect, a base material containing an acryl-based resin layer is more preferable, and it is even more preferable that the surface directly in contact with the cured layer is the surface of the acryl-based resin layer.

As another example of the cyclic structure contained in the cyclic structure-containing compound, an alicyclic structure can be exemplified. Examples of the alicyclic structure include a cyclo ring structure, a dicyclo ring structure, and a tricyclo ring structure. Specific examples thereof include a dicyclopentanyl ring, a cyclohexane ring, and the like.

The cationically polymerizable compound described so far can be synthesized by a known method, and can be obtained as a commercial product.

Specific examples of the cationically polymerizable compound containing an oxygen-containing heterocyclic ring as a cationically polymerizable group include 3,4-epoxycyclohexylmethyl-3′,4′-epoxycyclohexane carboxylate (for example, commercial products such as UVR 6105 and UVR 6110 manufactured by Union Carbide Corporation and CELLOXIDE 2021 manufactured by Daicel Corporation), bis(3,4-epoxycyclohexylmethyl)adipate (such as UVR 6128 manufactured by Union Carbide Corporation), vinylcyclohexene monoepoxide (such as CELLOXIDE 2000 manufactured by Daicel Corporation), ε-caprolactam-modified 3,4-epoxycyclohexylmethyl 3′,4′-epoxycyclohexane carboxylate (such as CELLOXIDE 2081 manufactured by Daicel Corporation), 1-methyl-4-(2-methyloxiranyl)-7-oxabicyclo[4,1,0]heptane (such as CELLOXIDE 3000 manufactured by Daicel Corporation), 7,7′-dioxa-3,3′-bi[bicyclo[4.1.0]heptane] (such as CELLOXIDE 8000 manufactured by Daicel Corporation), 3-ethyl-3-hydroxymethyloxetane, 1,4 bis {[(3-ethyl-3-oxetanyl)methoxy]methyl}benzene, 3-ethyl-3-(phenoxymethyl)oxetane, 3-ethyl-3-(2-ethylhexyloxymethyl)oxetane, di[1-ethyl(3-oxetanyl)]methyl ether, and the like.

Specific examples of the cationically polymerizable compound containing a vinyl ether group as a cationically polymerizable group include 1,4-butanediol divinyl ether, 1,6-hexanediol divinyl ether, nonanediol divinyl ether, cyclohexanediol divinyl ether, cyclohexane dimethanol divinyl ether, triethylene glycol divinyl ether, trimethylolpropane trivinyl ether, pentaerythritol tetravinyl ether, and the like. As the cationically polymerizable compound containing a vinyl ether group, those having an alicyclic structure are also preferable.

Furthermore, as the cationically polymerizable compound, it is possible to use the compounds exemplified in JP1996-143806A (JP-H08-143806A), JP1996-283320A (JP-H08-283320A), JP2000-186079A, JP2000-327672A, JP2004-315778A, JP2005-29632A, and the like.

As specific examples of the cationically polymerizable compound, example compounds B-1 to B-14 will be shown below, but the present invention is not limited to the following specific examples.

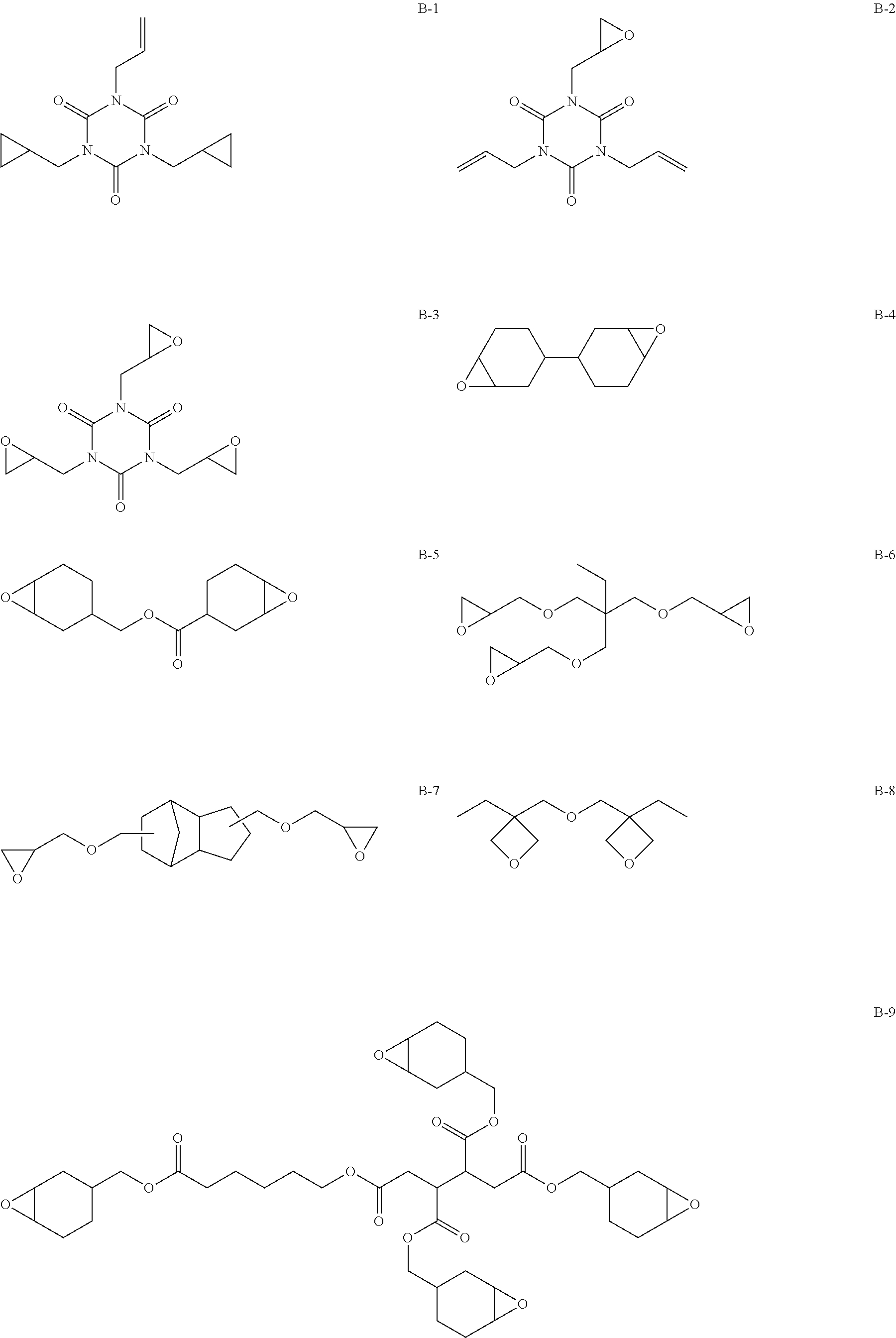

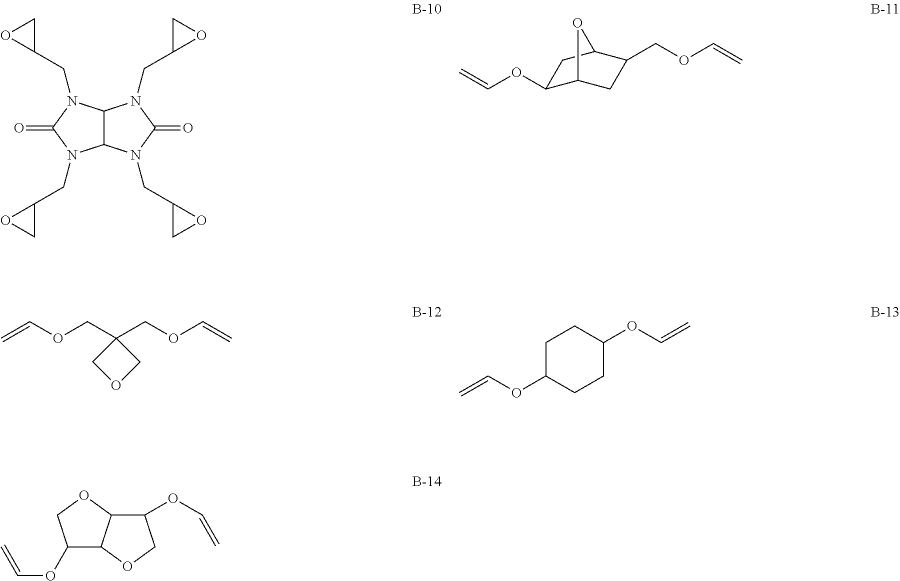 [SMILES: O=C1N(CC2CO2)C2C(N1CC1CO1)N(CC1CO1)C(=O)N2CC1CO1 ; C=COCC1CC2OC1CC2OC=C ; C=COCC1(COC=C)COC1 ; C=COC1CCC(OC=C)CC1 ; C=COC1COC2C(OC=C)COC12]

The content of the cationically polymerizable compound in the aforementioned composition, with respect to the total content of 100 parts by mass of the first radically polymerizable compound and the cationically polymerizable compound, is preferably equal to or greater than 0.05 parts by mass, more preferably equal to or greater than 0.1 parts by mass, and even more preferably equal to or greater than 1 part by mass. From the viewpoint of further inhibiting the occurrence of curling in the cured layer and further ameliorating the brittleness of the cured layer, it is preferable that the composition contains a large amount of the cationically polymerizable compound. In contrast, from the viewpoint of further improving the hardness of the cured layer, it is preferable that the proportion of the first radically polymerizable compound is higher among the polymerizable compounds contained in the composition. In this respect, the content of the cationically polymerizable compound is preferably equal to or less than 50 parts by mass and more preferably equal to or less than 40 parts by mass with respect to the aforementioned total content of 100 parts by mass. In the present invention, a compound having both the cationically polymerizable group and the radically polymerizable group is classified as a cationically polymerizable compound, and the content thereof in the composition is specified.

—Photopolymerization Initiator—

The aforementioned composition contains a radically polymerizable compound and the cationically polymerizable compound as polymerizable compounds. In order to initiate and carry out a polymerization reaction of the polymerizable compounds that are polymerized in different ways by irradiating the compounds with active energy rays (light irradiation), the composition contains a radical photopolymerization initiator and a cationic polymerization initiator. Only one kind of radical photopolymerization initiator may be used, or two or more kinds of radical photopolymerization initiators having different structures may be used in combination. The same shall be applied for the cation photopolymerization initiator.

Hereinafter, each of the photopolymerization initiators will be sequentially described.

Radical Photopolymerization Initiator

The radical photopolymerization initiator may be a compound that generates a radical as an active species by light irradiation, and known radical photopolymerization initiators can be used without limitation. Specific examples thereof include acetophenones such as diethoxyacetophenone, 2-hydroxy-2-methyl-1-phenylpropan-1-one, benzyl dimethyl ketal, 4-(2-hydroxyethoxy)phenyl-(2-hydroxy-2-propyl)ketone, 1-hydroxycyclohexyl phenyl ketone, 2-methyl-2-morpholino(4-thiomethylphenyl)propan-1-one, 2-benzyl-2-dimethylamino-1-(4-morpholinophenyl)butane, a 2-hydroxy-2-methyl-1-[4-(1-methylvinyl)phenyl]propane oligomer, and 2-hydroxy-1-{4-[4-(2-hydroxy-2-methyl-propionyl)-benzyl]phenyl}-2-methyl-propan-1-one; oxime esters such as 1,2-octanedione, 1-[4-(phenylthio)-,2-(O-benzoyloxime)], and ethanone, 1-[9-ethyl-6-(2-methylbenzoyl)-9H-carbazol-3-yl]-,1-(0-acetyloxime); benzoins such as benzoin, benzoin methyl ether, benzoin ethyl ether, benzoin isopropyl ether, and benzoin isobutyl ether; benzophenones such as benzophenone, methyl o-benzoyl benzoate, 4-phenylbenzophenone, 4-benzoyl-4′-methyl-diphenyl sulfide, 3,3′,4,4′-tetra(t-butylperoxycarbonyl)benzophenone, 2,4,6-trimethylbenzophenone, 4-benzoyl-N,N-dimethyl-N-[2-(1-oxo-2-propenyloxy)ethyl]benzene methanaminium bromide, and (4-benzoylbenzyl)trimethyl ammonium chloride; thioxanthones such as 2-isopropylthioxanthone, 4-isopropylthioxanthone, 2,4-diethylthioxanthone, 2,4-dichlorothioxanthone, 1-chloro-4-propoxythioxanthone, 2-(3-dimethylamino-2-hydroxy)-3,4-dimethyl-9H-thioxanthen-9-one methochloride; acylphosphine oxides such as 2,4,6-trimethylbenzoyl-diphenylphosphine oxide, bis(2,6-dimethoxybenzoyl)-2,4,4-trimethyl-pentylphosphine oxide, and bis(2,4,6-trimethylbenzoyl)-phenylphosphine oxide; and the like. Furthermore, as an aid for the radical photopolymerization initiator, triethanolamine, triisopropanolamine, 4,4′-dimethylaminobenzophenone (Michler's ketone), 4,4′-diethylaminobenzophenone, 2-dimethylaminoethyl benzoate, ethyl 4-dimethylaminobenzoate, (n-butoxy)ethyl 4-dimethylaminobenzoate, isoamyl 4-dimethylaminobenzoate, 2-ethylhexyl 4-dimethylaminobenzoate, 2,4-diethylthioxanthone, 2,4-diisopropylthioxanthone, and the like may be used in combination.

The aforementioned radical photopolymerization initiators and aids can be synthesized by a known method or can be obtained as commercial products.

The content of the radical photopolymerization initiator in the aforementioned composition may be appropriately adjusted within a range in which the polymerization reaction (radical polymerization) of the radically polymerizable compound is excellently carried out, and is not particularly limited. The content of the radical photopolymerization initiator, with respect to 100 parts by mass of the radically polymerizable compound (in a case where the composition contains the first and second radically polymerizable compounds, the total content thereof), is within a range of 0.1 to 20 parts by mass for example, preferably within a range of 0.5 to 10 parts by mass, and even more preferably within a range of 1 to 10 parts by mass.

Cation Photopolymerization Initiator

As the cation photopolymerization initiator, a compound which can generate a cation as an active species by light irradiation is preferable, and known cation photopolymerization initiators can be used without limitation. Specific examples thereof include a sulfonium salt, an ammonium salt, an iodonium salt (such as a diaryl iodonium salt), a triaryl sulfonium salt, a diazonium salt, an iminium salt, and the like that are known. More specifically, examples thereof include the cation photopolymerization initiators represented by Formulae (25) to (28) shown in paragraphs “0050” to “0053” in JP1996-143806A (JP-H08-143806A), the compounds exemplified as cationic polymerization catalysts in paragraph “0020” of JP1996-283320A (JP-H08-283320A), and the like. The cation photopolymerization initiator can be synthesized by a known method, or can be obtained as a commercial product. Examples of the commercial product include CI-1370, CI-2064, CI-2397, CI-2624, CI-2639, CI-2734, CI-2758, CI-2823, CI-2855, CI-5102, and the like manufactured by NIPPON SODA CO., LTD., PHOTOINITIATOR 2047 and the like manufactured by Rhodia, UVI-6974 and UVI-6990 manufactured by Union Carbide Corporation), CPI-IOP manufactured by San-Apro Ltd., and the like.

In view of the sensitivity of the photopolymerization initiator with respect to light, the compound stability, and the like, a diazonium salt, an iodonium salt, a sulfonium salt, and an iminium salt are preferable as the cation photopolymerization initiator. In view of weather fastness, an iodonium salt is most preferable.

Specific examples of commercial products of the iodonium salt-based cation photopolymerization initiator include B2380 manufactured by TOKYO CHEMICAL INDUSTRY CO., LTD., BBI-102 manufactured by Midori Kagaku Co., Ltd., WPI-113 manufactured by Wako Pure Chemical Industries, Ltd., WPI-124 manufactured by Wako Pure Chemical Industries, Ltd., WPI-169 manufactured by Wako Pure Chemical Industries, Ltd., WPI-170 manufactured by Wako Pure Chemical Industries, Ltd., and DTBPI-PFBS manufactured by Toyo Gosei Co., Ltd.

Specific examples of iodonium salt compounds which can be used as the cation photopolymerization initiator include the following compounds FK-1 and FK-2. The following compounds FK-1 and FK-2 can be synthesized by the method described in Example 1 of JP4841935B.

Cation photopolymerization initiator (iodonium salt compound) FK-1

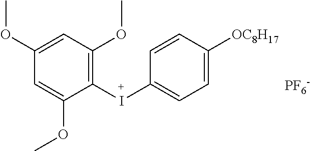

Cation photopolymerization initiator (iodonium salt compound) FK-2

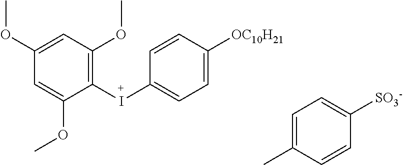

The content of the cation photopolymerization initiator in the aforementioned composition may be appropriately adjusted within a range in which the polymerization reaction (cationic polymerization) of the cationically polymerizable compound is excellently carried out, and is not particularly limited. The content of the cation photopolymerization initiator is, with respect to 100 parts by mass of the cationically polymerizable compound, within a range of 0.1 to 200 parts by mass for example, preferably within a range of 1 to 150 parts by mass, and more preferably within a range of 2 to 100 parts by mass.

—Optional Component—

The aforementioned composition contains the polymerizable compounds and the photopolymerization initiators described so far and can additionally contain one or more kinds of optional components. Specific examples of the optional components include a solvent and various additives.

Solvent

As the solvent which can be contained as an optional component, an organic solvent is preferable. One kind of organic solvent can be used, or two or more kinds of organic solvents can be used by being mixed together at any ratio. Specific examples of the organic solvent include alcohols such as methanol, ethanol, propanol, n-butanol, and i-butanol; ketones such as acetone, methyl isobutyl ketone, methyl ethyl ketone, and cyclohexanone; cellosolves such as ethyl cellosolve; aromatic solvents such as toluene and xylylene; glycol ethers such as propylene glycol monomethyl ether; acetic acid esters such as methyl acetate, ethyl acetate, and butyl acetate; diacetone alcohol; and the like. The amount of the solvent in the aforementioned composition can be appropriately adjusted within a range in which coating suitability of the composition can be secured. For example, the composition can contain the solvent in an amount of 50 to 500 parts by mass and preferably in an amount of 80 to 200 parts by mass, with respect to a total of 100 parts by mass of the polymerizable compounds and the photopolymerization initiators.

Additives

If necessary, the aforementioned composition can optionally further contain one or more kinds of known additives. Examples of the additives include an ultraviolet absorber, a surface conditioner, a brittleness improving agent, inorganic particles, organic particles, a leveling agent, a polymerization inhibitor, and the like. For details of these, for example, paragraphs “0032” to 0034” in JP2012-229412A can be referred to. The additives are not limited to the above, and it is possible to use various additives which can be generally used in an active energy ray-curable composition. The amount of the additives added to the composition may be appropriately adjusted, and is not particularly limited.

From the viewpoint of improving durability of the polarizing plate of the present invention, it is preferable that the aforementioned cured layer contains an ultraviolet absorber. Particularly, in an aspect in which the polarizing plate of the present invention is used as a front panel of an image display apparatus, it is preferable that the cured layer contains an ultraviolet absorber. The ultraviolet absorber which can be contained in the cured layer is not particularly limited. Examples of the ultraviolet absorber include the compounds described in paragraphs “0107” to “0185” in JP2006-184874A. Furthermore, a so-called polymer-based ultraviolet absorber can be preferably used. For example, it is possible to preferably use the polymer-based ultraviolet absorbers described in JP1994-148430A (JP-H06-148430A).

In a case where the composition for forming the aforementioned cured layer contains an ultraviolet absorber, the content of the ultraviolet absorber in the composition can be appropriately determined according to the type of the ultraviolet absorber, the condition of use thereof, and the like. For example, it is preferable that the amount of the ultraviolet absorber contained in the composition is preferably 0.1% to 10% by mass (in a case where the total amount of solid content is regarded as being 100% by mass) with respect to the total amount of solid content of the composition.

As examples of the ultraviolet absorber, the following compounds UV-1 to UV-4 can be exemplified, but the present invention is not limited thereto.

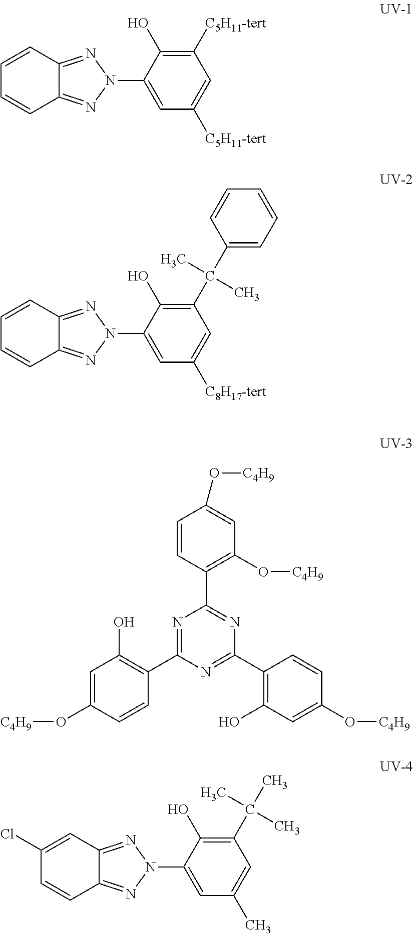

When an ultraviolet absorber is used, it is preferable that the ultraviolet absorber and the radical photopolymerization initiator are combined such that the absorption wavelengths of the ultraviolet absorber and the radical photopolymerization initiator do not overlap each other. Specifically, as the radical photopolymerization initiator, phosphine oxide-based compounds absorbing wavelengths that are longer than the wavelengths absorbed by the ultraviolet absorber are preferable which include. Examples of the phosphine oxide-based compound include bis(2,4,6-trimethylbenzoyl)-phenylphosphine oxide (such as IRGACURE 819 manufactured by BASF SE), bis(2,6-dimethoxybenzoyl)-2,4,4-trimethyl-pentylphosphoine oxide, and 2,4,6-trimethylbenzoyl-diphenyl-phosphine oxide (such as LUCIRIN TPO manufactured by BASF SE). By using the aforementioned radical initiator, it is possible to prevent the ultraviolet absorber from inhibiting the curing. In contrast, as the cation photopolymerization initiator, it is preferable to combine a compound absorbing wavelengths that are longer than the wavelengths absorbed by the ultraviolet absorber, such as IRGACURE PAG 103, IRGACURE PAG 121, or CGI 725 manufactured by BASF SE, with the ultraviolet absorber.

As described above, it is preferable to combine a polymerization initiator absorbing wavelengths longer than wavelengths absorbed by an ultraviolet absorber with the ultraviolet absorber. Furthermore, it is also preferable to use a curing accelerator (sensitizer) in combination. By using the sensitizer in combination, the amount of the polymerization initiator added can be reduced, and the selection of materials can be widened. Examples of the sensitizer which can be used in combination include various photosensitizers such as n-butylamine, triethylamine, tri-n-butylphosphine, Michler's ketone, thioxanthone, anthracene, diphenylbutadiene, distyrylbenzene, and acridone.

It is also preferable that the aforementioned cured layer contains a brittleness improving agent. The brittleness improving agent can contribute to the improvement of folding and bending properties of the polarizing plate of the present invention. The brittleness improving agent is not particularly limited, and as the brittleness improving agent, it is possible to use a polyester urethane-based compound, a polyether-based compound, a polyurethane-based compound, a polyether polyurethane-based compound, a polyamide-based compound, a polysulfone-based compound, a polysulfonamide-based compound, and other polymer-based compounds having a number-average molecular weight equal to or greater than 600. Among these, a polyester urethane-based compound is preferable.

The polyester urethane-based compound is a polymer having an ester bond and a urethane bond (—OCO—NH—) in one molecule.

The polyester urethane-based compound can be synthesized using monomers including at least a diol, a dicarboxylic acid, and a diisocyanate. These three kinds of monomers preferably have a structure in which (a) hydroxyl (—OH), (b) carboxyl (—COOH), and (c) isocyanate (—NCO) are bonded to each of both terminals of a hydrocarbon group having an unbranched structure.

The hydrocarbon group having an unbranched structure is preferably an alkylene group, an alkenylene group, an alkynylene group, an arylene group, or a combination of these.

It is preferable that the alkylene group, the alkenylene group, and the alkynylene group have a linear structure.

In a case where the aforementioned hydrocarbon group is an alkylene group, an alkenylene group, or an alkynylene group, the number of carbon atoms in the hydrocarbon group is preferably 1 to 8, more preferably 2 to 6, and particularly preferably 2 to 4.

The arylene group may have an alkyl group having 1 to 8 carbon atoms as a substituent.

The arylene group is preferably a phenylene group or a naphthylene group, more preferably a phenylene group, and most preferably a p-phenylene group.

The hydrocarbon group is particularly preferably the aforementioned alkylene group, the aforementioned arylene group, or a combination of these.

As the diol, ethylene glycol, 1,3-propanediol, 1,4-butanediol, neopentyl glycol, 1,6-hexanediol, 1,4-cyclohexanedimethanol, and 1,5-pentanediol are preferable.

As the dicarboxylic acid, terephthalic acid, isophthalic acid, naphthalenedicarboxylic acid, 1,4-cyclohexanedicarboxylic acid, succinic acid, glutaric acid, adipic acid, oxalic acid, and malonic acid are preferable.

As the diisocyanate, ethylene diisocyanate, trimethylene diisocyanate, tetramethylene diisocyanate, hexamethylene diisocyanate, isophorone diisocyanate, m-xylylene diisocyanate, p-phenylene diisocyanate, tolylene diisocyanate, p,p′-diphenylmethane diisocyanate, and 1,5-naphthalene diisocyanate are preferable.

The number-average molecular weight of the polyester urethane-based compound is preferably within a range of 2,000 to 100,000, and more preferably within a range of 5,000 to 50,000.

The content of the polyester urethane-based compound, with respect to the total amount of solid content of the aforementioned composition for forming a cured layer, is preferably within a range of 1% to 20% by mass, more preferably 2% to 15% by mass, and even more preferably 3% to 10% by mass.

Examples of commercial products of the polyester urethane-based compound include a VYLON series (trade name) manufactured by Toyobo Co., Ltd., and the like. It is possible to preferably use VYLON UR-1510, VYLON UR-2300, VYLON UR-3200, VYLON UR-3210, VYLON UR-3260, VYLON UR-6100, VYLON UR-8300, VYLON UR-8700, and the like.

Furthermore, one or more kinds of compounds selected from the group consisting of known silicone-based compounds and fluorine-based compounds that can be used as an antifoulant, a lubricant, and the like can be appropriately added as additives to the aforementioned composition. From the viewpoint of achieving either or both the inhibition of adhesion of a contaminant such as a finger print and the easy removal of the adhered contaminant, the cured layer formed using the composition containing these compounds is preferable. The amount of the compounds added is not particularly limited, but is, with respect to the total solid content of the composition, preferably 0.01% to 20% by mass, more preferably 0.05% to 10% by mass, and even more preferably 0.1% to 5% by mass. The solid content refers to the components excluding a solvent, and the total solid content refers to the total amount of solid content.

As preferred examples of the silicone-based compound, the compound can be exemplified in which a substituent is on either or both of a terminal of a compound chain having a plurality of dimethylsilyloxy units as repeating units and a side chain of the compound chain. The compound chain containing dimethylsilyloxy units as repeating units may contain a structural unit other than the dimethylsilyloxy units. It is preferable that the compound has a plurality of substituents, and the substituents may be the same as or different from each other. Examples of the substituent include groups including an acryloyl group, a methacryloyl group, a vinyl group, an aryl group, a cinnamoyl group, an epoxy group, an oxetanyl group, a hydroxyl group, a fluoroalkyl group, a polyoxyalkylene group, a carboxyl group, an amino group, and the like. The molecular weight thereof is not particularly limited. The weight-average molecular weight thereof is preferably equal to or less than 100,000, more preferably 50,000, even more preferably 3,000 to 30,000, and still more preferably 10,000 to 20,000. The content of silicone atoms in the silicone-based compound is not particularly limited, but is preferably equal to or greater than 18.0% by mass, more preferably 25.0% to 37.8% by mass, and even more preferably 30.0% to 37.0% by mass. Examples of preferred silicone-based compounds include X-22-174DX, X-22-2426, X-22-164B, X22-164C, X-22-170DX, X-22-176D, and X-22-1821 (all trade names) manufactured by Shin-Etsu Chemical Co., Ltd., FM-0725, FM-7725, FM-4421, FM-5521, FM 6621, and FM-1121 manufactured by CHISSO CORPORATION, DMS-U22, RMS-033, RMS-083, UMS-182, DMS-H21, DMS-H31, HMS-301, FMS121, FMS123, FMS131, FMS141, and FMS221 (all trade names) manufactured by Gelest, Inc., and the like, but the present invention is not limited to these.

As the fluorine-based compound, a compound having a fluoroalkyl group is preferable. The number of carbon atoms in the fluoroalkyl group is preferably 1 to 20, and more preferably 1 to 10. The fluoroalkyl group may have a linear structure (such as —CF₂CF₃—, —CH₂(CF₂)₄H, —CH₂(CF₂)CF₃, or —CH₂CH₂(CF₂)₄H), a branched structure (such as CH(CF₃)₂, CH₂CF(CF₃)₂, CH(CH₃)CF₂CF₃, or CH(CH₃)(CF₂)₅CF₂H), or an alicyclic structure (preferably a 5-membered ring or a 6-membered ring, such as a perfluorocyclohexyl group, a perfluorocyclopentyl group, or an alkyl group substituted with these), or may have an ether bond (such as CH₂OCH₂CF₂CF₃, CH₂CH₂OCH₂C₄F₈H, CH₂CH₂OCH₂CH₂CF₁₇, or CH₂CH₂OCF₂CF₂OCF₂CF₂H). The fluorine-based compound may contain a plurality of fluoroalkyl groups in the same molecule.

Furthermore, the fluorine-based compound can have one or more substituents and preferably two or more substituents such as an acryloyl group, a methacryloyl group, a vinyl group, an aryl group, a cinnamoyl group, an epoxy group, an oxetanyl group, hydroxyl group, a polyoxyalkylene group, a carboxyl group, and an amino group. The molecular weight of the fluorine-based compound is not particularly limited. The content of fluorine atoms in the fluorine-based compound is not particularly limited, but is preferably equal to or greater than 20% by mass, more preferably 30% to 70% by mass, and most preferably 40% to 70% by mass. Examples of preferred fluorine-based compounds include R-2020, M-2020, R-3833, and M-3833 (all trade names) manufactured by DAIKIN INDUSTRIES, LTD., MEGAFACE F-171, F-172, and F-179A and DEFENSA MCF-300 (all trade names) manufactured by DIC Corporation, and the like, but the present invention is not limited to these.

In addition, regarding the antifoulant which can be added to the aforementioned composition, paragraphs “0012” to “0101” in JP2012-88699A can be referred to.

As additives, for the purpose of imparting characteristics such as dust protection properties and antistatic properties, it is possible to appropriately add a dust protection agent, an antistatic agent, or the like such as a known cationic surfactant or a polyoxyalkylene-based compound. The dust protection agent and the antistatic agent may be contained in the aforementioned silicone-based compound or fluorine-based compound such that the structural unit thereof serves a part of the functions of the compound. In a case where these compounds are added as additives, the amount of the additives added, with respect to the solid content of the composition, is preferably within a range of 0.01% to 20% by mass, more preferably within a range of 0.05% to 10% by mass, and even more preferably within a range of 0.1% to 5% by mass. Examples of preferred compounds include MEGAFACE F-150 (trade name) manufactured by DIC Corporation, SH-3748 (trade name) manufactured by Dow Corning Toray Co., Ltd., and the like, but the present invention is not limited to these.

—Method for Preparing Composition—

The aforementioned active energy ray-curable composition can be prepared by simultaneously mixing the various components described above together or by sequentially mixing them together in an arbitrary order. The preparation method is not particularly limited, and a known stirrer or the like can be used.

—Method for Coating Composition—

The aforementioned composition is an active energy ray-curable composition, and can be used for forming a cured layer by coating a coating surface such as the surface of a base material and then irradiated with active energy rays. Coating can be performed by a known coating method described above. The amount of the composition used for coating may be adjusted such that a cured layer having a desired film thickness can be formed. The thickness of the cured layer is, for example, equal to or greater than 3 μm, preferably equal to or greater than 5 μm, more preferably equal to or greater than 10 μm, even more preferably equal to or greater than 20 μm, still more preferably greater than 20 μm, and yet more preferably equal to or greater than 30 μm. From the viewpoint of improving the hardness, it is preferable that the cured layer is thick. In contrast, from the viewpoint of thinning the polarizing plate in which the cured layer is formed, it is preferable that the cured layer is thin. In this respect, the thickness of the cured layer is preferably equal to or less than 500 μm, more preferably equal to or less than 300 μm, even more preferably equal to or less than 100 μm, still more preferably equal to or less than 80 μm, and yet more preferably equal to or less than 60 μm. By simultaneously or sequentially coating the base material with two or more kinds of compositions of a different makeup, the cured layer can be formed as a layer having a laminated structure consisting of two or more layers (for example, about two to five layers). In this case, as at least one hardcoat layer, it is preferable to use the aforementioned active energy ray-curable composition. The thickness of the layer having the laminated structure described above refers to the total thickness of the plurality of layers laminated.

—Curing Treatment—

By irradiating the composition, with which the base material is coated, with active energy rays (light irradiation), polymerization reactions of the radically polymerizable compound and the cationically polymerizable compound are respectively initiated and carried out by the action of the radical photopolymerization initiator and the cation photopolymerization initiator. The wavelength of the light to be radiated may be determined according to the type of the polymerizable compound and the polymerization initiator used. Examples of light sources for light irradiation include a high-pressure mercury lamp that emits light having a wavelength within a range of 150 to 450 nm, an ultra-high-pressure mercury lamp, a carbon arc lamp, a metal halide lamp, a xenon lamp, a chemical lamp, an electrodeless discharge lamp, a light emitting diode (LED), and the like. The amount of light radiated is generally within a range of 30 to 3,000 mJ/cm², and preferably within a range of 100 to 1,500 mJ/cm². If necessary, a drying treatment may be performed before and after the light irradiation or before or after the light irradiation. The drying treatment can be performed by blowing hot air, disposing the base material in a heating furnace, transporting the base material in a heating furnace, or the like. The heating temperature may be set to be a temperature at which the solvent can be dried and removed, but is not particularly limited. Herein, the heating temperature refers to the temperature of the hot air or the internal atmospheric temperature of the heating furnace.

(Decorative Layer)

In a front panel or the like of a display apparatus, for the purpose of concealing wiring so as to prevent the wiring from being visually recognized or for the purpose of decoration, a decorative layer is provided in the outer peripheral portion thereof or the like. In an aspect, the polarizing plate of the present invention can have a decorative layer. The decorative layer can be formed by printing a composition for forming a decorative layer onto a portion of a printing surface by a known printing method. The composition for forming a decorative layer (decorating agent) can be obtained as a commercial product, or can be prepared by a known method such as mixing of a binder with a colorant at an arbitrary ratio. Examples of the binder include a vinyl-based resin, a polyamide-based resin, a polyester-based resin, an acryl-based resin, a polyurethane-based resin, a polyvinyl acetal-based resin, an alkyd-based resin, and the like. As the colorant, it is possible to use a pigment or dye of an appropriate color. The composition for forming a decorative layer can be a photosensitive composition which additionally contains a polymerizable compound, a polymerization initiator, and a solvent. In this case, by printing the composition for forming a decorative layer and then performing light irradiation, the decorative layer can be formed. Examples of the printing method include various printing methods such as screen printing, offset printing, gravure printing, flexographic printing, and thermal transfer printing. By performing printing plural times, the thickness of the decorative layer can be increased.

The decorative layer is not limited to the layer formed by a printing method. For example, the decorative layer may be formed by performing coating by using the composition for forming a decorative layer by a known coating method. As the coating method, for example, it is possible to use methods such as a slit coating method, an ink jet method, a spray method, a roll coating method, a spin coating method, a cast coating method, a slit-and-spin coating method, a transfer method. Examples of the ink jet method include the methods described in “Application of Ink Jet Technologies to Electronics” (REALIZE Science and Engineering, Sep. 29, 2006). Furthermore, a so-called prewet method described in JP2009-145395A can be used.

In addition, a decorative layer of a desired shape may be formed by a known method such as lithography or exposure development.

The thickness of the decorative layer is not particularly limited, but is generally about 0.5 to 40 μm. In view of transmittance, in a case where the decorative layer is black, the thickness is preferably 0.5 to 10 μm, and in a case where the decorative layer is white, the thickness is preferably 10 to 40 μm. The decorative layer may be a layer having a laminated structure consisting of two or more layers. As the layer included in the layers constituting the laminated structure, a metal-containing layer can be exemplified which is formed of a metal material by a vacuum deposition method, a sputtering method, an ion plating method, or a plating method. By providing the metal-containing layer, it is possible to form a decorative layer having a metallic luster. The metal material may be selected according to the desired color of the metal luster. For example, it is possible to use a metal such as aluminum, nickel, gold, platinum, chrome steel, copper, tin, indium, silver, titanium, lead, or zinc and an alloy or a compound of these. The thickness of the metal-containing layer is generally about 0.05 μm, but the present invention is not limited thereto.

The decorative layer can be provided in a portion (such as an outer peripheral portion) of one of the surfaces of the base material, for example. It is preferable that the decorative layer is provided on the interlayer side of the base material, because then the surface of the polarizing plate of the present invention can be made flat.

Each of the films and layers described so far is preferably transparent. “Transparent” means that the film or the layer transmits visible light. Transmitting visible light means that the light transmittance of the film or the layer in a visible region is equal to or higher than 60%, preferably equal to or higher than 80%, and more preferably equal to or higher than 90%. The light transmittance used as a measure of transparency is a value calculated in a manner in which a total light transmittance and an amount of scattering light are measured by the method described in JIS-K7105, that is, by using an integrating sphere-type light transmittance analyzer, and then subtracting a diffuse transmittance from the total light transmittance to determine the light transmittance.

<Method for Manufacturing Polarizing Plate>

The polarizing plate of the present invention can be manufactured by any method without particular limitation, as long as the base material, the interlayer, the adhesive layer, and the polarizer layer are laminated in this order. For example, by bonding a first laminate including at least the base material to a second laminate including at least the polarizer layer, the polarizing plate of the present invention can be manufactured. It is preferable to bond the laminates to each other such that the direction of an absorption axis of the polarizer layer becomes orthogonal to the direction of a slow axis of the base material or the resin film, because then light does not easily leak. In the present invention and the present specification, the direction of an optical axis such as the direction of an absorption axis or the direction of a slow axis is a direction of an average alignment angle of the direction of an optical axis determined using a molecular alignment meter manufactured by Oji Scientific Instruments.

The interlayer and the adhesive layer may be formed on the first laminate side or on the second laminate side. Furthermore, the base material may be laminated on the second laminate before bonding or may be laminated on the polarizer layer after bonding. The aforementioned cured layer obtained by curing the active energy ray-curable composition may be formed on the first laminate side before bonding or may be formed on the base material after bonding. The polarizing plate of the present invention can also be manufactured by a Roll-to-Roll method.

By adopting the constitution described so far, it is possible to inhibit cracking from occurring on the edge of the polarizing plate, in which the base material containing at least a resin film and having a thickness of equal to or greater than 120 μm and the polarizer layer are laminated through the adhesive layer, when the polarizing plate is cut into a product size by using a punching blade or by a known cutting (punching) process such as die cutting.

[Front Panel of Display Device and Display Apparatus]

The polarizing plate of the present invention can be used as a front panel of a display device. The front panel of a display device is a member positioned on a viewing side above a display device in a display apparatus. The front panel is provided for the purpose of protecting the display device, and the like. The base material of the front panel of the display device of the present invention (hereinafter, simply described as a “front panel” as well) can function as a polarizing plate protective film.

An aspect of the present invention relates to a display apparatus having the polarizing plate (front panel) and the display device of the present invention.

Examples of the display device include a liquid crystal display device, a plasma display device, an electroluminescence (EL) display device, and the like. In a case where the polarizing plate of the present invention has a cured layer, which is obtained by curing an active energy ray-curable composition, on a base material, it is preferable that the display device is disposed such that the cured layer faces a viewing side and the polarizer layer faces the display device side.

Examples of the liquid crystal display device include a Twisted Nematic (TN) type, a Super-Twisted Nematic (STN) type, a Triple Super Twisted Nematic (TSTN) type, a multi domain type, a Vertical Alignment (VA) time, an In Plane Switching (IPS) type, an Optically Compensated Bend (OCB) type, and the like.

Examples of the display device include an in-cell touch panel device and an on-cell touch panel display device obtained by incorporating a touch panel function into any one of the aforementioned types of display devices. The examples also include those obtained by bonding a film-type touch sensor to a display device. The in-cell touch panel display device can be, for example, an in-cell touch panel liquid crystal display device obtained by incorporating the function of a resistive film-type touch panel, a capacitance-type touch panel, or an optical touch panel into a liquid crystal device prepared by interposing a liquid crystal layer between two glass substrates. To the in-cell touch panel liquid crystal device, for example, the known techniques described in JP2011-76602A, JP2011-222009A, and the like can be applied without limitation.

The on-cell touch panel display device preferably can be an on-cell touch panel liquid crystal display device obtained by incorporating the function of a resistive film-type touch panel, a capacitance-type touch panel, or an optical touch panel into the space between the glass substrates, between which a liquid crystal layer is interposed, and a polarizing plate. The on-cell touch panel liquid crystal device is described in, for example, JP2012-88683A.

When being used in a touch panel or the like, the touch sensor may have an optical adjustment layer, which is for adjusting a difference in the refractive index between the sensor and a transparent electrode layer, on at least one surface thereof.

The method for manufacturing the optical adjustment layer is not particularly limited, and for example, the method described in JP2012-206307A can be used.

The liquid crystal display apparatus includes at least a liquid crystal cell (liquid crystal display device) and a polarizing plate disposed on both sides of the liquid crystal cell. The polarizing plate includes at least a polarizer layer. Regarding the polarizing plates between which the liquid crystal cell is interposed, the polarizing plate disposed on the viewing side across the liquid crystal cell is called a front polarizing plate, and the polarizing plate disposed on the backlight side is called a rear polarizing plate. The polarizing plate of the present invention is suitable as a front polarizing plate, and can play a role of front panel.

The polarizing plate can include a polarizing plate protective film on both sides of the polarizer layer. In the polarizing plate, the protective film disposed on the liquid crystal cell side is called an inner layer, and the protective film disposed on the opposite side is called an outer layer. In the polarizing plate of the present invention, the base material preferably can be the outer layer, and the resin film preferably can be the inner layer. Furthermore, the cured layer obtained by curing the aforementioned active energy ray-curable composition may be provided on the outer layer.

In the display apparatus, in addition to the polarizing plate of the present invention, various members known in the related art can be used without limitation.

[Substrate of Touch Panel, Resistive Film-Type Touch Panel, and Capacitance-Type Touch Panel]

The polarizing plate of the present invention can be used as a substrate of a touch panel.

A resistive film-type touch panel has a basic constitution in which conductive films of a pair of upper and lower substrates having conductive films are disposed having a spacer therebetween. Provided that the viewing side is called an upper portion and the opposite side is called a lower portion, the touch panel has a substrate for an upper electrode and a substrate for a lower electrode. In an aspect, the polarizing plate of the present invention can be used as the substrate for the upper electrode. In this case, it is preferable that the polarizing plate of the present invention is disposed such that the base material faces the viewing side and the polarizer layer faces the side of the substrate for a lower electrode. The constitution of the resistive film-type touch panel is known, and in the present invention, known techniques can be used without limitation.

In an aspect, the polarizing plate of the present invention can also be used as a substrate of a capacitance-type touch panel. Examples of the capacitance-type touch panel include a surface capacitance-type touch panel and a projected capacitance-type touch panel. The projected capacitance-type touch panel has a basic constitution in which an X-axis electrode and a Y-axis electrode orthogonal to the X-axis electrode are disposed having an insulator therebetween. Specific aspects thereof include an aspect in which the X electrode and the Y electrode are formed on each surface of one substrate, an aspect in which the X electrode, the insulating layer, and the Y electrode are formed in this order on one substrate, an aspect in which the X electrode is formed on one substrate and the Y electrode is formed on the other substrate (in this aspect, a constitution in which two substrates are bonded to each other is the aforementioned basic constitution), and the like. The polarizing plate of the present invention is suitable as the substrate in any of the aforementioned aspects. It is preferable that, in the capacitance-type touch panel, the polarizing plate (substrate) of the present invention is disposed such that the base material is positioned on the viewing side and the polarizer layer is positioned on the opposite side.

### EXAMPLES

Hereinafter, the present invention will be more specifically described based on examples. The materials, reagents, amount and ratio of substances, operation, and the like shown in the following examples can be appropriately changed within a scope that does not depart form the gist of the present invention. Accordingly, the scope of the present invention is not limited to the following specific examples. In the following description, unless otherwise specified, “%” means “% by mass”. Furthermore, unless otherwise specified, a mixing ratio means a mass ratio. In addition, in the examples described below, unless otherwise specified, coating is performed for the entirety of a coating surface.

<Preparation of Polarizer (Polarizer Layer)>

A polymer film (“VF-PS #7500” manufactured by KURARAY CO., LTD.) having a thickness of 75 μm and containing a polyvinyl alcohol-based resin as a main component was immersed into 5 baths under the following conditions [1] to [5] in a state where tension was being applied to the longitudinal direction of the film. The film was then stretched such that the final length thereof increased by a factor of 6.2 compared to the original length of the film. The stretched film was dried for 1 minute in an air circulation-type oven (internal atmospheric temperature: 40° C.), thereby preparing a polarizer.

(Conditions)

[1] Swelling bath: pure water with a temperature of 30° C.

[2] Staining bath: aqueous solution with a temperature of 30° C. containing 0.032 parts by mass of iodine and 0.2 parts by mass of potassium iodide with respect to 100 parts by mass of water

[3] First cross-linking bath: aqueous solution with a temperature of 40° C. containing 3% by mass of potassium iodide and 3% by mass boric acid

[4] Second cross-linking bath: aqueous solution with a temperature of 60° C. containing 5% by mass potassium iodide and 4% by mass boric acid

[5] Rinsing bath: aqueous solution with a temperature of 25° C. containing 3% by mass of potassium iodide

<Resin Film (Retardation Film)>

As a resin film (retardation film) laminated on a side of the polarizer layer that is opposite to the base material, a stretched cyclic olefin film (ARTON, film thickness: 28 μm) manufactured by JSR Corporation was used.

### Preparation of Adhesive

### Preparation Example 1

100 parts by mass of a polyvinyl alcohol resin “PVA 117H” (degree of polymerization: 1,700, degree of saponification: 99.3%) manufactured by KURARAY CO., LTD. and 100 parts by mass of potassium iodide were dissolved in pure water with a temperature of 30° C., and the concentration of the solid content thereof was adjusted to be 3% by mass, thereby preparing a composition for forming an adhesive layer S-1.

### Preparation Example 2

2.0 g of an epoxy-based compound “DENACOL EX-211” manufactured by Nagase ChemteX Corporation and 0.15 g of a photobase generator “WPBG-056” manufactured by Wako Pure Chemical Industries, Ltd. were weighed out into a 20 ml screw cap tube and mixed and defoamed together, thereby preparing a composition for forming an adhesive layer S-2.

<Preparation of Composition for Forming Interlayer>

(Resin (Binder))
PVA (1): carboxylic acid-modified polyvinyl alcohol resin with a degree of saponification of 77% and a degree of polymerization of 600 (manufactured by KURARAY CO., LTD.)
PVA (2): carboxylic acid-modified polyvinyl alcohol resin with a degree of saponification of 87% and a degree of polymerization of 1,800 (manufactured by KURARAY CO., LTD.)
PVA (3): polyvinyl alcohol resin with a degree of saponification of 73% and a degree of polymerization of 500 (manufactured by KURARAY CO., LTD.)
Acryl-based resin: obtained by polymerizing monomer having the following composition

Emulsion polymer of methyl methacrylate/styrene/2-ethylhexyl acrylate/2-hydroxyethyl methacrylate/acrylic acid=59/9/26/5/1 (mass ratio) (emulsifier: anionic surfactant)
Polyester resin: as a polyester-based resin, a sulfonic acid-based aqueous dispersion of a polyester-based resin temperature by copolymerizing a monomer having the following composition was used.

Monomer composition: (acid component) terephthalic acid/isophthalic acid/5-sodiumsulfophthalic acid//(diol component) ethylene glycol/diethylene glycol=44/46/10//84/16 (molar ratio)

(Cross-Linking Agent)
Cross-linking agent (isocyanate-based compound A): an isocyanate-based compound A was prepared according to the following procedure. Nitrogen purging was performed in a 4-neck flask equipped with a stirrer, a thermometer, a reflux cooling pipe, and a nitrogen inlet pipe. The flask was filled with 1,000 parts by mass of hexamethylene diisocyanate (HDI) and 22 parts by mass of trimethylolpropane (molecular weight: 134) as a triol, and in a state where the internal temperature of the reactor was kept at 90° C. for 1 hour with stirring, urethanization was performed. Then, the temperature of the reaction solution was kept at 60° C., trimethylbenzyl ammonium-hydroxide was added thereto as an isocyanuration catalyst. At a point in time when the inversion rate reached 48%, phosphoric acid was added thereto such that the reaction stopped. Thereafter, the reaction solution was filtered, and then the unreacted HDI was removed using a thin-film evaporator.

The viscosity of the obtained isocyanate-based compound A at 25° C. was 25,000 mPa·s, the content of an isocyanate group in the compound was 19.9% by mass, the number-average molecular weight of the compound was 1,080, and the average number of isocyanate groups in the compound was 5.1. The number-average molecular weight was measured by GPC and expressed in terms of polystyrene. Then, through Nuclear Magnetic Resonance (NMR) analysis, the existence of a urethane bond, an allophanate bond, and an isocyanurate bond was checked.

Nitrogen purging was performed in a 4-neck flask equipped with a stirrer, a thermometer, a reflux cooling pipe, a nitrogen inlet tube, and a dropping funnel. The flask was filled with 100 parts by mass of the isocyanate compound A obtained as above, 42.3 parts by mass of methoxypolyethylene glycol having a number-average molecular weight of 400, and 76.6 parts by mass of dipropylene glycol dimethyl ether, and kept at 80° C. for 6 hours. Then the reaction temperature was cooled to 60° C., 72 parts by mass of diethyl malonate and 0.88 parts by mass of a 28% methanol solution of sodium methylate were added thereto, and the resulting solution was held as it was for 4 hours. Thereafter, 0.86 parts by mass of 2-ethylhexyl acid phosphate was added thereto.

Subsequently, 43.3 parts by mass of diisopropylamine was added thereto, and the temperature of the reaction solution was kept at 70° C. for 5 hours. By analyzing the reaction solution through gas chromatography, it was confirmed that a reaction rate of diisopropylamine was 70%. In this way, the isocyanate-based compound A was obtained (concentration of solid content: 70% by mass, amount of effective NCO group: 5.3%).

(Other Components)
Cross-linking catalyst: organic tin-based compound (ERASTRON Cat 21 manufactured by DKS Co., Ltd.)
Particles: silica sol having average particle size of 80 nm
Barbituric acid-based compound: barbituric acid-based compound A having the following structure (example compound (A-4) described above)

Barbituric Acid-Based Compound A

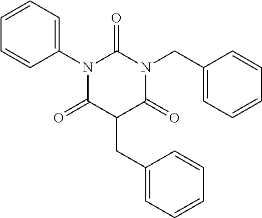 [SMILES: O=C1C(Cc2ccccc2)C(=O)N(c2ccccc2)C(=O)N1Cc1ccccc1]

Surfactant: polyethylene oxide-based surfactant (NAROACTY CL-95 manufactured by Sanyo Chemical Industries, Ltd.)

<Synthesis of Barbituric Acid-Based Compound A (Example Compound A-4)>

The example compound A-4 was synthesized according to the following scheme.

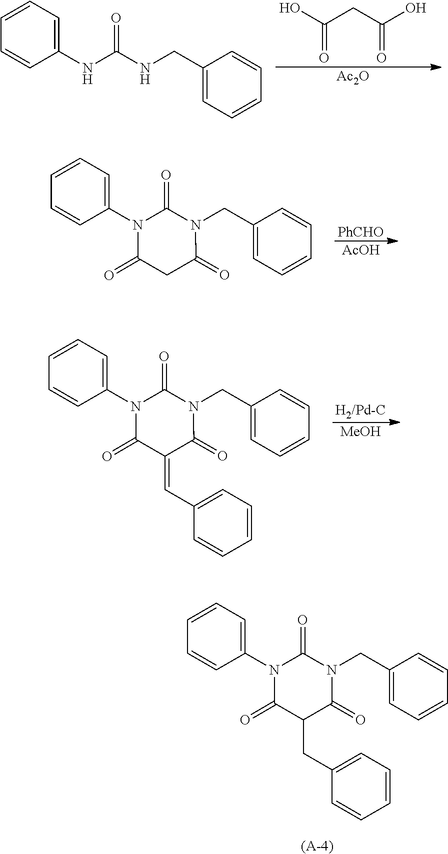

(In the above scheme, Ph represents a phenyl group, AcOH represents acetic acid, and Me represents a methyl group.)

### 1) Synthesis of Intermediate N-benzyl-N′-phenylurea

A 5 L glass flask equipped with a thermometer, a reflux cooling pipe, and a stirrer was filled with 321 g of benzyl alcohol and 2 L of acetonitrile and cooled in a water bath. While the reaction solution was being stirred, 358 g of phenyl isocyanate was added dropwise thereto at a rate at which the internal temperature of the reaction solution became equal to or lower than 40° C. The reaction solution was stirred as it was for 2 hours, 2 L of water was added thereto, and suction filtration was performed. The precipitated crystals were collected by filtration and washed three times with 1 L of water. The obtained crystals were dried at 80° C. under reduced pressure, thereby obtaining 610 g of N-benzyl-N′-phenylurea as an intermediate.

### 2) Synthesis of Intermediate 1-benzyl-3-phenylbarbiturate

A 300 ml glass flask equipped with a thermometer, a reflux cooling pipe, and a stirrer was filled with 5.0 g of N-benzyl-N′-phenylurea synthesized in above section 1), 2.5 g of malonic acid, 20 mL of toluene, and 5.6 g of acetic anhydride. While being stirred, the reaction solution was heated such that the internal temperature thereof became 80° C., and continuously stirred as it was for 3 hours at 80° C. Then, the reaction solution was cooled to 50° C., 15 mL of water was added to so as to perform liquid separation, and the water phase was discarded. While the organic layer was being stirred at room temperature, 5 mL of isopropanol was added dropwise thereto. The organic layer was further stirred for 0.5 hours at 10° C., and then suction filtration was performed. The precipitated crystals were collected by filtration, washed with cooled isopropanol, and then dried, thereby obtaining 4.6 g of 1-benzyl-3-phenylbarbiturate as an intermediate.

### 3) Synthesis of Intermediate 1-benzyl-5-benzylidene-3-phenylbarbiturate

A 300 ml glass flask equipped with a thermometer, a reflux cooling pipe, and a stirrer was filled with 4.0 g of 1-benzyl-3-phenylbarbiturate, 1.6 g of benzaldehyde, and 40 mL of acetic acid, and a drop of sulfuric acid was added thereto. While being stirred, the reaction solution was heated such that the internal temperature thereof became 100° C., and then continuously stirred as it was for 3 hours at 100° C. Thereafter, the reaction solution was cooled to 50° C., a mixed solution of 39 mL of isopropanol and 17 mL of water was added thereto, followed by stirring for 1 hour at a temperature of equal to or lower than 10° C. Subsequently, suction filtration was performed, and the precipitated crystals were collected by filtration and washed with methanol, thereby obtaining 3.9 g of 1-benzyl-5-benzylidene-3-phenylbarbiturate as an intermediate.

The structure of the obtained compound was checked by ¹H-NMR spectroscopy.

¹H-NMR (300 MHz, CDCl₃), δ: 8.70 (s, 1H), 8.10 (d, 2H), 7.58-7.20 (m, 15H), 5.20 (s, 2H)

### 4) Synthesis of Example Compound A-4

A 50 ml autoclave was filled with 3.5 g of 1-benzyl-5-dibenzylidene-3-phenylbarbiturate and 8 mL of methanol, and 0.1 g of Pd—C(10%) was added thereto. With stirring, the autoclave was filled with H2, and the reaction solution was heated such that the internal temperature became 50° C. and then continuously stirred for 3 hours as it was at 50° C. Then, Pd—C was separated by filtration, the reaction solution was cooled to 5° C., and 4 mL of water was added thereto, followed by stirring for 1 hour at 5° C. Then, suction filtration was performed, the precipitated crystals were collected by filtration, washed with a mixed solvent of methanol/water=1/1, and then dried, thereby obtaining 3.0 g of example compound A-4.

The structure of the obtained compound was checked by ¹H-NMR spectroscopy, Infrared absorption (IR) spectroscopy, and mass spectroscopy.

¹H-NMR (300 MHz, CDCl₃), δ: 7.52-7.16 (m, 10H), 5.10 (s, 2H), 3.86 (s, 2H)

(Preparation of Composition for Forming Interlayer)

By mixing the components together according to the composition shown in the following Table 2, the compositions for forming an interlayer E-1 to E-11 were prepared. The numerical values in Table 2 relating to the components excluding a solvent represent “a proportion (% by mass) of each component in the total amount of solid content”. The numerical values relating to the solvent show a proportion of the solvent (that is, the solvent is completely composed of water).

TABLE 2

| | Composition for | | | | | | |
|---|---|---|---|---|---|---|---|
| | forming interlayer | E-1 | E-2 | E-3 | E-4 | E-5 | E-6 |
| Resin | PVA(1) | 57.60% | | | | 57.60% | 57.60% |
| | PVA(2) | | 57.60% | | | | |
| | PVA(3) | | | 57.60% | | | |
| | Polyester- | | | | | | |
| | based resin | | | | | | |
| | Acryl-based | 28.80% | 28.80% | 28.80% | 86.40% | 28.79% | 28.70% |
| | resin | | | | | | |
| Cross-linking | Isocyanate-based | 4.00% | 4.00% | 4.00% | 4.00% | 4.00% | 4.00% |
| agent | compound A | | | | | | |
| Cross-linking | Organic tin | 0.70% | 0.70% | 0.70% | 0.70% | 0.70% | 0.70% |
| catalyst | compound | | | | | | |
| Particles | Silica | 8.10% | 8.10% | 8.10% | 8.10% | 8.10% | 8.10% |
| Barbituric acid- | A-4 | | | | | 0.01% | 0.10% |
| based compound | | | | | | | |
| Surfactant | | 0.80% | 0.80% | 0.80% | 0.80% | 0.80% | 0.80% |
| Solvent | water | 100% | 100% | 100% | 100% | 100% | 100% |
| Proportion of | | 8.90% | 8.90% | 8.90% | 8.90% | 8.90% | 8.90% |
| solid content | | | | | | | |

| | Composition for | | | | | |
|---|---|---|---|---|---|---|
| | forming interlayer | E-7 | E-8 | E-9 | E-10 | E-11 |
| Resin | PVA(1) | 57.60% | 57.60% | 57.60% | 57.60% | 57.60% |
| | PVA(2) | | | | | |
| | PVA(3) | | | | | |
| | Polyester- | | | 28.80% | | |
| | based resin | | | | | |
| | Acryl-based | 27.80% | 18.80% | | 32.79% | 0.80% |
| | resin | | | | | |
| Cross-linking | Isocyanate-based | 4.00% | 4.00% | 4.00% | 0.01% | 32.00% |
| agent | compound A | | | | | |
| Cross-linking | Organic tin | 0.70% | 0.70% | 0.70% | 0.70% | 0.70% |
| catalyst | compound | | | | | |
| Particles | Silica | 8.10% | 8.10% | 8.10% | 8.10% | 8.10% |
| Barbituric acid- | A-4 | 1.00% | 10.00% | | | |
| based compound | | | | | | |
| Surfactant | | 0.80% | 0.80% | 0.80% | 0.80% | 0.80% |
| Solvent | water | 100% | 100% | 100% | 100% | 100% |
| Proportion of | | 8.90% | 8.90% | 8.90% | 8.90% | 8.90% |
| solid content | | | | | | |

### Example 1

### Preparation of Base Material

Pellets of an acryl-based resin “SUMIPEX EX” manufactured by Sumitomo Chemical Co., Ltd were put into a single screw extruder having an extrusion diameter of 65 mmφ, and a polycarbonate-based resin “CALIBRE 301-10” manufactured by Sumika Styron Polycarbonate Limited was put into a single screw extruder having an extrusion diameter of 45 mmφ. The resins were melted and integrated by being melted and laminated by a multi-manifold method, and extruded through a T-shaped dies set to be at a temperature of 260° C. The obtained film-like substance was interposed between a pair of metal rolls and molded, thereby preparing a base material which had a thickness (total thickness) described in Table 1 and constituted with three layers consisting of acryl-based resin layer/polycarbonate resin layer/acryl-based resin layer.

### Preparation of Base Material with Interlayer

One surface of the base material was subjected to a corona discharge treatment in a treatment amount of 500 J/m². Then, by a reverse roll method, the surface having undergone the corona discharge treatment was coated with the composition for forming an interlayer E-1 in a state where the amount of the composition was being adjusted such that the film had the thickness shown in Table 4 after drying. In this way, a base material with an interlayer was prepared.

### Preparation of Polarizing Plate

Through the composition for forming an adhesive layer s-1, the base material with an interlayer was bonded onto one surface of the aforementioned polarizer such that the slow axis of the base material became orthogonal to the absorption axis of the polarizer. The laminate obtained in this way was dried for 5 minutes in an oven having an internal atmospheric temperature of 60° C. to 90° C.

The dried laminate was transported in and passed through an oven having an internal atmospheric temperature of 80° C. for 10 minutes, thereby performing a heating treatment (annealing treatment). In this way, a polarizing plate of Example 1 was prepared. At this time, the thickness of the adhesive layer was 20 m.

### Example 2

A polarizing plate of Example 2 was prepared by the same method as in Example 1, except that, in Example 1, through the composition for forming an adhesive layer S-1, the aforementioned resin film (retardation film) was bonded to a side of the polarizer to which the base material was not bonded, such that the slow axis of the retardation film became orthogonal to the absorption axis of the polarizer. At this time, the thickness of the adhesive layer was 20 μm in both of the Examples 1 and 2.

### Examples 3 to 8

### Preparation of Base Material

A base material was prepared by the same method as in Example 1, except that the extrusion conditions were changed so as to obtain the total thickness shown in Table 4.

### Formation of Cured Layer (Hardcoat Layer)

The respective components were added according to the composition shown in the following Table 3 and filtered through a polypropylene filter having a pore size of 10 μm, thereby preparing an active energy ray-curable composition (composition for forming a hardcoat layer) HCl. The numerical values in Table 3 relating to the components excluding a solvent represent “a proportion (% by mass) of each component in the total amount of solid content”.

Regarding the solvent, the proportion thereof was adjusted to become the proportion described in Table 3, thereby preparing the composition in which a proportion of solid content was 54% by mass.

By using the composition for forming a hardcoat layer HCl, a hardcoat layer was formed on one surface of the base material such that the thickness of the hardcoat layer became as shown in Table 4 after a curing treatment (light irradiation), thereby preparing a base material with a cured layer.

Specifically, by a die coating method using a slot die which is used in examples of JP2006-122889A and shown in paragraph “0486” and FIG. 10 of the same document, the base material was coated with the composition for forming a hardcoat layer HCl under the condition of a transport rate of 30 m/min, and the composition was dried for 150 seconds at 60° C. Then, with nitrogen purging at an oxygen concentration of about 0.1% by volume, by using an air-cooled metal halide lamp (manufactured by EYE GRAPHICS Co., Ltd.) at 160 W/cm, the coating layer was cured by being irradiated with ultraviolet rays at an illuminance of 400 mW/cm² and an irradiation amount of 500 mJ/cm² such that a hardcoat layer was formed, and the base material was wound up.

Polarizing plates of Examples 3 to 8 were prepared by the same method as in Example 2, except that a corona discharge treatment was performed on a side of the base material with a hardcoat layer prepared as above that was opposite to the side provided with the hardcoat layer.

### Example 9

A polarizing plate of Example 9 was prepared by the same method as in Example 3, except that in Example 3, a plastic base material having a thickness of 300 μm (TECHNOLLOY C-101 manufactured by Sumika Acryl Co., Ltd; three-layered structure in which PMMA film/polycarbonate film/PMMA film are laminated in this order) was used as a base material.

### Examples 10 to 12 and 16 to 19

Polarizing plates of Examples 10 to 12 and 16 to 19 were prepared by the same method as in Example 9, except that an interlayer was prepared using any of the compositions for forming an interlayer E-2 to E-8 made up as shown in Table 2.

### Examples 13 to 15

Polarizing plates of Examples 13 to 15 were prepared by the same method as in Example 9, except that an interlayer was prepared to have a thickness described in Table 4.

### Examples 20 and 21

The respective components were added according to the composition shown in the following Table 3 and filtered through a polypropylene filter having a pore size of 10 μm, thereby preparing compositions for forming a hardcoat layer HC2 and HC3.

Polarizing plates of Examples 20 and 21 were prepared by the same method as in Example 9, except that a cured layer (hardcoat layer) was prepared using the prepared composition for forming a hardcoat layer.

TABLE 3

| | Composition for forming hardcoat layer | HC1 | HC2 | HC3 |
|---|---|---|---|---|
| Polymerizable | Example compound A-1 | 63.57% | | 60.57% |
| compound | Example compound A-10 | | 96.27% | |
| | Example compound B-1 | 9.50% | | 9.50% |
| | Example compound B-12 | 18.50% | | 18.50% |
| Photopolymerization | Irg127 | 3.70% | 3.70% | 3.70% |
| initiator | CPI-100P | 3.70% | | 3.70% |
| Antifoulant | RS-90 | 1.00% | | 1.00% |
| Ultraviolet absorber | UV-1 | | | 3.00% |
| Surfactant | FP-1 | 0.03% | 0.03% | 0.03% |
| Solvent | Methyl ethyl ketone | 25% | 25% | 25% |
| | Methyl isobutyl ketone | 75% | 75% | 75% |
| Proportion of solid content | | 54% | 54% | 54% |

The components described in the above table are as below.
Irg127: alkylphenone-based photopolymerization initiator (manufactured by BASF SE)
CPI-100P: sulfonium salt-based photopolymerization initiator (manufactured by San-Apro Ltd.)
RS-90: UV reactive group-containing fluorine-based antifoulant (manufactured by DIC Corporation)
FP-1: the following fluorine-based compound FP-1

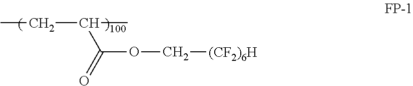

### Example 22

A polarizing plate of Example 22 was prepared by the same method as in Example 9, except that a decorative layer having a thickness of 2 μm was formed by printing a composition for forming a decorative layer on the outer peripheral portion of the surface of the base material on the side opposite to the cured layer (hardcoat layer) by screen printing.

The composition for forming a decorative layer was prepared by adding 7.14 parts by mass of carbon black MA8 manufactured by Mitsubishi Chemical Corporation and 23 parts by mass of a diluent solvent (containing a mixed solvent of butyl cellosolve and ethyl cellosolve and cyclohexanone at a ratio (mass ratio) of about 8:2) to 50 parts by mass of STR CONC 710 BLACK manufactured by Seiko Advance Ltd. and performing dilution. STR CONC 710 BLACK manufactured by Seiko Advance Ltd contains carbon black as a coloring component, a vinyl-based resin and an acryl-based resin as a binder, and a mixed solvent of butyl cellosolve and ethyl cellosolve as a solvent.

### Example 23

A polarizing plate of Example 23 was prepared by the same method as in Example 9, except that, as a base material, a polycarbonate film having a thickness of 300 μm (in-plane retardation at 550 nm: 140 nm) was used with reference to paragraph “0126” of JP3325560B.

### Example 24

In a base material with an interlayer prepared in the same manner as in Example 9, a surface coated with the interlayer was coated with the composition for forming an adhesive layer S-2 by using a bar coater such that the film thickness after curing became 2.5 μm, thereby forming a coating film of the composition for forming an adhesive layer S-2.

On one side of the polarizer, a coating film of the composition for forming an adhesive layer S-2 was formed in the same manner as described above, and the formed coating film was laminated on the aforementioned retardation film such that the slow axis of the retardation film became orthogonal to the absorption axis of the polarizer.

Then, the coating film of the composition for forming an adhesive layer S-2 provided on the base material with an interlayer was laminated on a surface of the polarizer that was opposite to the surface to which the retardation film was bonded. The laminate obtained in this way was loaded on a belt conveyor of an ultraviolet irradiation device with a belt conveyor. The retardation film side of the laminate was irradiated with ultraviolet rays from an ultraviolet lamp “D BULB” manufactured by Fusion UV Systems, Inc installed in the ultraviolet irradiation device such that a cumulative light amount became 500 mJ/cm², thereby curing the coating film on both surfaces of the polarizer. In this way, a polarizing plate of Example 24 was prepared.

### Example 25

As a base material, a laminated film of a polyester-based resin layers consisting of three layers (layer I/layer II/layer II) was prepared by the following method.

90 parts by mass of raw material polyester 1 and 10 parts by mass of raw material polyester 2 containing 10 parts by mass of an ultraviolet absorber (2,2′-(1,4-phenylene)bis(4H-3,1-benzoxazin-4-one) were dried until a moisture content thereof became equal to or less than 20 ppm, then put into a hopper 1 of a single screw kneading extruder a having a diameter of 50 mm, and melted at 300° C. in the extruder 1, thereby preparing a molten resin for forming the layer II positioned between the layer I and the layer III.

The raw material polyester 1 was dried until a moisture content thereof became equal to or less than 20 ppm, then put into a hopper 2 of a single screw extruder 2 having a diameter of 30 mm, and then melted at 300° C. in the extruder 2, thereby preparing a resin composition for forming the layer I and the layer III.

The two kinds of molten resins were respectively passed through a gear pump and a filter (pore size: 20 μm). Then, through a block by which the two kinds of resins become confluent as three layers, the resins were laminated such that the molten resin extruded from the extruder 1 become the internal layer (layer II) and that the molten resin extruded from the extruder 2 became the outer layers (layer I and layer III), and then extruded in the form of a sheet from a die having a width of 120 mm.

The molten resin sheet extruded from the die was extruded onto a cooling cast drum set to be at a temperature of 25° C. and caused to come into close contact with the cooling cast drum by using a method of applying static electricity. By using a peeling roll disposed to face the cooling cast drum, the resin sheet was peeled, thereby obtaining a non-stretched film. At this time, the amount of resin discharged from each extruder was adjusted such that a thickness ratio of layer I:layer II:layer III became 10:80:10.

By using a group of heated rolls and an infrared heater, the non-stretched film was heated such that the surface temperature of the film became 95° C. Then, by using a group of rolls having different circumferential speeds, the film was stretched in the movement direction of the film by a factor of 3.1, thereby obtaining a base material.

A polarizing plate of Example 25 was prepared by the same method as in Example 9, except that the obtained base material and the composition for forming an interlayer E-9 were used.

### Example 26

Pellets of an acryl-based resin “SUMIPEX EX” manufactured by Sumitomo Chemical Co., Ltd and an ultraviolet absorber 2,2′-methylenebis[6-(2H-benzotriazol-2-yl)-4-(1,1,3,3-tetramethylbutyl)phenol] (LA 31 manufactured by ADEKA CORPORATION were mixed together using a super mixer such that a proportion of the ultraviolet absorber became 4 parts by mass with respect to 100 parts by mass of the acryl-based resin. By melting and kneading the mixture with a double screw extruder, an acryl-based resin composition containing an ultraviolet absorber was obtained as pellets. A polarizing plate of Example 26 was prepared by the same method as in Example 3, except that the obtained acryl-based resin composition containing an ultraviolet absorber was used.

### Example 27

By the same method as in Example 9, an interlayer was provided on one surface of a base material, and a cured layer (hardcoat layer) was provided on the other surface, thereby obtaining a laminate. By using a wire bar, the surface of the interlayer of the laminate was coated with the composition for forming an adhesive layer S-3 made up as below. The composition was dried for 60 seconds with hot air with a temperature of 60° C. and then for 120 seconds with hot air with a temperature of 100° C., thereby preparing a laminate with an adhesive layer. At this time, the thickness of the adhesive layer was 2.4 μm.

Makeup of composition for forming adhesive layer S-3

| | |
|---|---|
| P-1 shown below | 1.0 parts by mass |
| Butoxyethanol | 33 parts by mass |
| Propylene glycol monomethyl ether | 33 parts by mass |
| water | 33 parts by mass |

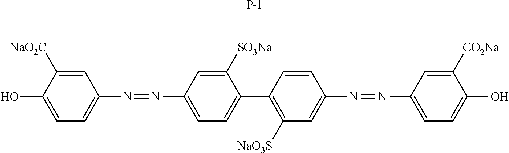

In the air, the prepared laminate with an adhesive layer was irradiated with ultraviolet rays by using an air-cooled metal halide lamp (manufactured by EYE GRAPHICS Co., Ltd.) at 160 W/cm². At this time, exposure was performed in a state where a wire grid polarizer (ProFlux PPL02 manufactured by Moxtek, Inc.) was set in parallel with the surface of the laminate with an adhesive layer. The illuminance of the ultraviolet rays used at this time was set to be 100 mW/cm² in a UV-A region (cumulated for wavelengths of 380 nm to 320 nm), and an irradiation amount was set to be 1,000 mJ/cm² in the UV-A region.

In this way, an adhesive layer was obtained which can function as an alignment film controlling the alignment of dichroic dyes contained in the following composition for a coating-type polarizing film.

Thereafter, by using a bar coater, the surface of the adhesive layer was coated with the following composition for a coating-type polarizing film made up as below. Subsequently, the composition was matured for 15 seconds at a film surface temperature of 160° C. and then cooled to room temperature, thereby preparing a coating-type polarizing plate. The thickness of the formed polarizing film (coating-type polarizing film) was 0.3 μm.

Makeup of composition for coating-type polarizing film

| | |
|---|---|
| Dichroic dye PB-1 | 50 parts by mass |
| Dichroic dye C-1 | 30 parts by mass |
| Dichroic dye C-2 | 20 parts by mass |
| Fluorine-based compound A | 0.3 parts by mass |
| Chloroform | 1,900 parts by mass |

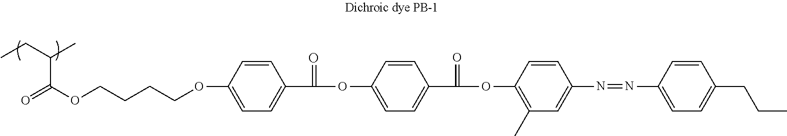

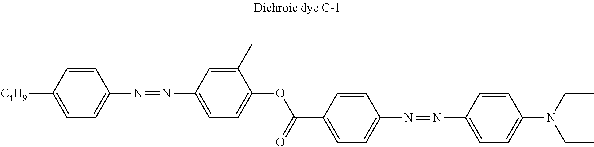

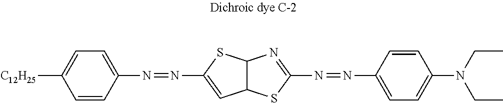

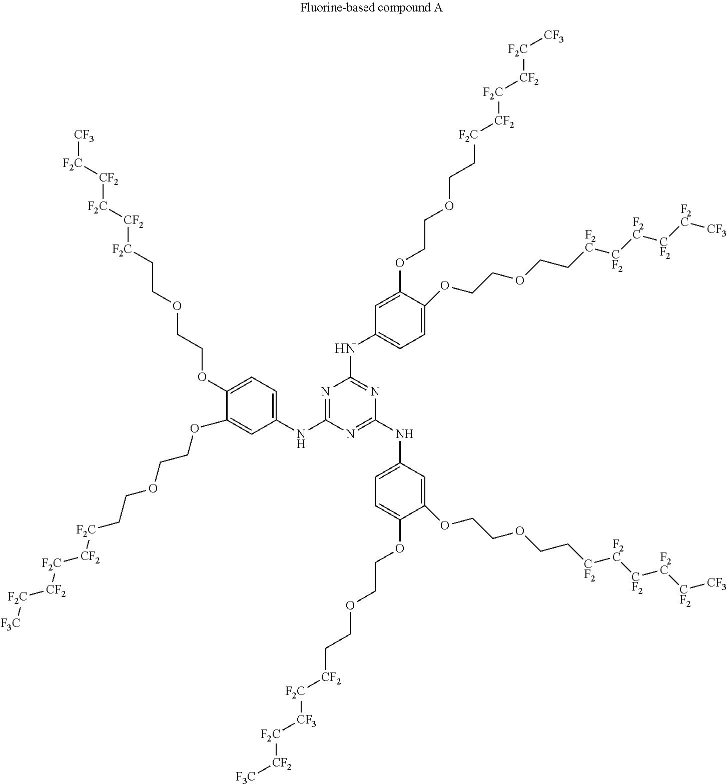

Then, by the same method as in Example 9, the aforementioned retardation film was bonded to the surface of the coating-type polarizing film through the composition for forming an adhesive layer S-1, thereby preparing a polarizing plate of Example 27.

### Example 28

By the same method as in Example 9, an interlayer was provided on one surface of a base material, and a cured layer (hardcoat layer) was provided on the other surface, thereby obtaining a laminate. By using a wire bar, the surface of the interlayer of the laminate was coated with the composition for forming an adhesive layer S-4 made up as below. The composition was dried for 60 seconds with hot air with a temperature of 60° C. and then for 120 seconds with hot air with a temperature of 100° C., thereby preparing a laminate with an adhesive layer. At this time, the thickness of the adhesive layer was 1.2 pun.

Makeup of composition for forming adhesive layer S-4

| | |
|---|---|
| Modified polyvinyl alcohol shown below | 2.4 parts by mass |
| Isopropyl alcohol | 1.6 parts by mass |
| Methanol | 36 parts by mass |
| water | 60 parts by mass |

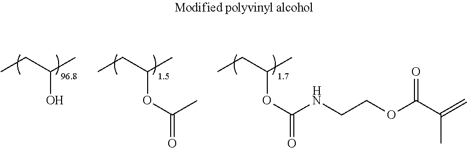

(The above numerical values represent a molar ratio)

Then, a rubbing treatment was performed on the surface of the adhesive layer. By the same method as in Example 27, the surface having undergone the rubbing treatment was coated with a composition for forming a coating-type polarizing plate, thereby obtaining a laminate with a coating-type polarizing film. The absorption axis of the formed coating-type polarizing film was aligned in parallel with the rubbing direction.

Thereafter, by the same method as in Example 9, the aforementioned retardation film was bonded to the surface of the coating-type polarizing film through the composition for forming an adhesive layer S-1, thereby preparing a polarizing plate of Example 28.

### Example 29

By the same method as in Example 9, an interlayer was provided on one surface of a base material, and a cured layer (hardcoat layer) was provided on the other surface, thereby obtaining a laminate. By using a wire bar, the surface of the interlayer of the laminate was coated with the composition for forming an adhesive layer S-5 made up as below. The composition was dried for 60 seconds with hot air with a temperature of 60° C. and then for 120 seconds with hot air with a temperature of 100° C., thereby preparing a laminate with an adhesive layer. At this time, the thickness of the adhesive layer was 100 nm.

Makeup of composition for forming adhesive layer S-5

| | |
|---|---|
| Polyvinyl alcohol-based resin (completely gelated polyvinyl alcohol | 2 parts by mass |
| 1000 manufactured by Wako Pure Chemical Industries, Ltd.) | |
| water | 98 parts by mass |

The following components of a composition for forming a coating-type polarizing plate
were mixed together and stirred for 1 hour in a state where the temperature of the composition
was being kept at 80° C., thereby obtaining a composition for forming a coating-type polarizing
film.
Makeup of composition for forming coating-type polarizing film

| | |
|---|---|
| Polymerizable smectic liquid crystal compound (J-1) | 75 parts by mass |
| Polymerizable smectic liquid crystal compound (J-2) | 25 parts by mass |
| Azo compound A shown below | 2.5 parts by mass |
| Photopolymerization initiator (Irg369 manufactured by BASF SE) | 6 parts by mass |
| Surfactant (BYK-361N manufactured by BYK-Chemie GmbH | 1.2 parts by mass |
| Cyclopentanone | 250 part by mass |

Polymerizable smectic liguid crystal compound (J-1): synthesized by the method described in Lub et al. Recl. Trav. Chim. Pays-Bas, 115, 321-328 (1996) 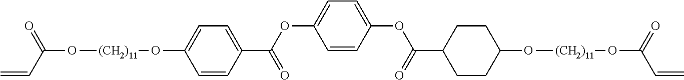
Polymerizable smectic liquid crystal compound (J-2): synthesized by the same method as used for synthesizing J-1 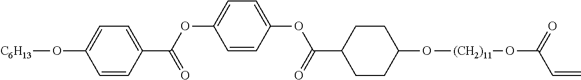
Azo compound A: Dye of D10 described in JP1996-278409A (following structure)

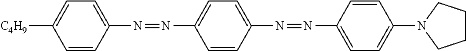

A rubbing treatment was performed on the surface of the aforementioned adhesive layer. By a spin coating method, the surface having undergone the rubbing treatment was coated with the aforementioned composition for forming a coating-type polarizing film, and the composition was heated and dried for 3 minutes on a hot plate (set temperature: 120° C.). Then, the composition was cooled to room temperature by being left to stand at room temperature, thereby forming a dry film on the adhesive layer. In the dry film, the liquid crystal of the polymerizable smectic liquid crystal compound was in a state of a smectic B phase. Thereafter, by using an ultraviolet irradiation device (SPOT CURE SP-7 manufactured by USHIO, INC.), the dry film was irradiated with ultraviolet rays in an exposure amount of 2,400 mJ/cm² (based on 365 nm), thereby forming a polarizing film. At this time, the thickness of the polarizing film was 1.7 μm.

Subsequently, by the same method as in Example 9, the aforementioned retardation film was bonded to the surface of the coating-type polarizing film through the composition for forming an adhesive layer S-1, thereby preparing a polarizing plate of Example 29.

### Example 30

By the same method as in Example 9, an interlayer was provided on one surface of a base material, and a cured layer (hardcoat layer) was provided on the other surface, thereby obtaining a laminate. By a spin coating method, the surface of the interlayer of the laminate was coated with the composition for forming an adhesive layer S-5 made up as in Example 29. The composition was dried for 60 seconds with hot air with a temperature of 60° C. and then for 120 seconds with hot air with a temperature of 100° C., thereby preparing a laminate with an adhesive layer. At this time, the thickness of the adhesive layer was 100 nm.

A rubbing treatment was performed on the surface of the aforementioned adhesive layer. By using a bar coater, the surface having undergone the rubbing treatment was coated with the following composition for forming a coating-type polarizing film, and the composition was naturally dried in a thermostatic chamber with a temperature of 23° C., thereby forming a coating-type polarizing film. At this time, the thickness of the polarizing film was 0.4 μm.

Makeup of composition for forming coating-type polarizing film

| | |
|---|---|
| Azo compound B shown below | 5 parts by mass |
| water | 98 parts by mass |

As a compound B, 3-amino-2,7-naphthalene sulfonic acid was made into a diazonium salt by using sodium nitrite and hydrochloric acid, and subjected to a coupling reaction together with 5-amino-2-naphthalene sulfonic acid in an acidic aqueous hot and cold solution, thereby obtaining a monoazo compound.

The monoazo compound was made into a diazonium salt by using sodium nitrite and hydrochloric acid and subjected to a coupling reaction together with 5-amino-2-naphthol such that sulfonate was converted into a sodium salt, thereby obtaining an azo compound B shown in the following structural formula.

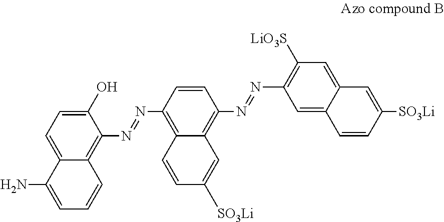

Then, by the same method as in Example 9, the aforementioned retardation film was bonded to the surface of the coating-type polarizing film through the composition for forming an adhesive layer S-1, thereby preparing a polarizing plate of Example 30.

### Comparative Example 1

A polarizing plate of Comparative Example 1 was prepared by the same method as in Example 1, except that a base material having a thickness (total thickness) described in Table 1 was prepared, and an interlayer was not formed.

### Comparative Example 2

A polarizing plate of Comparative Example 2 was prepared by the same method as in Comparative Example 1, except that a base material having a thickness (total thickness) described in Table 1 was prepared.

### Comparative Example 3

A polarizing plate of Comparative Example 3 was prepared by the same method as in Example 5, except that an interlayer was prepared using the composition for forming an interlayer E-10 made up as shown in Table 2.

### Comparative Example 4

A polarizing plate of Comparative Example 4 was prepared by the same method as in Example 5, except that an interlayer was prepared using the composition for forming an interlayer E-11 made up as shown in Table 2.

### Comparative Example 5

A polarizing plate of Comparative Example 5 was prepared by the same method as in Example 9, except that an interlayer was prepared in a manner in which a surface of a base material was coated with the composition for forming an interlayer E-12 made up as below, the composition was dried for 150 seconds at 60° C., and the coating layer was cured by being irradiated with ultraviolet rays with nitrogen purging at an oxygen concentration of 0.1% by volume by using an ultraviolet irradiation device at 120 W/cm (manufactured by Fusion UV Systems Japan KK) at an illuminance of 120 mW/cm² and an irradiation amount of 200 mJ/cm².

Makeup of composition for forming interlayer E-12

| | | |
|---|---|---|
| Urethane acrylate A (*) | 45 | parts by mass |
| KAYARAD DPCA (manufactured | 15 | parts by mass |
| by Nippon Kayaku Co., Ltd.) | | |
| VISCOAT 150D (manufactured | 33.3 | parts by mass |
| by OSAKA ORGANIC CHEMICAL | | |
| INDUSTRY LTD.) | | |
| ARONIX M-240 (manufactured | 6.7 | parts by mass |
| by TOAGOSEI CO., LTD.) | | |
| DARGCUR 1173 (manufactured | 4 | parts by mass |
| by BASF SE) | | |

(*) Urethane acrylate A: synthesized with reference to paragraph “0105” in JP2014-88010A

[Evaluaton Method]

<Pencil Hardness>

Pencil hardness was evaluated according to JIS K 5400. The polarizing plates of examples and comparative examples were humidified for 2 hours at a temperature of 25° C. and a relative humidity of 60%%, and then 5 different sites on the surface to be evaluated were scratched under a load of 4.9 N by using a testing pencil with hardness of H to 9H specified in JIS S 6006. The hardness of the pencil (pencil with the highest hardness) by which visually recognized scratch was formed at 0 to 2 sites at this time is described in Table 4.

<Process Suitability>

The polarizing plates of examples and comparative examples were humidified for 2 hours at a temperature of 25° C. and a relative humidity of 60%, and die-cut using a die cutting machine (a manual press machine of a TORQUE PACK PRESS TP series manufactured by ADAMA AMERICA, INC). Then the edge of the polarizing plates was visually observed and evaluated according to the following standards. The polarizing plates graded A to D by the evaluation can be acceptable as a product. The edge of the polarizing plate graded E by the evaluation cracked to such a degree that the polarizing plate was not acceptable as a product.

A: cracking was not observed on the edge.

B: cracking practically was not observed on the edge.

C: slight cracking was observed on the edge.

D: cracking was observed in some portions of the edge.

E: cracking was observed in most of the edge.

<Modulus of Elasticity>

The polarizing plates of examples and comparative examples were obliquely cut using Surface And Interfacial Cutting Analysis System (SAICAS) (registered trademark, manufactured by DAYPLA WINTES CO., LTD.). For the cut cross-section, a modulus of elasticity was determined by the method described above.

<Curling>

The polarizing plates of examples and comparative examples were punched in 100 mm×100 mm, and placed on a flat surface and humidified for 2 hours at a temperature of 25° C. and a relative humidity of 60% such that the end surface of the test piece rose. By using a steel rule, the height of the end face that rose after the test piece was humidified was measured, and evaluated as below. The height of the end face that rose when the test piece was placed such that the base material was on the polarizer film was denoted by “+”, and the height of the end face that rose when the test piece was placed such that the base material was under the polarizer film was denoted by “−”. In all of examples, the polarizing plates were evaluated to be A. In contrast, in Comparative Example 5, the polarizing plate was evaluated B as shown in Table 4.

A: the height of end face that rose was less than ±2 cm, and hence the polarizing plate is unproblematic for practical use.

B: the height of end face that rose was equal to or greater than ±2 cm, and hence the polarizing plate is problematic for practical use.

The above evaluation results are shown in Table 4. In Table 4, regarding the base material, PMMA/PC/PMMA means a laminated film constituted with three layers of acryl-based resin layer/polycarbonate resin layer/acryl-based resin layer. In Example 25, the base material PET means the laminated film (constituted with three layers) of the polyester-based resin layer described above.

TABLE 4

| | | | | Thickness | |
|---|---|---|---|---|---|
| | | | Composition | of base | |
| | | Composition | for forming | material | |
| | | for forming | adhesive | film (total | Thickness of |
| | Transparent support | interlayer | layer | thickness) | interlayer |
| Example 1 | PMMA/PC/PMMA | E-1 | S-1 | 120 μm | 0.30 μm |
| Example 2 | PMMA/PC/PMMA | E-1 | S-1 | 120 μm | 0 30 μm |
| Example 3 | PMMA/PC/PMMA | E-1 | S-1 | 300 μm | 0.30 μm |
| Example 4 | PMMA/PC/PMMA | E-1 | S-1 | 200 μm | 0.30 μm |
| Example 5 | PMMA/PC/PMMA | E-1 | S-1 | 120 μm | 0.30 μm |
| Example 6 | PMMA/PC/PMMA | F-1 | S-1 | 400 μm | 0.30 μm |
| Example 7 | PMMA/PC/PMMA | E-1 | S-1 | 700 μm | 0.30 μm |
| Example 8 | PMMA/PC/PMMA | E-1 | S-1 | 1,000 μm | 0.30 μm |
| Example 9 | TECHNOLLOY C101 | E-1 | S-1 | 300 μm | 0.30 μm |
| Example 10 | TECHNOLLOY C101 | E-2 | S-1 | 300 μm | 0.30 μm |
| Example 11 | TECHNOLLOY C101 | E-3 | S-1 | 300 μm | 0.30 μm |
| Example 12 | TECHNOLLOY C101 | E-4 | S-1 | 300 μm | 0.30 μm |
| Example 13 | TECHNOLLOY C101 | E-1 | S-1 | 300 μm | 0.01 μm |
| Example 14 | TECHNOLLOY C101 | E-1 | S-1 | 300 μm | 1.00 μm |
| Example 15 | TECHNOLLOY C101 | E-1 | S-1 | 300 μm | 5.00 μm |
| Example 16 | TECHNOLLOY C101 | E-5 | S-1 | 300 μm | 0.30 μm |
| Example 17 | TECHNOLLOY C101 | E-6 | S-1 | 300 μm | 0.30 μm |
| Example 18 | TECHNOLLOY C101 | F-7 | S-1 | 300 μm | 0.30 μm |
| Example 19 | TECHNOLLOY C101 | E-8 | S-1 | 300 μm | 0.30 μm |
| Example 20 | TECHNOLLOY C101 | E-1 | S-1 | 300 μm | 0.30 μm |
| Example 21 | TECHNOLLOY C101 | E-1 | S-1 | 300 μm | 0.30 μm |
| Example 22 | TECHNOLLOY C101 | E-1 | S-1 | 300 μm | 0.30 μm |
| Example 23 | Uniaxially stretched | E-1 | S-1 | 300 μm | 0.30 μm |
| | polycarbonate | | | | |
| Example 24 | TECHNOLLOY C101 | E-1 | S-2 | 300 μm | 0.30 μm |
| Example 25 | PET | E-9 | S-1 | 300 μm | 0.30 μm |
| Example 26 | PMMA(containing | E-1 | S-1 | 300 μm | 0.30 μm |
| | ultraviolet absorber)/PC/ | | | | |
| | PMMA(containing | | | | |
| | ultraviolet absorber) | | | | |
| Example 27 | TECHNOLLOY C101 | E-1 | S-3 | 300 μm | 0.30 μm |
| Example 28 | TECHNOLLOY C101 | E-1 | S-4 | 300 μm | 0.30 μm |
| Example 29 | TECHNOLLOY C101 | E-1 | S-5 | 300 μm | 0.30 μm |
| Example 30 | TECHNOLLOY C101 | E-1 | S-6 | 300 μm | 0.30 μm |
| Comparative | PMMA/PC/PMMA | N/A | S-1 | 110 μm | 0.30 μm |
| Example 1 | | | | | |
| Comparative | PMMA/PC/PMMA | N/A | S-1 | 120 μm | 0.30 μm |
| Example 2 | | | | | |
| Comparative | PMMA/PC/PMMA | E-10 | S-1 | 120 μm | 0.30 μm |
| Example 3 | | | | | |
| Comparative | PMMA/PC/PMMA | E-11 | S-1 | 120 μm | 0.30 μm |
| Example 4 | | | | | |

| | Modulus of | | Modulus of | | | | |
|---|---|---|---|---|---|---|---|
| | elasticity Ea | Modulus of | elasticity Ec | | | | |
| | of base | elasticity Eb | of adhesive | Cured layer (hardcoat layer) | | Pencil | Process |
| | material film | of interlayer | layer | Composition | Thickness | hardness | suitability |
| Example 1 | 3.1 GPa | 2.3 GPa | 1.5 GPa | N/A | N/A | 3H | C |
| Example 2 | 3.1 GPa | 2.3 GPa | 1.5 GPa | N/A | N/A | 3H | C |
| Example 3 | 3.1 GPa | 2.3 GPa | 1.5 GPa | HC1 | 35 μm | 8H | C |
| Example 4 | 3.1 GPa | 2.3 GPa | 1.5 GPa | HC1 | 35 μm | 7H | C |
| Example 5 | 3.1 GPa | 2.3 GPa | 1.5 GPa | HC1 | 35 μm | 5H | B |
| Example 6 | 3.1 GPa | 2.3 GPa | 1.5 GPa | HC1 | 35 μm | 8H | C |
| Example 7 | 3.1 GPa | 2.3 GPa | 1.5 GPa | HC1 | 35 μm | 9H | D |
| Example 8 | 3.1 GPa | 2.3 GPa | 1.5 GPa | HC1 | 35 μm | 9H | D |
| Example 9 | 3.1 GPa | 2.3 GPa | 1.5 GPa | HC1 | 35 μm | 8H | C |
| Example 10 | 3.1 GPa | 2.9 GPa | 1.5 GPa | HC1 | 35 μm | 8H | D |
| Example 11 | 3.1 GPa | 1.7 GPa | 1.5 GPa | HC1 | 35 μm | 8H | D |
| Example 12 | 3.1 GPa | 2.3 GPa | 1.5 GPa | HC1 | 35 μm | 8H | D |
| Example 13 | 3.1 GPa | 2.3 GPa | 1.5 GPa | HC1 | 35 μm | 8H | D |
| Example 14 | 3.1 GPa | 2.3 GPa | 1.5 GPa | HC1 | 35 μm | 8H | B |
| Example 15 | 3.1 GPa | 2.3 GPa | 1.5 GPa | HC1 | 35 μm | 8H | A |
| Example 16 | 3.1 GPa | 2.3 GPa | 1.5 GPa | HC1 | 35 μm | 8H | B |
| Example 17 | 3.1 GPa | 2.3 GPa | 1.5 GPa | HC1 | 35 μm | 8H | A |
| Example 18 | 3.1 GPa | 2.3 GPa | 1.5 GPa | HC1 | 35 μm | 8H | A |
| Example 19 | 3.1 GPa | 1.7 GPa | 1.5 GPa | HC1 | 35 μm | 8H | B |
| Example 20 | 3.1 GPa | 2.3 GPa | 1.5 GPa | HC2 | 35 μm | 8H | C |
| Example 21 | 3.1 GPa | 2.3 GPa | 1.5 GPa | HC3 | 35 μm | 8H | C |
| Example 22 | 3.1 GPa | 2.3 GPa | 1.5 GPa | HC1 | 35 μm | 8H | C |
| Example 23 | 2.6 GPa | 2.3 GPa | 1.5 GPa | HC1 | 35 μm | 8H | C |
| Example 24 | 3.1 GPa | 2.3 GPa | 2.0 GPa | HC1 | 35 μm | 8H | C |
| Example 25 | 5.0 GPa | 3.3 GPa | 1.5 GPa | HC1 | 35 μm | 8H | C |
| Example 26 | 3.1 GPa | 2.3 GPa | 1.5 GPa | HC1 | 35 μm | 8H | C |
| Example 27 | 3.1 GPa | 2.3 GPa | 1.5 GPa | HC1 | 35 μm | 8H | C |
| Example 28 | 3.1 GPa | 2.3 GPa | 1.5 GPa | HC1 | 35 μm | 8H | C |
| Example 29 | 3.1 GPa | 2.3 GPa | 1.5 GPa | HC1 | 35 μm | 8H | C |
| Example 30 | 3.1 GPa | 2.3 GPa | 1.5 GPa | HC1 | 35 μm | 8H | C |
| Comparative | 3.1 GPa | — | 1.5 GPa | N/A | N/A | H | B |
| Example 1 | | | | | | | |
| Comparative | 3.1 GPa | — | 1.5 GPa | N/A | N/A | 3H | E |
| Example 2 | | | | | | | |
| Comparative | 3.1 GPa | 1.2 GPa | 1.5 GPa | N/A | N/A | 3H | E |
| Example 3 | | | | | | | |
| Comparative | 3.1 GPa | 4.4 GPa | 1.5 GPa | N/A | N/A | 3H | E |
| Example 4 | | | | | | | |

| | | | Modulus of | | Modulus of | | |
|---|---|---|---|---|---|---|---|
| | | | elasticity E1 | | elasticity E2 | | |
| | | | of interlayer | | of interlayer | | |
| | | | (surface layer | | (surface layer | | |
| | | Composition | portion on | Modulus of | portion on | | |
| | | for forming | base material | elasticity Eb | adhesive layer | Pencil | Process |
| | Base material film | interlayer | film side) | of interlayer | side) | hardness | suitability |
| Example 9 | TECHNOLLOY C101 | E-1 | 2.8 GPa | 2.3 GPa | 1.8 GPa | 8H | C |
| Example 12 | TECHNOLLOY C101 | E-4 | 2.3 GPa | 2.3 GPa | 2.3 GPa | 8H | D |

| | | Composition | | |
|---|---|---|---|---|
| | | for forming | Process | |
| | Base material film | interlayer | suitability | Curling |
| Example 9 | TECHNOLLOY C101 | E-1 | C | A |
| Comparative | TECHNOLLOY C101 | E-5 | C | B |
| Example 5 | | | | |

From the evaluation results of Comparative Example 1 shown in Table 4, it was confirmed that, in a case where the thickness of the base material does not satisfy 120 μm, even if the polarizer layer and the base material are laminated through the adhesive layer without providing an interlayer, the process suitability of the obtained polarizing plate is excellent.

In contrast, from the comparison of Examples 1 to 30 and Comparative Examples 2 to 4, it was confirmed that, in a case where the thickness of the base material is equal to or greater than 120 μm, by providing an interlayer having a modulus of elasticity, which satisfies the relationship of Expression 1 together with a modulus of elasticity of the base material and a modulus of elasticity of the adhesive layer, between the base material and the adhesive layer, a polarizing plate having excellent process suitability can be obtained. Furthermore, it was confirmed that the polarizing plates of examples provided with the base material having a thickness of equal to or greater than 120 μm had high pencil hardness and are suitable as a front panel of a display apparatus or a substrate of a touch panel. Particularly, examples 3 to 30 in which a cured layer (hardcoat layer) was provided on the base material had pencil hardness higher than that of Examples 1 and 2.

In addition, it was confirmed that Examples 16 to 19 having an interlayer containing a barbituric acid-based compound are particularly excellent in process suitability among examples.

From the comparison of Example 9 and Examples 10 and 11, it was confirmed that the process suitability is further improved when the interlayer has a modulus of elasticity satisfying the relationship of Expression 2.

Moreover, from the comparison of Example 9 and Example 12, it was confirmed that it is preferable that the interlayer has a distribution of modulus of elasticity satisfying the relationship of Expression 3 in view of process suitability.

### Example 31

### In-Cell Touch Panel Liquid Crystal Device

An in-cell touch panel liquid crystal device incorporated into a commercial liquid crystal display apparatus (manufactured by Sony Ericsson, XPERIA P) was prepared. The polarizing plate of Example 9 was bonded onto the in-cell touch panel liquid crystal device through an adhesive layer having a thickness of 20 Gm.

### Example 32

### On-Cell Touch Panel Liquid Crystal Device

The polarizing plate of Example 9 was bonded onto a color filter integrated with a touch panel sensor described in paragraphs “0139” to “0143” in JP2012-88683A through an adhesive layer having a thickness of 20 μm.

### Example 33

An on-cell touch panel liquid crystal device incorporated into a commercial organic EL display apparatus (manufactured by SAMSUNG, GALAXY SII) was prepared. The polarizing plate of Example 9 was bonded onto the on-cell touch panel liquid crystal device through an adhesive layer having a thickness of 20 μm.

### Comparative Example 6

An in-cell touch panel liquid crystal device incorporated into a commercial liquid crystal display apparatus (Sony Ericsson, XPERIA P) was prepared. The polarizing plate of Comparative Example 1 was bonded onto the in-cell touch panel liquid crystal device through an adhesive layer having a thickness of 20 μm.

The evaluation results obtained from the above are shown in Table 5.

TABLE 5

| | | | | Pencil |
|---|---|---|---|---|
| | Front panel | Touch panel | Display device | hardness |
| Example 31 | Example 9 | In-cell | Liquid crystal | 8H |
| Example 32 | Example 9 | On-cell | Liquid crystal | 8H |
| Example 33 | Example 9 | On-cell | Organic EL | 8H |
| Comparative | Comparative | On-cell | Liquid crystal | H |
| Example 6 | Example 1 | | | |

The present invention is useful in the field of manufacturing various display apparatuses, touch panels, and the like.

What is claimed is:

1. A polarizing plate comprising:
a base material;
an interlayer;
an adhesive layer; and
a polarizer layer in this order,
wherein the base material contains at least a resin film and has a thickness of equal to or greater than 120 μm,
the interlayer is a cured layer obtained by curing a thermosetting composition containing a thermally cross-linkable compound in a proportion of equal to or higher than 0.10% by mass with respect to a total amount of solid content of the composition, and
a modulus of elasticity Ea of the base material, a modulus of elasticity Eb of the interlayer, and a modulus of elasticity Ec of the adhesive layer satisfy the following Expression 1:
Ea>Eb>Ec Expression 1.

2. The polarizing plate according to claim 1, further comprising:
a resin film on a side of the polarizer layer that is opposite to the base material.

3. The polarizing plate according to claim 1,
wherein the thickness of the base material is equal to or greater than 200 μm and equal to or less than 700 pun.

4. The polarizing plate according to claim 1,
wherein the modulus of elasticity Ea of the base material, the modulus of elasticity Eb of the interlayer, and the modulus of elasticity Ec of the adhesive layer satisfy the following Expression 2:
(Ea+Ec)×3/5>Eb>(Ea+Ec)×2/5 Expression 2.

5. The polarizing plate according to claim 1,
wherein the modulus of elasticity Eb of the interlayer is equal to or higher than 1.5 GPa and equal to or lower than 5.0 GPa.

6. The polarizing plate according to claim 1,
wherein the modulus of elasticity Eb of the interlayer, a modulus of elasticity of E1 of a surface layer portion of the interlayer on the base material side, and a modulus of elasticity E2 of a surface layer portion of the interlayer on the adhesive layer side satisfy the following Expression 3:
E1>Eb>E2 Expression 3.

7. The polarizing plate according to claim 1,
wherein a thickness of the interlayer is equal to or greater than 0.01 μm and equal to or less than 5.00 μm.

8. The polarizing plate according to claim 1,
wherein the interlayer contains a compound having a barbituric acid structure.

9. The polarizing plate according to claim 1, further comprising:
a cured layer, which is obtained by curing an active energy ray-curable composition, on a side of the base material opposite to the interlayer side.

10. The polarizing plate according to claim 1, further comprising:
a decorative layer in a portion on one surface of the base material.

11. The polarizing plate according to claim 1,
wherein the base material includes a quarter wavelength retardation plate.

12. The polarizing plate according to claim 1,
wherein the resin film included in the base material is a laminated film having an acryl-based resin film, a polycarbonate resin film, and an acryl-based resin film in this order.

13. A front panel of a display device that is the polarizing plate according to claim 1.

14. A display apparatus comprising:
the front panel according to claim 13; and
a display device.

15. The display apparatus according to claim 14,
wherein the display device is a liquid crystal display device.

16. The display apparatus according to claim 14,
wherein the display device is an organic electroluminescence display device.

17. The display apparatus according to claim 14,
wherein the display device is an in-cell touch panel display device.

18. The display apparatus according to claim 14,
wherein the display device is an on-cell touch panel display device.

19. A substrate of a touch panel that is the polarizing plate according to claim 1.

20. A resistive film-type touch panel comprising:
the substrate according to claim 19.

21. A capacitance-type touch panel comprising:
the substrate according to claim 19.
